(19) United States
(12) Patent Application Publication
(10) Pub. No.: US 2010/0327877 A1
(43) Pub. Date: Dec. 30, 2010

(54) RADIO FREQUENCY IDENTIFICATION (RFID) DEVICE AND METHOD FOR TESTING THE SAME

(75) Inventors: Hee Bok KANG, Cheongju (KR); Suk Kyoung Hong, Gwacheon (KR)

Correspondence Address: AMPACC Law Group, PLLC;LOADING..., 6100 219th Street SW, Suite 580, Mountlake Terrace, WA, 98043, US

(73) Assignee: Hynix Semiconductor Inc., Icheon (KR)

(21) Appl. No.: 12/650,524

(22) Filed: Dec. 30, 2009

(30) Foreign Application Priority Data
Jun. 24, 2009 (KR) 10-2009-0056372
Jun. 24, 2009 (KR) 10-2009-0056374
Jun. 24, 2009 (KR) 10-2009-0056388
Jun. 24, 2009 (KR) 10-2009-0056389
Jun. 24, 2009 (KR) 10-2009-0056390

(51) Int. Cl. G01R 31/02

(52) U.S. Cl. 324/537

(57) ABSTRACT

A radio frequency identification (RFID) device and a test method thereof are disclosed. In this test method, the RFID device receives different kinds of tag selection addresses and memory addresses according to a time sharing scheme, so that one or more RFID tags are tested. The RFID device includes a tag chip and a test chip. The tag chip performs a test operation upon receiving a test input signal from an external node, and externally outputs a test output signal indicating a result of the test operation. The test chip tests the tag chip upon receiving an address and data from an external node via a test pad during a test mode.

### CROSS-REFERENCE TO RELATED APPLICATION

The priority of Korean patent application Nos. 10-2009-0056372, 10-2009-0056374, 10-2009-0056388, 10-2009-0056389, and 10-2009-0056390 filed on Jun. 24, 2009, the disclosure of which is hereby incorporated in its entirety by reference, is claimed.

### BACKGROUND OF THE INVENTION

Embodiments of the present invention relate to a Radio Frequency IDentification (RFID) device and a method for testing the same, and more specifically, to a technology for enabling one test chip to test a plurality of tag chips included in a tag chip array at a wafer level (i.e., before the wafer is cut into individual circuits).

A Radio Frequency IDentification (RFID) tag chip has been widely used to automatically identify objects using a radio frequency (RF) signal. In order to automatically identify an object using the RFID tag chip, an RFID tag is first attached to the object to be identified, and an RFID reader wirelessly communicates with the RFID tag of the object without the need for line of sight or physical contact with the RFID tag. With the widespread use of such RFID technologies, shortcomings of related automatic identification technologies, such as barcode and optical character recognition technologies, can be greatly reduced.

In recent times, the RFID tag has been widely used in physical distribution management systems, user authentication systems, electronic money (e-money), transportation systems, and the like. For example, the physical distribution management system generally performs identification of goods or management of goods in stock using an Integrated Circuit (IC) recording data therein, instead of using a delivery note or tag. In addition, the user authentication system generally performs an Entrance and Exit Management function or the like using an IC card including personal information or the like.

In the meantime, a non-volatile ferroelectric memory may be used as a memory in an RFID tag. Generally, a non-volatile ferroelectric memory, that is, a ferroelectric Random Access Memory (FeRAM), has a data processing speed similar to that of a Dynamic Random Access Memory (DRAM), and preserves data even in a case where power is turned off, such that many developers are conducting intensive research into FeRAM as a next generation memory device.

The above-mentioned FeRAM has a very similar structure to that of DRAM, and uses a ferroelectric capacitor as a memory device. The ferroelectric substance has high residual polarization characteristics, such that data is not lost although an electric field is removed.

FIG. 1 is a block diagram illustrating a general RFID device.

The RFID device according to the related art generally includes an antenna unit 1, an analog unit 10, a digital unit 20, and a memory unit 30.

In this case, the antenna unit 1 receives a radio frequency (RF) signal from an external RFID reader. The RF signal from the antenna unit 1 is input to the analog unit 10 via antenna pads 11 and 12.

The analog unit 10 amplifies the input RF signal, such that it generates a power-supply voltage VDD providing a driving voltage of an RFID tag. The analog unit 10 detects an operation command signal from the input RF signal, and outputs a command signal CMD to the digital unit 20. In addition, after the analog unit 10 detects the output voltage VDD, it outputs a power-on reset signal POR for controlling a reset operation and also a clock CLK to the digital unit 20.

The digital unit 20 receives the power-supply voltage VDD, the power-on reset signal POR, the clock CLK, and the command signal CMD from the analog unit 10, and outputs a response signal RP in response to the received signals to the analog unit 10. The digital unit 20 outputs an address ADD, Input/Output data (I/O), a control signal CTR, and a clock CLK to the memory unit 30. The memory unit 30 reads and writes data using a memory device, and stores data therein.

In this case, the RFID device uses frequencies of various bands. In general, as the value of a frequency band is lowered, the RFID device has a lower recognition speed, has a shorter operation distance, and is less affected by environments. In contrast, as the value of a frequency band is increased, the RFID device has a higher recognition speed, has a greater operation distance, and is considerably affected by peripheral environments.

The best test method capable of testing whether such an RFID tag is operating normally or not is as follows. An RF signal is input to the antenna pads 11 and 12 of each RFID pad. The RF signal is processed by the digital unit 20 contained in the RFID tag so that a response signal RP is generated, and then the response signal RP is modulated and transmitted to the RFID reader. As a result, the above-mentioned test method is able to determine whether the signal received in the RFID reader is a correct signal.

However, more than several thousand RFID tags are present in one wafer, such that the above test method that applies the RF signal to each of all the RFID tags is not cost effective and is far from efficient.

### BRIEF SUMMARY OF THE INVENTION

Various embodiments of the present invention are directed to providing an RFID device and a method for testing the same that substantially obviates one or more problems due to limitations and disadvantages of the related art.

In accordance with one aspect of the present invention, a radio frequency identification (RFID) device includes: a tag chip configured to perform its own test operation upon receiving a test input signal from an external node, and externally output a test output signal indicating a result of the test operation; and a test chip configured to test the tag chip upon receiving an address and data from an external node via a test pad during a test mode.

In accordance with another aspect of the present invention, radio frequency identification (RFID) device includes: a memory unit configured to read and/or write data from/in a cell array in response to internal control signals; and a test interface unit which generates the internal control signals upon receiving an address and data from an external node when a test activation signal is activated, performs a test operation of the memory unit, and externally outputs a test output signal indicating a result of the test operation to an external node.

In accordance with another aspect of the present invention, a method for testing a radio frequency identification (RFID) device which includes a memory unit and a test interface unit for testing the memory unit in response to an address and data that are received from an external node via a single common test pad, the method includes: sequentially receiving the address and the data via the common test pad; performing a test operation of the memory unit; and outputting a result of the test operation of the memory unit to an external node via the common test pad.

In accordance with another aspect of the present invention, a radio frequency identification (RFID) device includes: a tag chip array configured to have a plurality of tag chips, each of which includes a memory unit; a test chip configured to test the tag chip array upon receiving an address and data from an external node during a test mode; and one or more data buses configured to interconnect the tag chip array and the test chip, wherein the test chip controls a tag chip's output current received via the data bus, and thus outputs a failed status of each of the tag chip and the test chip to an external node.

In accordance with another aspect of the present invention, a method for testing a radio frequency identification (RFID) device which includes a tag chip equipped with a memory unit and a test chip for testing the tag chip in response to an address and data received from an external node and being coupled to the tag chip via a data bus, the method includes: receiving an address corresponding to each of the tag chip and the test chip; and detecting a current applied to the data bus in response to a test command, and then determining the tag chip or the test chip to be in a failed mode when a pull-down current is detected in the current.

In accordance with another aspect of the present invention, a radio frequency identification (RFID) device includes: a digital unit which is activated by a test serial input signal and a test clock (or test clock signal), performs a test operation in response to a test input signal received from an external node during an activation period, and outputs a response signal when the test operation is completed; and an input/output (I/O) pad unit configured to receive a power-supply voltage, a ground voltage, the test serial input signal, the test clock, and the test input signal from an external node.

In accordance with another aspect of the present invention, a method for testing a radio frequency identification (RFID) device which includes a digital unit that is activated by a test serial input signal and a test clock, performs a test operation in response to a test input signal received from an external node during an activation period, and outputs a response signal when the test operation is completed, and an input/output (I/O) pad unit configured to receive a power-supply voltage, a ground voltage, the test serial input signal, the test clock, and the test input signal from an external node, the method includes: activating the digital unit by the test serial input signal and the test clock; receiving the test input signal via the input/output (I/O) pad unit; performing, by the digital unit, the test operation in response to the test input signal, and generating a test output signal; outputting the test output signal to an external node; and comparing the test input signal with the test output signal.

In accordance with another aspect of the present invention, a radio frequency identification (RFID) device includes: a shift register configured to receive a test serial input signal and a test clock, generate a test serial output signal, and output the test serial output signal; a test circuit which is activated by the test serial output signal and performs a test operation in response to a test input signal received from an external node during an activation period; and an input/output (I/O) pad unit configured to receive a power-supply voltage, a ground voltage, the test serial input signal, the test clock, and the test input signal from an external node, and output the test serial output signal.

In accordance with another aspect of the present invention, a radio frequency identification (RFID) device includes: a shift register configured to receive a test serial input signal and a test clock, generate a test serial output signal, and output the test serial output signal; a test circuit which is activated by the test serial output signal and performs a test operation in response to an address, data, and a control signal received from an external node during an activation period; and an input/output (I/O) pad unit configured to receive a power-supply voltage and a ground voltage from an external node, receive the test serial input signal, the test clock, the address, the data, and the control signal, and output the test serial output signal.

In accordance with another aspect of the present invention, a method for testing a radio frequency identification (RFID) device which includes a shift register configured to receive a test serial input signal and a test clock, generate a test serial output signal, and output the test serial output signal, a test circuit which is activated by the test serial output signal and performs a test operation in response to a test input signal received from an external node during an activation period, and an input/output (I/O) pad unit configured to receive a power-supply voltage and a ground voltage from an external node, receive the test serial input signal, the test clock, the test input signal, and output the test serial output signal, the method includes: activating the test circuit by the test serial output signal; receiving the test input signal via the input/output (I/O) pad unit; generating a test output signal by allowing the test circuit to perform the test operation in response to the test input signal; outputting the test output signal to an external node; and comparing the test input signal with the test output signal.

In accordance with another aspect of the present invention, a method for testing a radio frequency identification (RFID) device which includes a shift register configured to receive a test serial input signal and a test clock, generate a test serial output signal, and output the test serial output signal, a test circuit which is activated by the test serial output signal and performs a test operation in response to an address, data, and a control signal received from an external node during an activation period, and an input/output (I/O) pad unit configured to receive a power-supply voltage and a ground voltage from an external node, receive the test serial input signal, the test clock, the address, the data, and the control signal, and output the test serial output signal, the method includes: activating the test circuit by the test serial output signal; receiving the address and the control signal via the input/output (I/O) pad unit; generating a test output signal by allowing the test circuit to perform the test operation in response to the address and the control signal; outputting the test output signal to an external node; and comparing the test input signal with the test output signal.

In accordance with another aspect of the present invention, a radio frequency identification (RFID) device includes: a test chip configured to be initialized by a power-supply voltage so that it starts a test operation; and first to N-th RFID tags (where N is a natural number equal to or higher than ‘2’) sequentially coupled in series to the test chip, wherein the first to N-th RFID tags are sequentially activated upon receiving a power-supply voltage and a ground voltage from an external node, so that a test operation of the first to N-th RFID tags is performed.

### BRIEF DESCRIPTION OF THE DRAWINGS

FIG. 1 is a block diagram illustrating an RFID device according to a related art.

FIG. 2 is a structural diagram illustrating an RFID device according to a first embodiment of the present invention.

FIG. 3 is a flowchart illustrating a method for testing an RFID device according to a first embodiment of the present invention.

FIG. 4 is a flowchart illustrating operations of a test interface unit shown in FIG. 2.

FIG. 5 is an arrangement structure illustrating that a test chip and a tag chip are arranged on a wafer of the RFID device shown in FIG. 2.

FIG. 6 is a structural diagram illustrating that a test chip is coupled to tag chips via scribe lanes in the RFID device shown in FIG. 2.

FIG. 7 is a structural diagram illustrating pads of a test chip for use in an RFID device according to a first embodiment of the present invention.

FIG. 8 is a detailed circuit diagram illustrating a test interface unit shown in FIG. 2.

FIG. 9 is a detailed circuit diagram of an address latch unit shown in FIG. 8.

FIG. 10 is a detailed circuit diagram illustrating an address synthesis unit shown in FIG. 8.

FIG. 11 is a waveform diagram illustrating operations of a test interface unit shown in FIG. 8.

FIG. 12 is a detailed circuit diagram illustrating a test interface unit shown in FIG. 2.

FIG. 13 is a detailed circuit diagram illustrating a data latch unit shown in FIG. 12.

FIG. 14 is a detailed circuit diagram illustrating a data synthesis unit shown in FIG. 12.

FIG. 15 is a waveform diagram illustrating a test synthesis unit shown in FIG. 12.

FIG. 16 is a detailed circuit diagram illustrating an RFID device according to a second embodiment of the present invention.

FIGS. 17 and 18 are flowcharts illustrating a method for testing an RFID device according to a second embodiment of the present invention.

FIG. 19 is a flowchart illustrating a method for testing a tag chip and a test chip according to the test method for the RFID device shown in FIG. 16.

FIG. 20 is a flowchart illustrating an automatic fail recognition function performed when a test chip is tested in the test method of the RFID device according to an embodiment of the present invention.

FIG. 21 is a structural diagram illustrating pads of a test chip for use in the RFID device shown in FIG. 16.

FIG. 22 is a detailed circuit diagram illustrating a test interface unit shown in FIG. 2.

FIG. 23 is a block diagram illustrating an output circuit contained in a test chip of the RFID device shown in FIG. 16.

FIG. 24 is a detailed circuit diagram illustrating a decoder contained in a test chip selection controller shown in FIG. 23.

FIG. 25 is a detailed circuit diagram illustrating a latch unit contained in a test chip selection controller shown in FIG. 23.

FIGS. 26 and 27 are a detailed circuit diagram and a timing diagram illustrating operations of constituent elements related to a data bus D_bus_1 of the test chip shown in FIG. 23, respectively.

FIGS. 28 and 29 are a detailed circuit diagram and a timing diagram illustrating a current detector and a driver related to a data bus D_bus_n of the test chip shown in FIG. 23, respectively.

FIG. 30 shows a wafer including a plurality of RFID tag arrays according to a third embodiment of the present invention.

FIG. 31 is a structural diagram illustrating one RFID tag array according to a third embodiment of the present invention.

FIG. 32 is a conceptual diagram illustrating a process for sequentially activating a plurality of RFID tags in an RFID tag array according to a third embodiment of the present invention.

FIG. 33 is a circuit diagram illustrating an RFID tag array according to a third embodiment of the present invention.

FIGS. 34 and 35 are circuit diagrams illustrating procedures for sequentially testing a plurality of RFID tags contained in an RFID tag array according to a third embodiment of the present invention.

FIG. 36 is a circuit diagram illustrating that respective RFID tags are coupled to one another via scribe lanes in an RFID tag array according to a third embodiment of the present invention.

FIG. 37 is a structural diagram illustrating an RFID device according to a third embodiment of the present invention.

FIG. 38 is a structural diagram illustrating an RFID device according to a fourth embodiment of the present invention.

FIG. 39 is a detailed circuit diagram illustrating a slot counter controller shown in FIGS. 37 and 38.

FIG. 40 is a structural diagram illustrating an Input/Output (I/O) pad used in testing the RFID tag shown in FIGS. 37 and 38.

FIG. 41 is a timing diagram illustrating operations of a slot counter controller shown in FIGS. 37 and 38.

FIG. 42 is a timing diagram illustrating that a plurality of RFID tags shown in FIGS. 37 and 38 are sequentially activated.

FIG. 43 is a flowchart illustrating a method for testing a plurality of RFID tags shown in FIGS. 37 and 38.

FIG. 44 is a circuit diagram illustrating a test input buffer shown in FIGS. 37 and 38.

FIGS. 45 and 46 are timing diagrams illustrating operations of a test input buffer shown in FIG. 44.

FIG. 47 is a circuit diagram illustrating a test output driver shown in FIGS. 37 and 38.

FIG. 48 is a timing diagram illustrating operations of a test output driver shown in FIG. 47.

FIG. 49 is a structural diagram illustrating an RFID device according to a fifth embodiment of the present invention.

FIG. 50 is a structural diagram illustrating an RFID device according to a sixth embodiment of the present invention.

FIG. 51 is a detailed circuit diagram illustrating a shift register shown in FIGS. 49 and 50.

FIG. 52 is a structural diagram illustrating an Input/Output (I/O) pad used for testing the RFID device shown in FIGS. 37 and 38.

FIG. 53 is a timing diagram illustrating operations of a shift register shown in FIG. 51.

FIG. 54 is a timing diagram illustrating that a plurality of RFID tags shown in FIGS. 49 and 50 are sequentially activated.

FIGS. 55 and 56 are flowcharts illustrating methods for testing a plurality of RFID tags contained in an RFID tag array shown in FIGS. 49 and 50.

FIG. 57 is a detailed circuit diagram illustrating a test input buffer shown in FIGS. 49 and 50, and FIGS. 58 and 59 are timing diagrams illustrating operations of the test input buffer.

FIG. 60 is a detailed block diagram illustrating an I/O circuit unit shown in FIG. 52.

FIGS. 61 and 62 are a detailed circuit diagram and a timing diagram of a test output driver shown in FIGS. 49 and 50, respectively.

FIGS. 63 and 64 are a detailed circuit diagram and a timing diagram of a control output driver shown in FIGS. 49 and 50, respectively.

FIG. 65 is a circuit diagram illustrating an address I/O unit shown in FIG. 60.

FIG. 66 is a detailed circuit diagram illustrating a data I/O unit shown in FIG. 60.

FIG. 67 is a detailed circuit diagram illustrating a control signal I/O unit shown in FIG. 60.

FIG. 68 is a detailed circuit diagram illustrating the control signal I/O unit shown in FIG. 60.

FIG. 69 is a circuit diagram illustrating an electrostatic protection unit shown in FIG. 52.

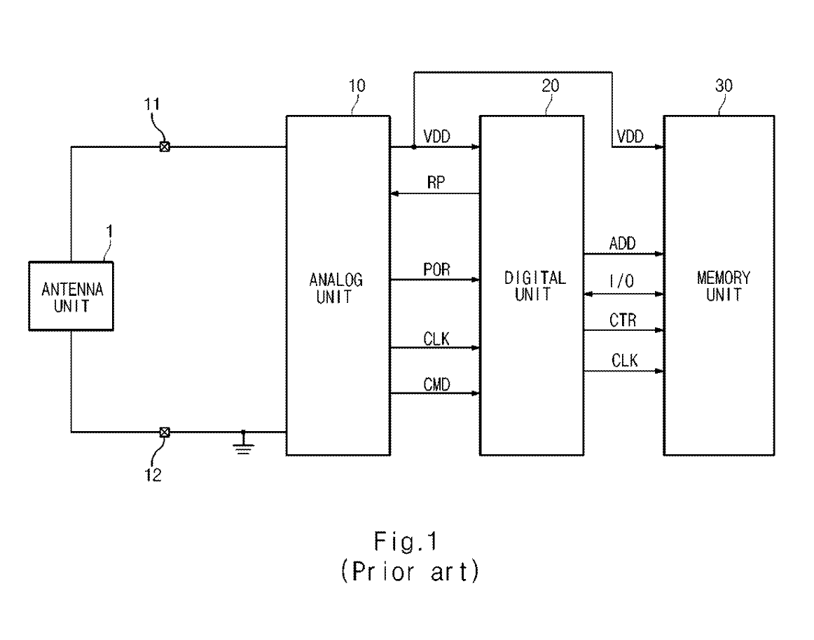

### DESCRIPTION OF EMBODIMENTS

Reference will now be made in detail to the embodiments of the present invention, examples of which are illustrated in the accompanying drawings. Wherever possible, the same reference numbers will be used throughout the drawings to refer to the same or like parts.

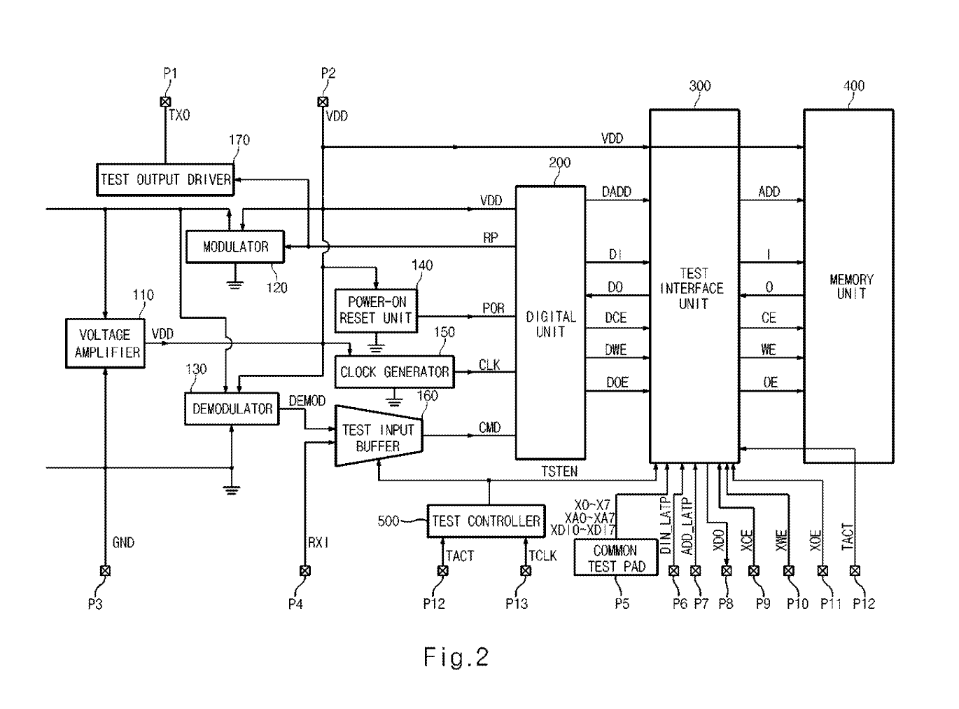

FIG. 2 is a structural diagram illustrating a Radio Frequency Identification (RFID) tag chip for use in an RFID device according to an embodiment of the present invention. In the present embodiment, a plurality of pads P1, P2 . . . P13 is provided in a test chip.

In an embodiment of the present invention, a measurement signal is sent via a common test pad (i.e., without receiving a Radio Frequency (RF) signal via an antenna) while the chip is still on the wafer, such that a performance or throughput of an RFID tag chip can be easily tested.

The RFID device according to this embodiment of the present invention includes a voltage amplifier 110, a modulator 120, a demodulator 130, a power-on reset unit 140, a clock generator 150, a test input buffer 160, a test output driver 170, a digital unit 200, a test interface unit 300, a memory unit 400, and a test controller 500.

In this case, the voltage amplifier 110 generates an RFID drive voltage in response to a power-supply voltage VDD received from a power-supply voltage applying pad P2. The modulator 120 modulates a response signal RP received from the digital unit 200. The demodulator 130 generates an operation command signal DEMOD in response to the output voltage of the power-supply voltage applying pad P2, and outputs the generated operation command signal DEMOD to the test input buffer 160.

The power-on reset unit 140 detects a voltage received from the power-supply voltage applying pad P2, and outputs a power-on reset signal POR to the digital unit 200 so as to control a reset operation in response to the detected voltage. The clock generator 150 outputs a clock CLK to the digital unit 200, wherein the clock CLK is capable of controlling operations of the digital unit 200 in response to the output voltage of the power-supply voltage applying pad P2.

In this case, detailed operations of the power-on reset signal POR are as follows. While the power-on reset signal POR increases simultaneously with a power-supply voltage during a transition time in which the power-supply voltage changes from a low level to a high level, as soon as the power-supply voltage VDD reaches its operating level, the power-on reset signal POR is changed from a high level to a low level. The power-on reset signal POR remains high sufficiently long enough to reset a circuit included in the RFID tag.

The test input buffer 160 receives a test input signal RX1 from a test signal input pad P4, receives an operation command signal DEMOD from the demodulator 130, receives a test activation signal TSTEN from the test controller 500, and outputs a command signal CMD to the digital unit 200 in response to the received signals.

In other words, when the test activation signal TSTEN is deactivated in a normal operation mode, the test input buffer 160 outputs the command signal CMD to the digital unit 200 in response to the operation command signal DEMOD received from the demodulator 130. On the other hand, when the test activation signal TSTEN is activated during a test operation mode, the test input buffer 160 outputs a command signal CMD, capable of testing an RFID tag in response to a test input signal RXI from a test signal input pad P4, to the digital unit 200.

The test output driver 170 drives the test output signal TXO in response to a response signal RP received from the digital unit 200, such that it outputs the result of a command executed on each RFID tag to an external device (or external node) via the test signal output pad P1. As used herein, “external device” or “external node” refers to a location outside of the component or the device being discussed. For example, an external node of a tag chip is any node outside of the tag chip.

In this case, the voltage amplifier 110, the modulator 120, the demodulator 130, the power-on reset unit 140, the clock generator 150, the test input buffer 160, and the test output driver 170 are driven by a power-supply voltage VDD received from an external power-supply voltage applying pad P2 and a ground voltage GND received from an external ground voltage applying pad P3 during a test operation mode for testing RFID performance.

In other words, the power-supply voltage applying pad P2 is a pad which receives the power-supply voltage VDD when testing a plurality of RFID tags on a wafer. In addition, the ground voltage applying pad P3 is a pad which receives a ground voltage GND when testing a plurality of RFID tags on a wafer.

When the RFID tag receives an RF signal from the RFID reader by wirelessly communicating with the RFID reader, the voltage amplifier 110 can provide the power-supply voltage VDD. In contrast, because the RFID device shown in the embodiment of the present invention tests such RFID tags without the use of an RF signal, it receives the power-supply voltage VDD and the ground voltage GND via an additional power-supply voltage applying pad P2 and an additional ground voltage applying pad P3, respectively.

The digital unit 200 receives a power-supply voltage VDD, a power-on reset signal POR, a clock CLK, and a command signal CMD, analyzes the command signal CMD, and generates a control signal and process signals. The digital unit 200 outputs a response signal RP corresponding to the control and process signals to the modulator 120.

The digital unit 200 outputs an address DADD, data DI, a chip enable signal DCE, a write enable signal DWE, and an output enable signal DOE to the test interface unit 300. The digital unit 200 receives output data DO from the test interface unit 300.

The test interface unit 300 is activated by the test enable signal TSTEN received from the test controller 500. When the test interface unit 300 is activated, the test interface unit 300 receives tag selection addresses X0˜X7, memory addresses XA0˜XA7, input data XDI0˜XDI7, and control signals DIN_LATP, ADD_LATP, XCE, XWE, XOE, and TACT from an external device, and tests the memory unit 400 using the received information.

Among the above-mentioned control signals, DIN_LATP is a data latch activation signal, ADD_LATP is an address latch activation signal, and XCE is a chip enable signal. In addition, XWE is a write enable signal, XOE is an output enable signal, and TACT is a test operation signal.

In this case, the test interface unit 300 receives the tag selection addresses X0˜X7, memory addresses XA0˜XA7, and input data XDI0˜XDI7 via a common test pad P5. In response to control signals DIN_LATP, ADD_LATP, XCE, XWE, and XOE received via control signal input pads P6, P7, P9, P10, and P11, and another control signal TACT via the test input pad P12, the test interface unit 300 generates an address ADD, data I, and control signals CE, WE, and OE, such that it tests the memory unit 400 using the generated information. Also, the test interface unit 300 receives a control result signal O from the memory unit 400, and outputs output data XDO to an external device via a data output pad P8.

In the meantime, if the test interface unit 300 is activated, it tests an internal circuit of the RFID tag upon receiving the address DADD, data DI, and control signals DCE, DWE, and DOE from the digital unit 200. In this case, the internal circuit may include all of a voltage amplifier 110, a modulator 120, a demodulator 130, a power-on reset unit 140, a clock generator 150, a test input buffer 160, a test output driver 170, a digital unit 200, and a memory unit 400.

In order to test an overall operation of the RFID tag, the digital unit 200 generates an address DADD, data DI, and control signals DCE, DWE, and DOE in response to the command signal CMD generated by the test input signal RXI.

The test interface unit 300 generates an address ADD, data I, and control signals CE, WE, and OE in response to an address DADD, data DI, and control signals DCE, DWE, and DOE, such that it tests an overall operation of the RFID tag. The test interface unit 300 receives a control result signal O indicating a test result from the memory unit 400, and generates a control result signal DO.

The digital unit 200 generates a response signal RP in response to the control result signal DO. The test output driver 170 drives a test output signal TXO in response to the response signal RP, and outputs the test output signal TXO to the test output pad P1.

The memory unit 400 includes a plurality of memory cells, each of which writes and reads data to/from a storage unit. In this case, the memory unit 400 may be a non-volatile ferroelectric memory (FeRAM). The FeRAM has a data processing speed similar to that of DRAM. Also, the FeRAM has a structure very similar to that of DRAM, and uses a ferroelectric substance as a capacitor material so that it has high residual polarization characteristics. Due to the high residual polarization characteristics, data is not lost although an electric field is removed.

The test controller 500 selectively activates the RFID tag during a test mode. The test controller 500 receives the test operation signal TACT from the test input pad P12, and receives a test clock TCLK from the test clock input pad P13. The test controller 500 outputs a test activation signal TSTEN for controlling activation or deactivation of the RFID tag to the test input buffer 160 and the test interface unit 300.

As described above, in accordance with an embodiment of the present invention, if the test activation signal TSTEN is activated in the test mode, the test result of the RFID device may be transmitted to an external device via the test signal output pad P1 or the data output pad P8.

That is, if an overall operation of the RFID device is tested, a test input signal RXI received via a test signal input pad P4 is transferred to the digital unit 200, the test interface unit 300, and the memory unit 400. After that, the test input signal RXI is output via the test output pad P1 after passing through the test interface unit 300, the digital unit 200, and the test output driver 170. As a result, the external test device measures an output of the test signal output pad P1, such that it can test an overall operation of the RFID device from the output.

On the other hand, in the case of testing only the memory unit 400 of the RFID device, addresses and data received via the common test pad P5 are transmitted to the memory unit 400 after passing through the test interface unit 300, and are then output via the data output pad P8 after passing through the test interface unit 300. As a result, the external test device measures an output of the test signal output pad P8, such that it can test an overall operation of the memory unit 400.

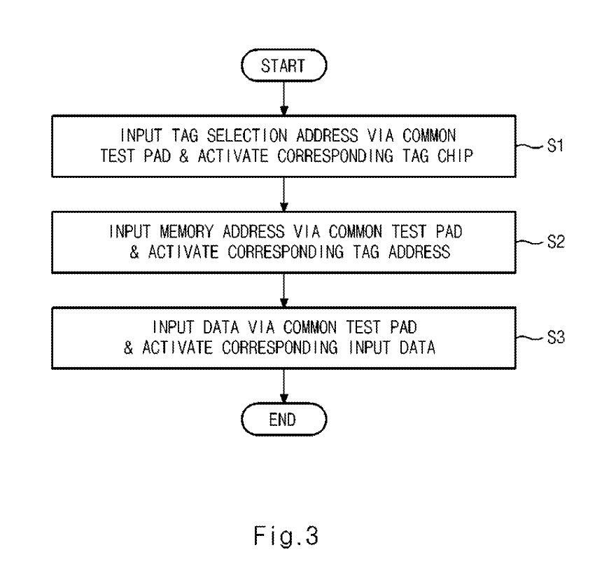

FIG. 3 is a flowchart illustrating a method for testing an RFID device according to an embodiment of the present invention.

Referring to FIG. 3, a tag selection address X is applied to the test interface unit 300 via a common test pad P5 such that a corresponding tag chip is activated at step S1. Next, a memory address XA is applied to the test interface unit 300 via the common test pad P5, and a corresponding address is then activated at step S2. After that, input data XDI is applied to the test interface unit 300 via the common test pad P5, and a corresponding address is then activated at step S3.

The above-mentioned embodiment of the present invention controls different input lines (i.e., a tag selection address X, a memory address XA, and input data XDI) via the common test pad P5 according to a time sharing scheme. The tag selection address X, the memory address XA, and the input data XDI are inputted at different times, such that it is able to test a performance or throughput of the RFID tag chip. As a result, the embodiment of the present invention is able to reduce not only the number of pads contained in a test chip but also the layout of the test chip.

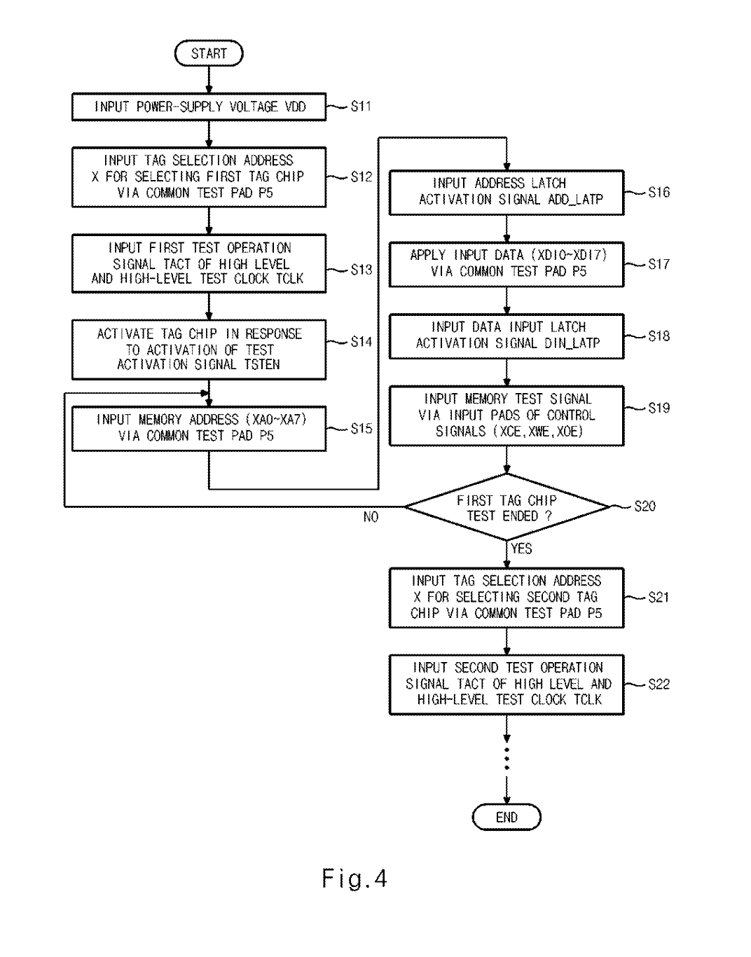

FIG. 4 is a flowchart illustrating a method for testing tag chips using the test interface unit 300 in the RFID device according to an embodiment of the present invention.

Referring to FIG. 4, if a power-supply voltage VDD is applied to the RFID device, the test chip is initialized so that it is firstly activated at step S11. A tag selection address X for selecting a first tag chip is applied to the test interface unit 300 via the common test pad P5 at step S12.

Thereafter, if a first test operation signal TACT of a high level and a first test clock TCLK of a high pulse are applied to the test interface unit 300, the test activation signal TSTEN is activated at step S13. Subsequently, if the test activation signal TSTEN is activated to a high level, a corresponding (i.e., selected) tag chip is activated at step S14.

Next, a memory address (any of XA0˜XA7) for selecting a corresponding address via the common test pad P5 is applied to the test interface unit 300 at step S15. Thereafter, the address latch activation signal ADD_LATP is applied to the test interface unit 300 via the pad P7 at step S16.

Subsequently, input data (any of XDI0˜XDI7) is applied to the interface unit 300 via the common test pad P5 at step S17. In this case, the output data XDO is output via the data output pad P8.

A data latch activation signal DIN_LATP is applied to the test interface unit 300 via the pad P6 at step S18. After that, a memory test signal is applied to the test interface unit 300 via input pads P9˜P11 of a chip enable signal XCE, a write enable signal XWE, and an output enable signal XOE at step S19.

It is determined whether a test operation of a first tag chip is completed at step S20. If the test operation of the first tag chip has completed at step S20, a tag selection address X for selecting a second tag chip via the common test pad P5 is applied to the test interface unit 300 at step S21. Next, a second test operation signal TACT of a high level and a second test clock TCLK of a high pulse are applied to the test interface unit 300 at step S22. Thereafter, the above-mentioned test operations are repeated until the last tag chip is activated and completely tested.

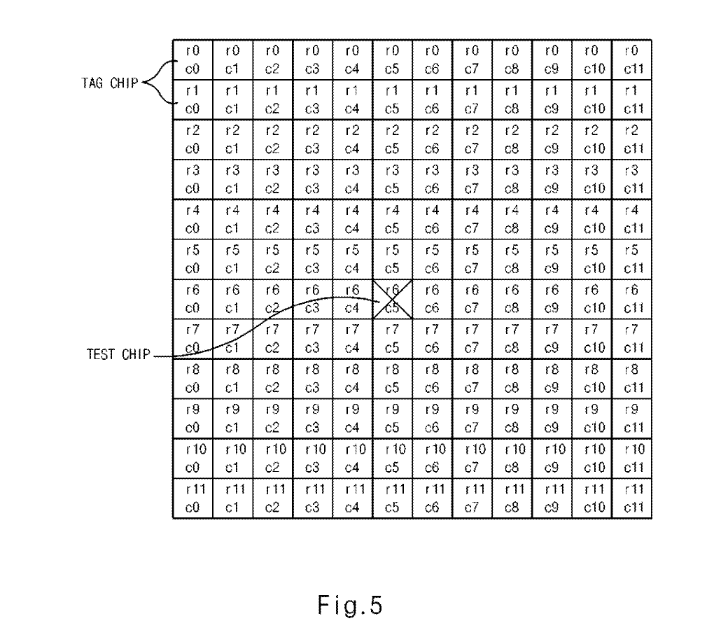

FIG. 5 is an arrangement structure illustrating that a test chip and a tag chip are arranged on a wafer of the RFID device shown in FIG. 2 according to the embodiment of the present invention.

Referring to FIG. 5, a plurality of tag chips is formed in row and column directions on one wafer, such that a tag chip array is formed. Each tag chip array includes a plurality of tag chips. That is, the tag chip array indicates a set of RFID tag chips interconnected via scribe lanes (i.e., the interconnection wires are disposed in the scribe lanes).

A single tag chip array includes a single test chip and a plurality of tag chips. In this case, a single test chip may be arranged at the center of the tag chip array. The single test chip tests all the tag chips arranged on a corresponding tag chip array, such that it is able to reduce time and cost required for the test.

As used herein, the term “radio frequency identification device” or “RFID device” refers to a device or product that includes one or more test chips and one or more tags chips. For example, the term “RFID device” may refer to the entire wafer including one or more test chips and a plurality of tag chips, or may refer to a section of a wafer including a test chip and one or more tag chips that have not been diced and separated into individual chips.

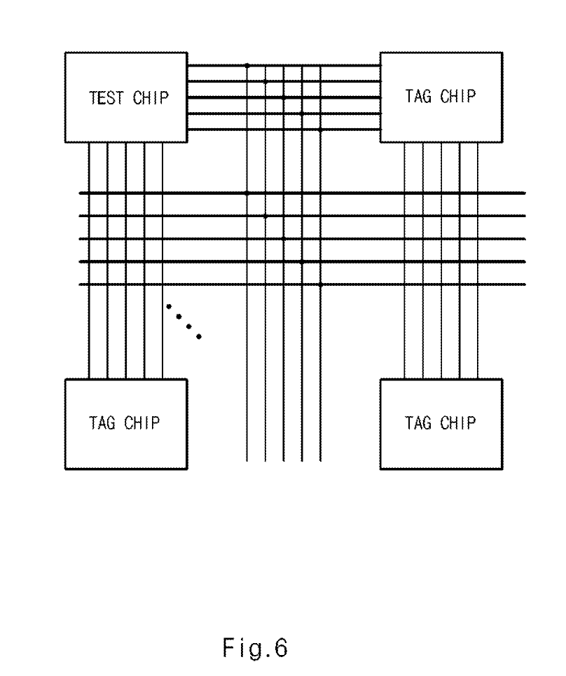

FIG. 6 is a structural diagram illustrating that a test chip is coupled to tag chips via scribe lanes in the RFID device shown in FIG. 2. In the present embodiment, the test chip is coupled to one or more tag chips via one or more interconnects (or data bus) formed in the scribe lanes (or scribe regions) to transmit information needed to test the tag chips.

Referring to FIG. 6, a single tag chip array includes one test chip and a plurality of tag chips. In FIG. 6, I/O signals indicating a test command and a test result are exchanged between the test chip and the tag chips via scribe lanes formed among the tag chips. That is, the test chip and the tag chips are coupled to each other via a plurality of scribe lanes arranged in X- and Y-axis directions.

Therefore, a power-supply voltage VDD, a ground voltage GND, a control signal, an address and data, which have been received from an external device, are applied to an internal circuit of each tag chip via I/O pads of the tag chip after passing through a plurality of scribe lanes arranged in X- and Y-axis directions. However, the test output signal TXO, the control result signal, etc. generated from the tag chip are transmitted to an external device via a plurality of scribe lanes arranged in X- and Y-axis directions before passing through I/O pads of the test chip.

In this case, in order to test a tag chip array, a test chip is initialized. A variety of methods may be used to initialize the test chip. For example, if the power-supply voltage VDD is received via an I/O pad, initialization of the test chip may be established as necessary.

The above-mentioned embodiment shown in FIG. 6 allows test commands and I/O data to be exchanged a with a plurality of tag chips using only one test chip via scribe lanes, resulting in a reduction in layout area.

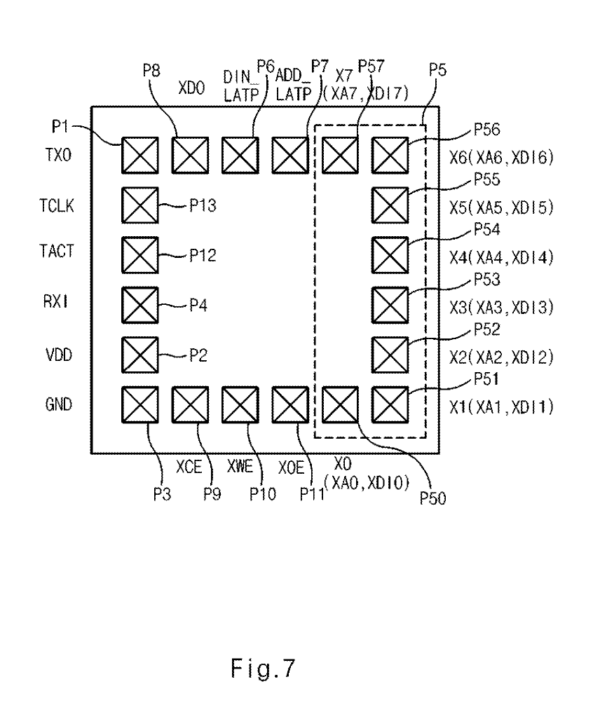

FIG. 7 is a structural diagram illustrating pads of a test chip for use in an RFID device according to an embodiment of the present invention.

The test chip includes a common test pad P5 to which tag selection addresses X0˜X7, memory addresses XA0˜XA7, and input data XDI0˜XDI7 are commonly input according to a time sharing scheme. In this case, the common test pad P5 includes common input pads P50˜P57 that respectively input tag selection addresses X0˜X7, memory addresses XA0˜XA7, and input data XDI0˜XDI7 to the test interface unit 300.

The test chip further includes a test signal output pad P1 for outputting a test output signal TXO to an external device, a power-supply voltage applying pad P2 for receiving a power-supply voltage VDD, and a ground voltage applying pad P3 for receiving a ground voltage GND. Further, the test chip includes a test signal input pad P4 for receiving a test input signal RXI, a pad P6 for receiving a data latch activation signal DIN_LATP, and a pad P7 for receiving an address latch activation signal ADD_LATP. The test chip further includes a data output pad P8 for outputting output data XDO indicating the control result signal, a pad P9 for receiving a chip enable signal XCE, a pad P10 for receiving a write enable signal XWE, and a pad P11 for receiving an output enable signal XOE. In addition, the test chip includes a test input pad P12 for receiving a test operation signal TACT, and a test clock input pad P13 for receiving a test clock TCLK.

The above-mentioned embodiment shown in FIG. 7 is designed to receive all of tag selection addresses X0˜X7 for tag chip selection, memory addresses XA0˜XA7, and input data XDI0˜XDI7 via the common test pad P5, such that the number of pads contained in a test chip and the layout of the test chip can be reduced.

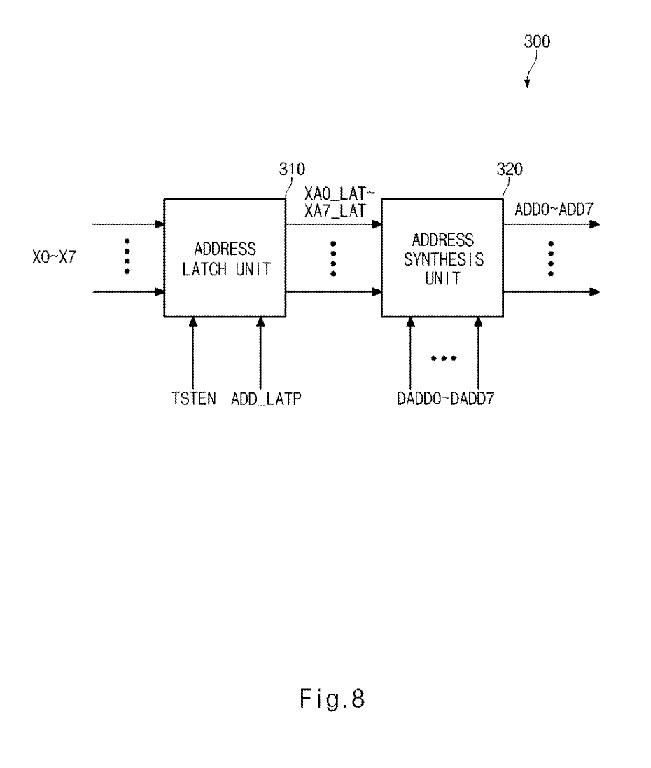

FIG. 8 is a detailed circuit diagram of the test interface unit 300 related to an address latch operation of an RFID device according to an embodiment of the present invention. For convenience of description, an exemplary case that tag selection addresses X0˜X7 are applied to the test interface unit 300 will hereinafter be described.

Referring to FIG. 8, the test interface unit 300 includes an address latch unit 310 and an address synthesis unit 320.

In this case, the address latch unit 310 receives tag selection addresses X0˜X7 from the common test pad P5 when the test activation signal TSTEN is activated. The address latch unit 310 latches the tag selection addresses X0˜X7 in response to the activation of the address latch activation signal ADD_LATP, and outputs the latched addresses XA0_LAT˜XA7_LAT.

The address synthesis unit 320 synthesizes latched addresses XA0_LAT to XA7_LAT and other addresses DADD0 to DADD7 received from the digital unit 200, and outputs the resultant addresses ADD0 to ADD7 to the memory unit 400.

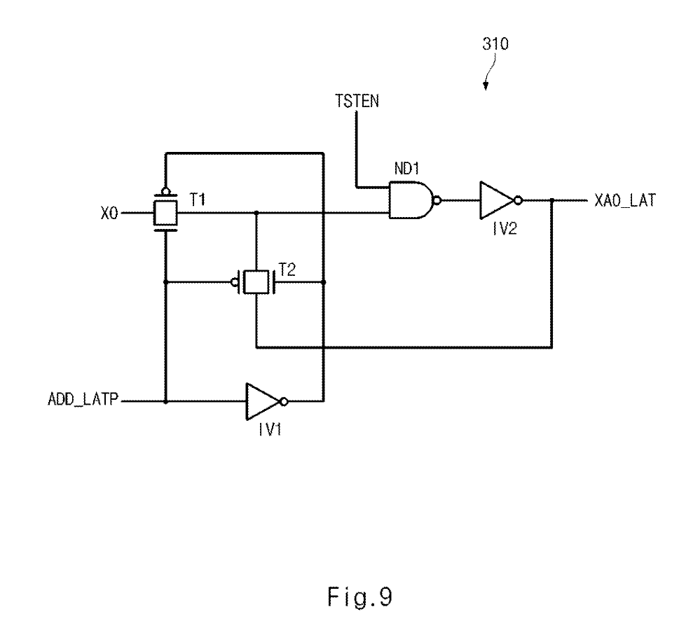

FIG. 9 is a detailed circuit diagram of the address latch unit 310 shown in FIG. 8.

Referring to FIG. 9, the address latch unit 310 includes transfer gates T1 and T2, a NAND gate ND1, and inverters IV1 and IV2.

In this case, the transfer gate T1 passes a tag selection address X0 when an address latch activation signal ADD_LATP is activated. On the other hand, the transfer gate T2 latches a tag selection address X0 when the address latch activation signal ADD_LATP is deactivated and TSTEN is activated. In addition, the NAND gate ND1 and the inverter IV2 output the latched address XA0_LAT when the test activation signal TSTEN is activated. If the test activation signal TSTEN is deactivated to a low level, the latched address XA0_LAT becomes low in level.

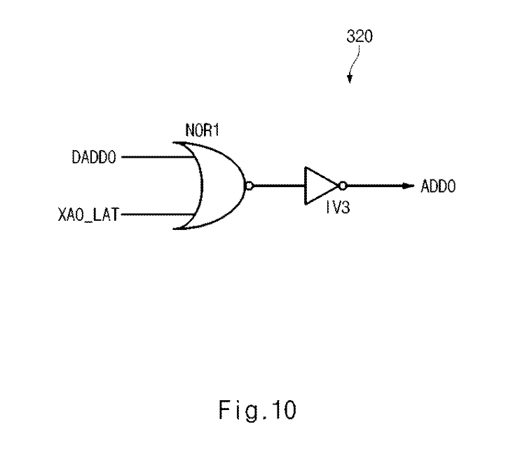

FIG. 10 is a detailed circuit diagram illustrating the address synthesis unit 320 shown in FIG. 8.

Referring to FIG. 10, the address synthesis unit 320 includes a NOR gate NOR1 and an inverter IV3. In this case, the NOR gate NOR1 performs a NOR operation on both an address DADD0 from the digital unit 200 and a latched address XA0_LAT, and outputs the NOR-operation result. The inverter IV3 inverts the output of the NOR gate NOR1 and outputs an address ADD0.

The above-mentioned address synthesis unit 320 performs a logic OR operation on both an address DADD0 and a latched address XA0_LAT, such that an address ADD0 can be activated when at least one of the two addresses DADD0 and XA0_LAT is activated.

In other words, if the test input signal RXI is activated in an overall RFID test operation, an internal address ADD0 is generated in response to an internal address DADD0 received via the digital unit 200. In this case, the test interface unit 300 generates internal control signals CE, WE, and OE in response to control signals DCE, DWE, and DOE received from the digital unit 200.

On the other hand, if a tag selection address X0 received via the common test pad P5 is activated in a test operation of the memory unit 400, an internal address ADD0 is generated in response to a latched address XA0_LAT. In this case, the test interface unit 300 generates internal control signals CE, WE, and OE in response to external control signals XCE, XWE, and XOE received via the pads P9˜P11.

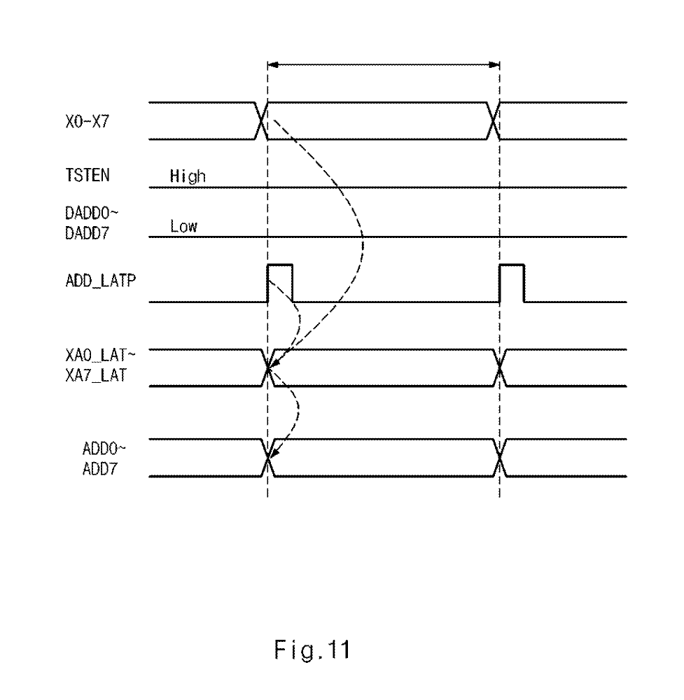

FIG. 11 is a waveform diagram illustrating operations of the test interface unit 300 shown in FIG. 8 in association with the address latch operation.

Referring to FIG. 11, tag selection addresses X0˜X7 are applied to the test interface unit 300 via the common test pad P5. In this case, in order to test the memory unit 400, the test activation signal TSTEN is activated to a high level, so that the high-level test activation signal TSTEN is maintained. If the address latch activation signal ADD_LATP is activated to a high level, the address latch unit 310 latches the tag selection addresses X0˜X7, and outputs the latched addresses XA0_LAT˜XA7_LAT.

If the digital unit 200 is not operated, the addresses DADD0 to DADD7 are set to a logic low level, such that the latched addresses XA0_LAT˜XA7_LAT are output as addresses ADD0˜ADD7 without any change.

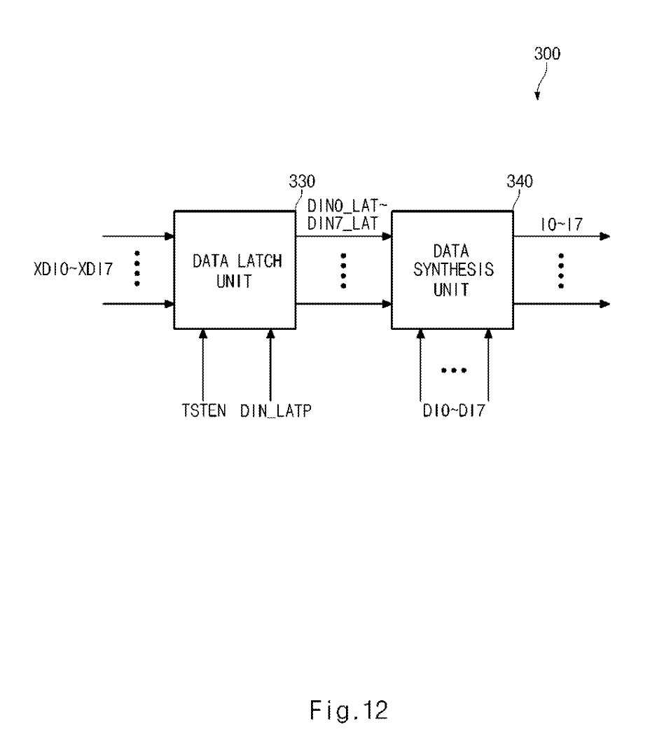

FIG. 12 is a detailed circuit diagram illustrating the test interface unit 300 related to an input data latch operation of the RFID device according to an embodiment of the present invention. For convenience of description, an exemplary case that input data XDI0˜XDI7 is applied to the test interface unit 300 will hereinafter be described. Referring to FIG. 12, the test interface unit 300 includes a data latch unit 330 and a data synthesis unit 340.

In this case, the data latch unit 330 receives input data XDI0˜XDI7 from the common test pad P5 when the test activation signal TSTEN is activated. The data latch unit 330 latches the input data XDI0˜XDI7 in response to the activation of the data latch activation signal DIN_LATP, and outputs the latched data DIN0_LAT˜DIN7_LAT. The data synthesis unit 340 synthesizes latched data DIN0_LAT˜DIN7_LAT and other data DI0˜DI7 received from the digital unit 200, and outputs the resultant input data I0˜I7 to the memory unit 400.

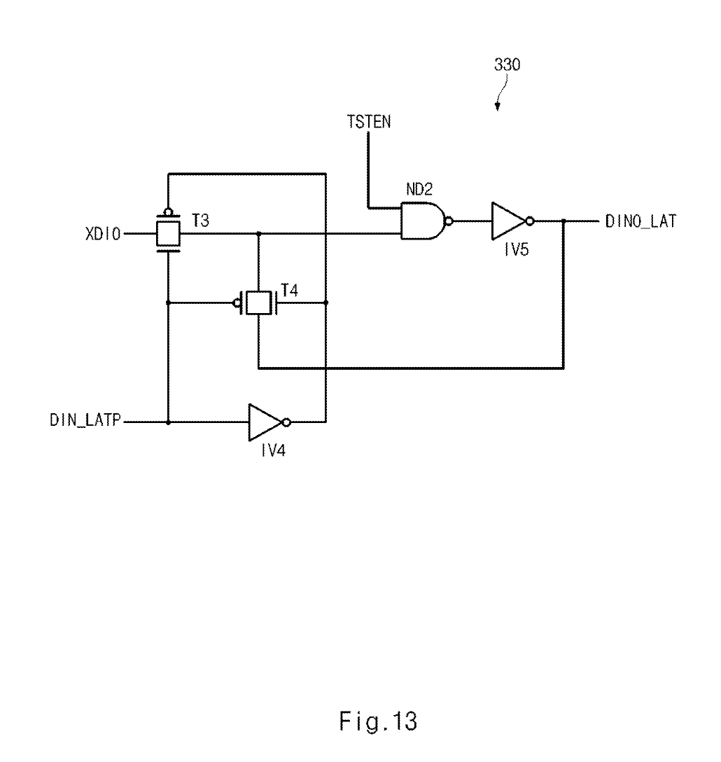

FIG. 13 is a detailed circuit diagram of the data latch unit 330 shown in FIG. 12. Referring to FIG. 13, the address latch unit 330 includes transfer gates T3 and T4, a NAND gate ND2, and inverters IV4 and IV5.

In this case, the transfer gate T3 passes data XDI0 when a data latch activation signal DIN_LATP is activated. On the other hand, the transfer gate T4 allows data XDI0 to be latched when the data latch activation signal DIN_LATP is deactivated and TSTEN is activated. In addition, the NAND gate ND2 and the inverter IV5 output the latched data DIN0_LAT when the test activation signal TSTEN is activated. If the test activation signal TSTEN is deactivated to a low level, the latched data DIN0_LAT becomes low in level.

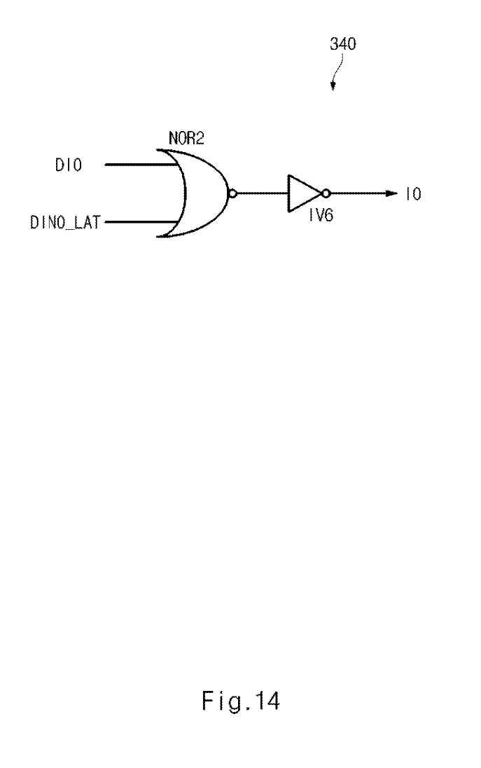

FIG. 14 is a detailed circuit diagram illustrating the data synthesis unit 340 shown in FIG. 12.

Referring to FIG. 14, the data synthesis unit 340 includes a NOR gate NOR2 and an inverter IV6. In this case, the NOR gate NOR2 performs a NOR operation on both data DI0 from the digital unit 200 and latched data DIN0_LAT, and outputs the NOR-operation result. The inverter IV6 inverts the output of the NOR gate NOR2 and outputs data I0. The above-mentioned data synthesis unit 340 performs a logic OR operation on both input data XDI0 and latched data DIN0_LAT, such that data I0 can be activated when at least one of the two data XDI0 and DIN0_LAT is activated.

In other words, if the test input signal RXI is activated in an overall RFID test operation, input data I0 is generated in response to internal data DI0 received via the digital unit 200. On the other hand, if input data XDI0 received via the common test pad P5 is activated in a test operation of the memory unit 400, input data I0 is generated in response to latched data DIN0_LAT.

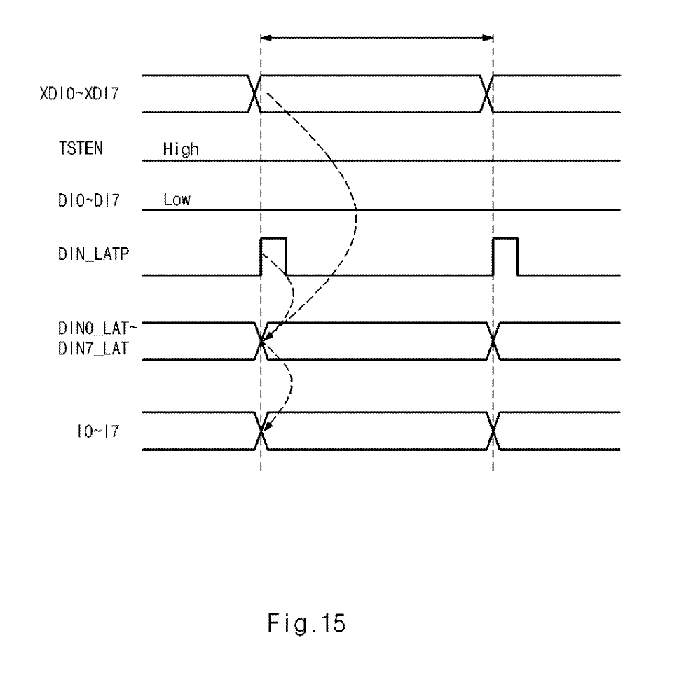

FIG. 15 is a waveform diagram illustrating operations of the test interface unit 300 shown in FIG. 12.

Referring to FIG. 15, input data XDI0˜XDI7 is applied to the test interface unit 300 via the common test pad P5. In this case, the test activation signal TSTEN is activated to a high level, so that the high-level test activation signal TSTEN is maintained. If the data latch activation signal DIN_LATP is activated to a high level, the data latch unit 330 latches the input data XDI0˜XDI7, and outputs the latched addresses DIN0_LAT˜DIN7_LAT. If the digital unit 200 is not operated, data DI0˜DI7 is set to a logic low level, such that the latched data DIN0_LAT˜DIN7_LAT is output as data I0˜I7 without any change.

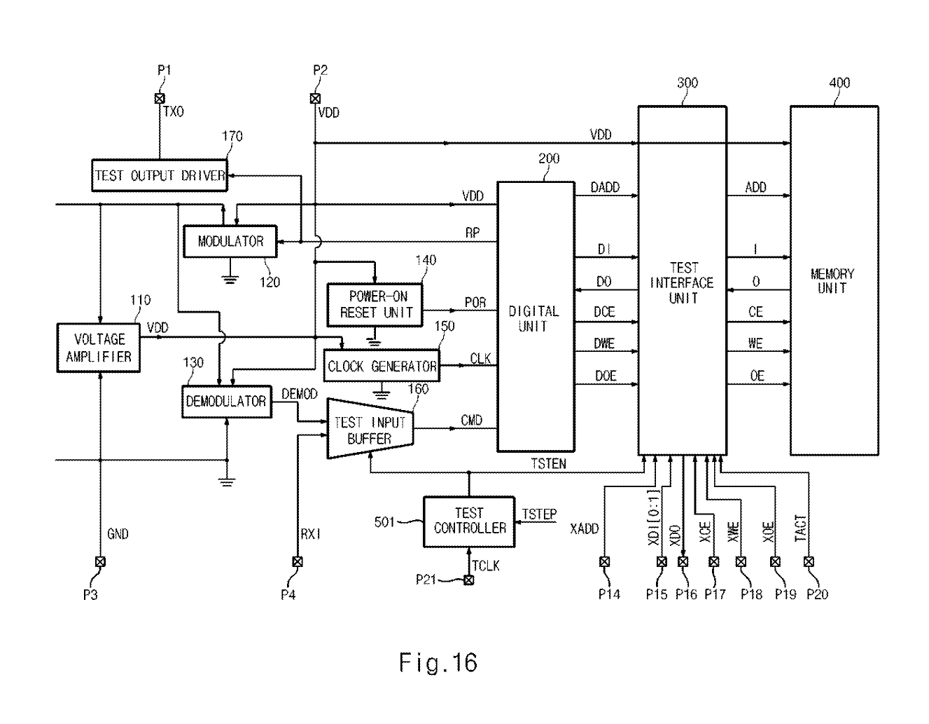

FIG. 16 is a structural diagram illustrating an RFID device according to a second embodiment of the present invention.

In an embodiment of the present invention, a measurement signal is directly received from a wafer level via a common test pad without receiving an RF signal via an antenna, such that a performance or throughput of an RFID tag chip can be easily tested.

The RFID device according to the second embodiment of the present invention includes a voltage amplifier 110, a modulator 120, a demodulator 130, a power-on reset unit 140, a clock generator 150, a test input buffer 160, a test output driver 170, a digital unit 200, a test interface unit 300, a memory unit 400, and a test controller 501.

In this case, the voltage amplifier 110 generates an RFID-tag drive voltage in response to a power-supply voltage VDD received from a power-supply voltage applying pad P2. The modulator 120 modulates a response signal RP received from the digital unit 200. The demodulator 130 generates an operation command signal DEMOD in response to the output voltage of the power-supply voltage applying pad P2, and outputs the generated operation command signal DEMOD to the test input buffer 160.

The power-on reset unit 140 detects a voltage received from the power-supply voltage applying pad P2, and outputs a power-on reset signal POR to the digital unit 200 so as to control a reset operation in response to the detected voltage. The clock generator 150 outputs a clock CLK to the digital unit 200, wherein the clock CLK is capable of controlling operations of the digital unit 200 in response to the output voltage of the power-supply voltage applying pad P2.

The test input buffer 160 receives a test input signal RX1 from a test signal input pad P4, receives an operation command signal DEMOD from the demodulator 130, receives a test activation signal TSTEN from the test controller 500, and outputs a command signal CMD to the digital unit 200 in response to the received signals.

In other words, when the test activation signal TSTEN is deactivated during a normal operation mode, the test input buffer 160 outputs the command signal CMD to the digital unit 200 in response to the operation command signal DEMOD received from the demodulator 130. On the other hand, when the test activation signal TSTEN is activated during a test operation mode, the test input buffer 160 outputs a command signal CMD, capable of testing an RFID tag in response to a test input signal RXI from a test signal input pad P4, to the digital unit 200.

The test output driver 170 drives the test output signal TXO in response to a response signal RP received from the digital unit 200, such that it outputs the result of a command executed on each RFID tag to an external device via the test signal output pad P1.

In this case, the voltage amplifier 110, the modulator 120, the demodulator 130, the power-on reset unit 140, the clock generator 150, the test input buffer 160, and the test output driver 170 are driven by a power-supply voltage VDD received from an external power-supply voltage applying pad P2 and a ground voltage GND received from an external ground voltage applying pad P3 during a test operation mode for testing RFID performance.

In other words, the power-supply voltage applying pad P2 is a pad which receives the power-supply voltage VDD when testing a plurality of RFID tags on a wafer by activating respective RFID tags. In addition, the ground voltage applying pad P3 is a pad which receives a ground voltage GND when testing a plurality of RFID tags on a wafer.

In other words, if the RFID tag receives an RF signal from the RFID reader by wirelessly communicating with the RFID reader, the voltage amplifier 110 provides the power-supply voltage VDD. In contrast, because the RFID device shown in the embodiment of the present invention tests such RFID tags on a wafer, it receives the power-supply voltage VDD and the ground voltage GND via an additional power-supply voltage applying pad P2 and an additional ground voltage applying pad P3, respectively.

The digital unit 200 receives a power-supply voltage VDD, a power-on reset signal POR, a clock CLK, and a command signal CMD, analyzes the command signal CMD, and generates a control signal and process signals. The digital unit 200 outputs a response signal RP corresponding to the control and process signals to the modulator 120.

The digital unit 200 outputs an address DADD, data DI, a chip enable signal DCE, a write enable signal DWE, and an output enable signal DOE to the test interface unit 300. The digital unit 200 receives output data DO from the test interface unit 300.

The test interface unit 300 is activated by the test enable signal TSTEN received from the test controller 500. When the test interface unit 300 is activated, the test interface unit 300 receives addresses XADD, input data XDI[0:1], and control signals XCE, XWE, XOE, and TACT from an external device, and tests the memory unit 400 using the received information. Among the above-mentioned control signals, XCE is a chip enable signal. In addition, XWE is a write enable signal, XOE is an output enable signal, and TACT is a test operation signal.

In this case, in response to the addresses XADD from the test pad P14, input data XDI[0:1] from the data input pad P15, and control signals XCE, XWE, XOE, and TACT from the control signal input pads P17˜P20, the test interface unit 300 generates addresses ADD, data I, and control signals CE, WE, and OE, such that it tests the memory unit 400 using the generated information. Also, the test interface unit 300 receives a control result signal O from the memory unit 400, and outputs output data XDO to an external device via a data output pad P16.

In the meantime, if the test interface unit 300 is activated, it tests an internal circuit of the RFID tag upon receiving the address DADD, data DI, and control signals DCE, DWE, and DOE from the digital unit 200.

In this case, the internal circuit may include all of a voltage amplifier 110, a modulator 120, a demodulator 130, a power-on reset unit 140, a clock generator 150, a test input buffer 160, a test output driver 170, a digital unit 200, and a memory unit 400.

In order to test an overall operation of the RFID tag, the digital unit 200 generates an address DADD, data DI, and control signals DCE, DWE, and DOE in response to the command signal CMD generated by the test input signal RXI.

The test interface unit 300 generates an address ADD, data I, and control signals CE, WE, and OE in response to an address DADD, data DI, and control signals DCE, DWE, and DOE, such that it tests an overall operation of the RFID tag. The test interface unit 300 receives a control result signal O indicating a test result from the memory unit 400, and generates a control result signal DO.

The digital unit 200 generates a response signal RP in response to the control result signal DO. The test output driver 170 operates a response signal RP, and outputs it to the test signal output pad P1.

The memory unit 400 includes a plurality of memory cells, each of which writes and reads data in/from a storage unit. In this case, the memory unit 400 may be a non-volatile ferroelectric memory (FeRAM). The FeRAM has a data processing speed similar to that of a DRAM. Also, the FeRAM has a structure very similar to that of the DRAM, and uses a ferroelectric substance as a capacitor material so that it has high residual polarization characteristics. Due to the high residual polarization characteristics, data is not lost although an electric field is removed.

The test controller 501 activates the RFID tag in a test mode. The test controller 501 receives a test control signal TSTEP, and receives a test clock TCLK from a test clock input pad P21. The test controller 501 outputs a test activation signal TSTEN for controlling activation or deactivation of the RFID tag to the test input buffer 160 and the test interface unit 300.

As described above, in accordance with an embodiment of the present invention, if the test activation signal TSTEN is activated in the test mode, the test result of the RFID device may be transmitted to an external device via the test signal output pad P1 or the data output pad P16.

That is, if an overall operation of the RFID device is tested, a test input signal RXI received via a test signal input pad P4 is transferred to the digital unit 200, the test interface unit 300, and the memory unit 400. After that, the test input signal RXI is output via the test output pad P1 after passing through the test interface unit 300, the digital unit 200, and the test output driver 170. As a result, the external test device measures an output of the test signal output pad P1, such that it can test an overall operation of the RFID device. On the other hand, in the case of testing only the memory unit 400 of the RFID device, the address XADD received via the test pad P14 is transmitted to the memory unit 400 via the test interface unit 300. As a result, the external test device measures an output of the test signal output pad P16, such that it can test an overall operation of the memory unit 400 in response to the measured output.

As described above, the method for testing tag chips in the RFID device according to the embodiment of the present invention can be classified into one method for utilizing a test input signal RXI and a test output signal TXO and another method for utilizing the test interface unit 300.

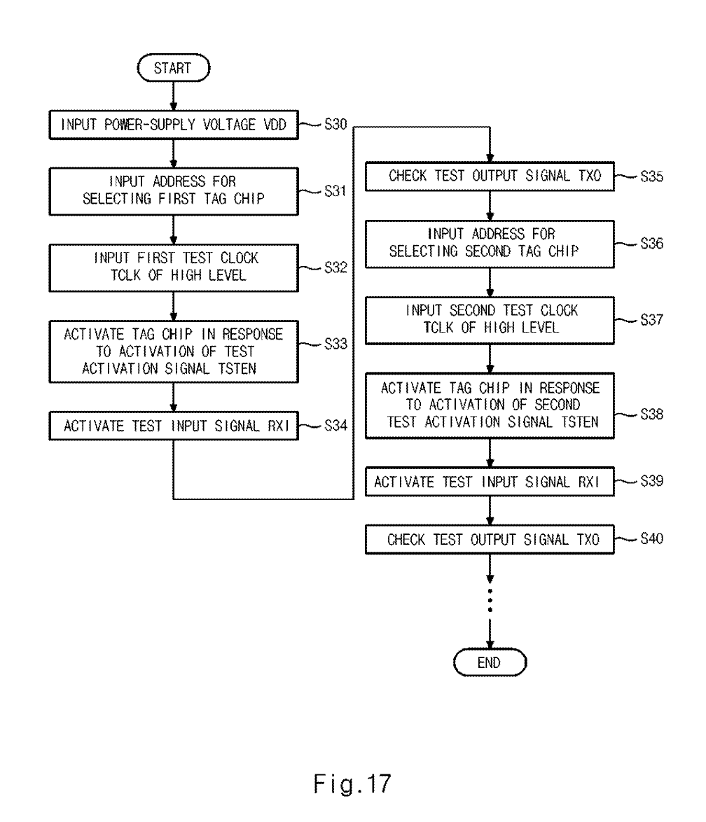

FIG. 17 is a flowchart illustrating the method for testing the tag chip using the test input signal RXI and the test output signal TXO.

Referring to FIG. 17, if a power-supply voltage VDD is applied to the RFID device, the test chip is initialized so that it is firstly activated at step S30. An address for selecting a first tag chip is applied to the test interface unit 300 via a test pad P14 at step S31.

Thereafter, if a first test clock TCLK of a high pulse is applied to the test interface unit 300, the test activation signal TSTEN is activated at step S32. Subsequently, if the test activation signal TSTEN is activated to a high level, a corresponding tag chip is activated at step S33.

Next, the test input signal RXI received via the test signal input pad P4 is activated at step S34. Accordingly, an external test device checks the test output signal TXO being output via the test signal output pad P1, such that it is able to test an overall operation of the RFID tag at step S35.

Then, an address for selecting a second tag chip is applied to the test interface unit 300 via the test pad P14 at step S36. Thereafter, if a second test clock TCLK of a high pulse is applied to the test interface unit 300, the test activation signal TSTEN is activated at step S37. Subsequently, if a second test activation signal TSTEN is activated to a high level, a corresponding tag chip is activated at step S38.

The test input signal RXI received via the test signal input pad P4 is then activated at step S39. Accordingly, an external test device checks the test output signal TXO being output via the test signal output pad P1, such that it is possible to test an overall operation of the RFID tag at step S45. Thereafter, the above-mentioned test operations are repeated until the last tag chip is activated and completely tested.

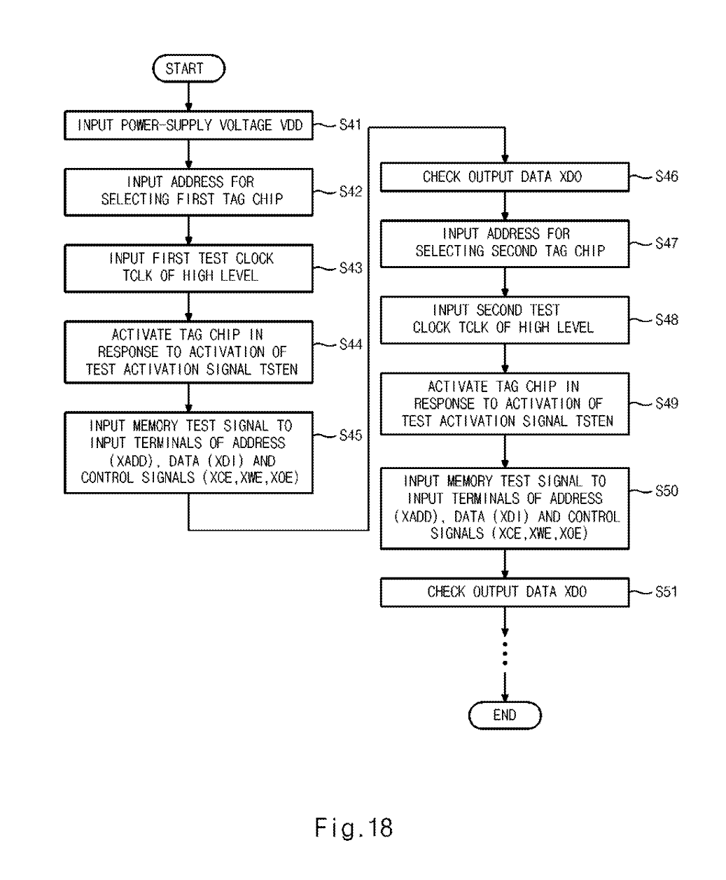

FIG. 18 is a flowchart illustrating a method for testing the memory unit 400 of a tag chip using the test interface unit 300 of the RFID device according to an embodiment of the present invention.

Referring to FIG. 18, if a power-supply voltage VDD is applied to the RFID device, the test chip is initialized so that it is firstly activated at step S40. An address for selecting a first tag chip is applied to the test interface unit 300 via the test pad P14 at step S42.

Thereafter, if a first test clock TCLK of a high pulse is applied to the test interface unit 300, the test activation signal TSTEN is activated at step S43. Subsequently, if the test activation signal TSTEN is activated to a high level, a corresponding tag chip is activated at step S44.

Next, an address XADD, input data XDI[0:1], and control signals XCE, XWE, and XOE are applied to the test interface unit 300 via a test pad P14, a data input pad P15, and control signal input pads P17˜P20, respectively, at step S45. In this case, output data XDO is output via the data output pad P16.

After that, an external test device checks output data XDO being output via the data output pad P16, such that it is possible to test an overall operation of the memory unit 400 of the RFID tag at step S46.

Then, an address for selecting a second tag chip is applied to the test interface unit 300 via the test pad P14 at step S47. Thereafter, if a second test clock TCLK of a high pulse is applied to the test interface unit 300, the test activation signal TSTEN is activated at step S48.

Subsequently, if a second test activation signal TSTEN is activated to a high level, a corresponding tag chip is activated at step S49.

Next, an address XADD, input data XDI[0:1], control signals XCE, XWE, and XOE are applied to the test interface unit 300 via the test pad P14, the data input pad P15, and the control signal input pads P17˜P20, respectively, at step S50.

After that, an external test device checks output data XDO being output via the data output pad P16, such that it is possible to test an overall operation of the memory unit 400 of the RFID tag at step S51.

Thereafter, the above-mentioned test operations are repeated until the last tag chip is activated and completely tested.

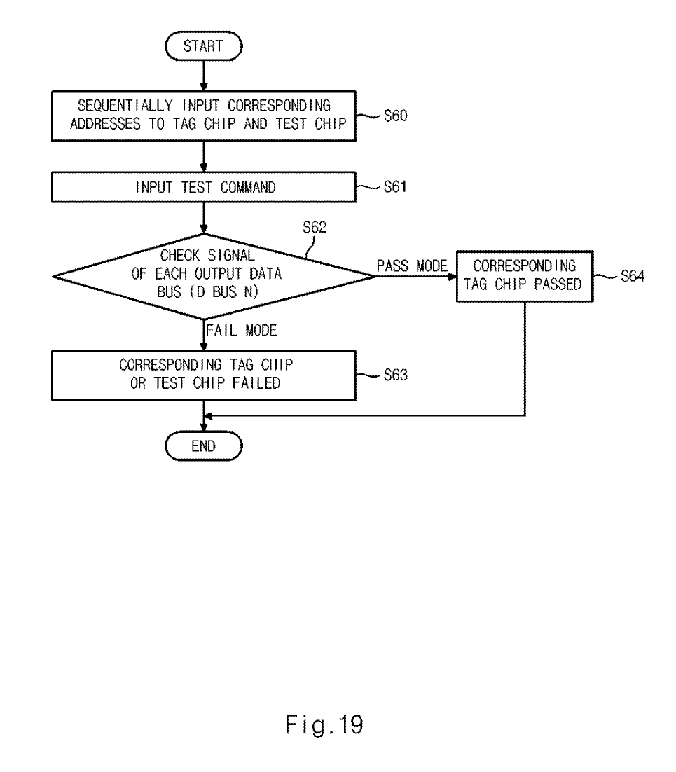

FIG. 19 is a flowchart illustrating a method for testing a tag chip and a test chip according to the test method for the RFID device shown in FIG. 16.

Referring to FIG. 19, corresponding addresses are sequentially applied to a test chip and tag chips at step S60. An external test device applies the same test command to both the tag chip and the test chip without discriminating between the tag chip and the test chip at step S61. Thereafter, if the test command is received, a signal status of an output data bus D_bus_n coupled to each tag chip is checked at step S62.

In this case, the test chip is established in such a manner that a status of the output data bus D_bus_n is in a failed mode. In other words, a corresponding data bus D_bus_n coupled to the test chip is pulled down by a pull-down driver PDD, such that a current status is automatically changed to a failed mode when testing the test chip. In this case, the test chip may be easily distinguished from the tag chip regardless of the location of the test chip itself.

Therefore, when checking a signal status of the output data bus D_bus_n, if a failed mode is decided, a corresponding tag chip or test chip is failed (or discarded) at step S63. In contrast, if a Pass mode is decided when checking the signal status of the output data bus D_bus_n, a corresponding tag chip is passed at step S64.

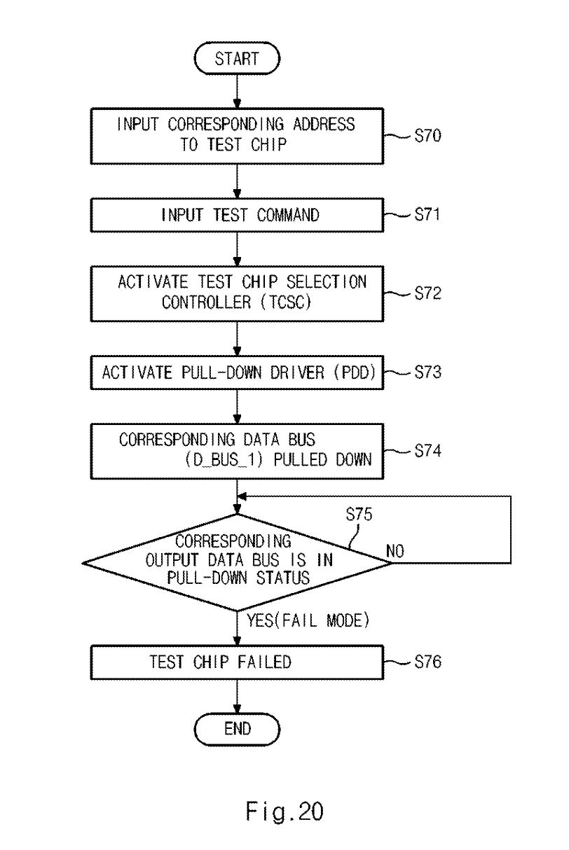

FIG. 20 is a flowchart illustrating an automatic fail recognition function performed when a test chip is tested in the test method of the RFID device according to an embodiment of the present invention.

Referring to FIG. 20, an address corresponding to a test chip is applied to the RFID device at step S70. Thereafter, the RFID device receives a test command from an external test device at step S71. A test chip selection controller TCSC for selecting a test chip is activated so that a selection signal TCSC_EN is enabled at step S72.

After that, if a pull-down driver PDD is activated by an enabled selection signal TCSC_EN at step S73, a corresponding data bus D_bus_1 coupled to the test chip is pulled down at step S74.

Then, it is determined whether a corresponding output data bus D_bus_1 is in a pull-down status or not at step S75. If the output data bus D_bus_1 is in the pull-down status, this status means a failed mode so that a corresponding test chip is failed at step S76.

In accordance with the above-mentioned embodiment of the present invention, if the test chip is selected in a test mode, a data bus D_bus_1 coupled to the test chip is pulled down, such that the test chip can be easily identified.

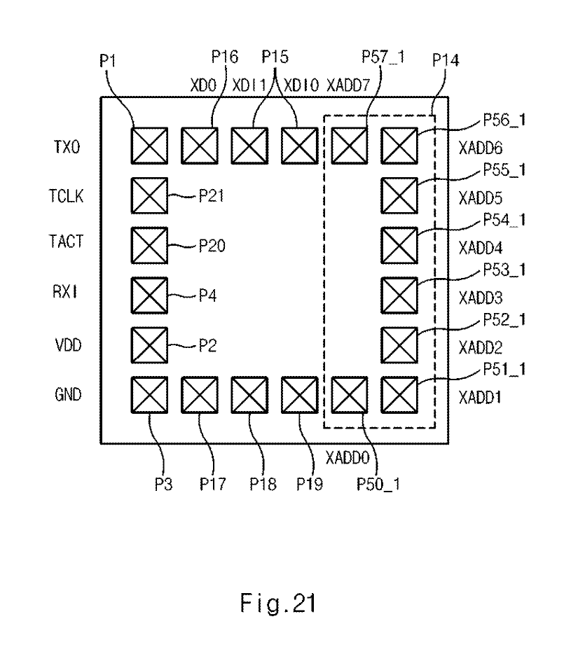

FIG. 21 is a structural diagram illustrating pads of a test chip for use in the RFID device according to an embodiment of the present invention.

Referring to FIG. 21, the test chip includes a test pad P14 to which an address XADD is input. In this case, the test pad P14 includes input pads P50_1˜P57_1 for receiving addresses XADD0˜XADD7, respectively.

The test chip further includes a test signal output pad P1 for outputting a test output signal TXO to an external device, a power-supply voltage applying pad P2 for receiving a power-supply voltage VDD, and a ground voltage applying pad P3 for receiving a ground voltage GND.

Further, the test chip includes a test signal input pad P4 for receiving a test input signal RXI, a pad P15 for receiving input data XDI[0:1], and a data output pad P16 for generating output data XDO. The test chip further includes a pad P17 for receiving a chip enable signal XCE, a pad P10 for receiving a write enable signal XWE, and a pad P18 for receiving an output enable signal XOE. In addition, the test chip includes a test input pad P20 for receiving a test operation signal TACT, and a test clock input pad P21 for receiving a test clock TCLK.

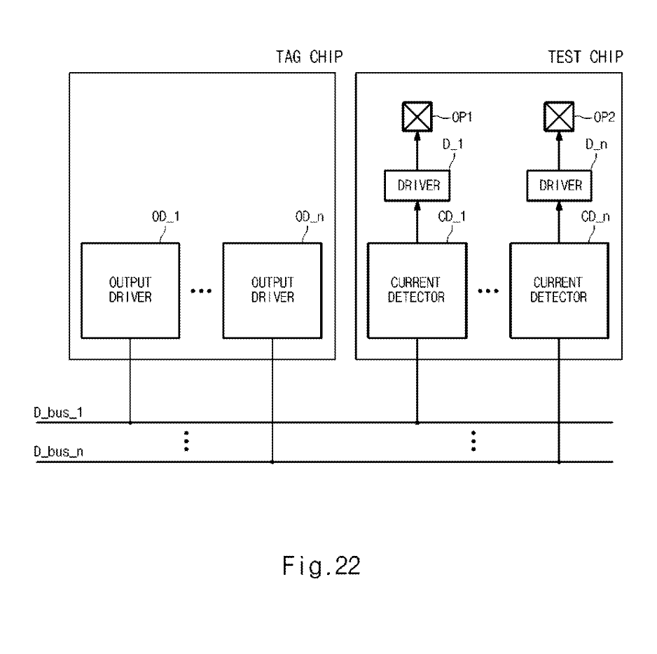

FIG. 22 is a detailed circuit diagram illustrating an output circuit of a tag chip and a test chip contained in the RFID device according to an embodiment of the present invention.

Referring to FIG. 22, the tag chip includes a plurality of output drivers OD_1˜OD_n. In this case, a plurality of output drivers OD_1˜OD_n is coupled to a plurality of data buses D_bus_1˜D_bus_n on a one to one basis. Preferably, the data buses D_bus_1˜D_bus_n may be formed on a scribe lane of a wafer.

For example, the data bus D_bus_1 indicates a bus for receiving output data XDO of the tag chip. The data bus D_bus_n is a bus for receiving the test output signal TXO of the tag chip. Each of output drivers OD_1˜OD_n is operated as a pull-down output driver based on an Open Drain scheme.

Therefore, if the output drivers OD_1˜OD_n are turned on, a predetermined pull-down current flows in the data buses D_bus_1˜D_bus_n. Otherwise, if the output drivers OD_1˜OD_n are turned off, a predetermined pull-down current not flows in the data buses D_bus_1˜D_bus_n, and it is possible to substantially prevent a current from flowing in the data buses D_bus_1˜D_bus_n.

The test chip includes a plurality of current detectors CD_1˜CD_n, a plurality of drivers D_1˜D_n, and output pads OP1 and OP2. In this case, the plurality of current detectors CD_1˜CD_n are coupled to a plurality of data buses D_bus_1˜D_bus_n on a one to one basis. The current detectors CD_1˜CD_n detect whether the output drivers OD_1˜OD_n of the tag chip are turned on in such a manner that a current flows therein, or the output drivers OD_1˜OD_n of the tag chip are turned off in such a manner that a current is blocked.

Further, a plurality of current detectors CD_1˜CD_n is coupled to a plurality of drivers on a one to one basis. The output pads OP1 and OP2 are coupled to a plurality of drivers D_1˜D_n on a one to one basis. In addition, the output drivers OD_1˜OD_n of the tag chip and the current detectors CD_1˜CD_n of the test chip are coupled to each other via the data buses D_bus_1˜D_bus_n.

Therefore, the output data of the OD_1˜OD_n of the tag chip is applied to the current detectors CD_1˜CD_n of the test chip via the data buses D_bus_1˜D_bus_n, respectively. The output signals of the current detectors CD_1˜CD_n are output externally via the output pads OP1 and OP2, respectively.

In this case, the output pad OP1 may be a data output pad P16 for generating output data XDO, and the other output pad OP2 may be a test signal output pad P1 for outputting the test output signal TXO.

The above-mentioned embodiment of the present invention controls the tag chip's output current received via the data buses D_bus_1˜D_bus_n so as to externally output the failed status of the tag and test chips, such that the test operation is facilitated and a test time is reduced.

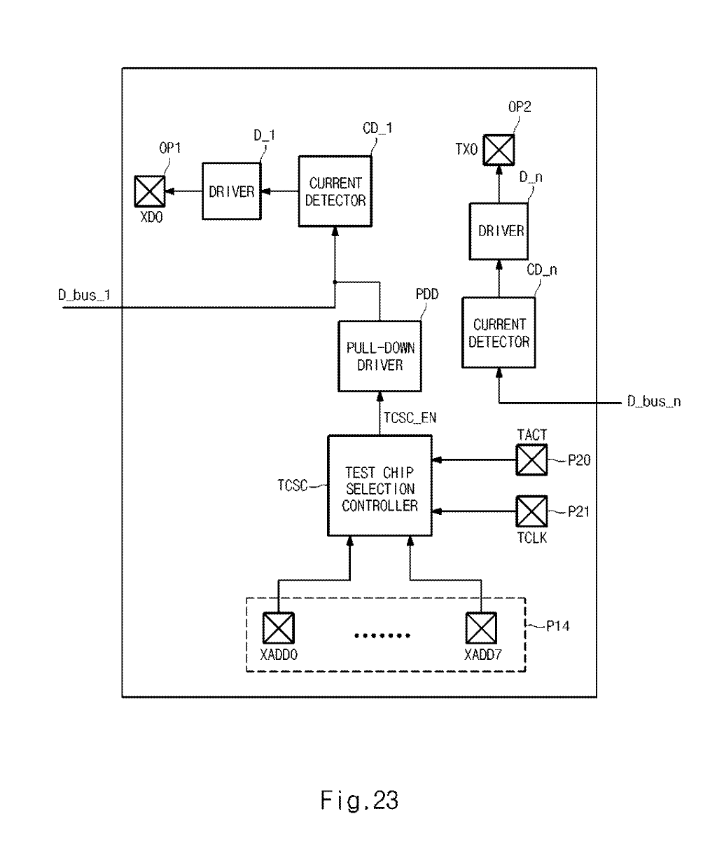

FIG. 23 is a block diagram illustrating an output circuit contained in a test chip of the RFID device shown in FIG. 16.

Referring to FIG. 23, the test chip includes a plurality of current detectors CD_1˜CD_n, a plurality of drivers D_1˜D_n, output pads OP1 and OP2, a pull-down driver PDD, and a test chip selection controller TCSC.

In this case, the current detectors CD_1˜CD_n detect currents of the data buses D_bus_1˜D_bus_n, and output the detected currents to the drivers D_1˜D_n. The drivers D_1˜D_n receive output signals of the current detectors CD_1˜CD_n, and output the received signals to the output pads OP1 and OP2, respectively.

In addition, the test chip selection controller TCSC receives a test operation signal TACT and a test clock TCLK. Further, the test chip selection controller TCSC outputs a selection signal TCSC_EN for selecting a corresponding test chip according to addresses XADD0˜XADD7 received from the test pad P5. The pull-down driver PDD, when the selection signal TCSC_EN is activated, controls the data bus D_bus_1 coupled to the current detector CD_1 to be pulled down.

In this case, the data bus D_bus_1 is not independently coupled to the current detector CD_1, but is related even to the output of the pull-down driver PDD. That is, the data bus D_bus_1 is coupled to both the output driver OD_1 of the tag chip and the output terminal of the pull-down driver PDD, such that it is affected by two signals.

Therefore, if the tag chip is deactivated, the output driver OD_1 is turned off, no current flows in the data bus D_bus_1. In this case, if the test chip is activated, the data bus D_bus_1 may be pulled down by the pull-down driver PDD.

On the other hand, if the tag chip is activated, the output driver OD_1 is turned on or off, a current may flow or not flow in the data bus D_bus_1. In this case, if the test chip is deactivated, the data bus D_bus_1 may not be pulled down by the pull-down driver PDD. By the above-mentioned operations, the data bus D_bus_1 can reflect control signals of the tag chip and the test chip in a test mode.

In the test mode, if a current order reaches the order of testing a test chip, a mode of the test chip is set to a failed mode. That is, if the test operation is carried out after the tag chip and the test chip are separated from each other via an additional address, the test process is complicated.

Therefore, the embodiment of the present invention applies the same test signal to the tag chip and the test chip without discriminating between the tag chip and the test chip. In this case, if the test chip is selected in the test mode, the test chip unconditionally pulls down the data bus D_bus1 coupled to the test chip itself. Accordingly, the external test device determines that the tag chip is failed or a corresponding chip serves as a test chip, such that it causes the chip to fail in operation. In this case, the external test device determines whether output data XDO received via the output pad OP1 is a pull-down voltage, such that it is determined whether a corresponding chip is a test chip or not.

For reference, in the test mode, the data bus D_bus_n is not independently pulled down. The test output signal TXO is transmitted to an external device via the output pad OP2 coupled to the data bus D_bus_n. The test output signal TXO is generated by the artificially-entered test input signal RXI. Therefore, although the data bus D_bus_n is not pulled down, a pass mode is recognized when the test output signal TXO is output via the output pad OP2, and a failed mode is recognized when the test output signal TXO is not output via the output pad OP2.

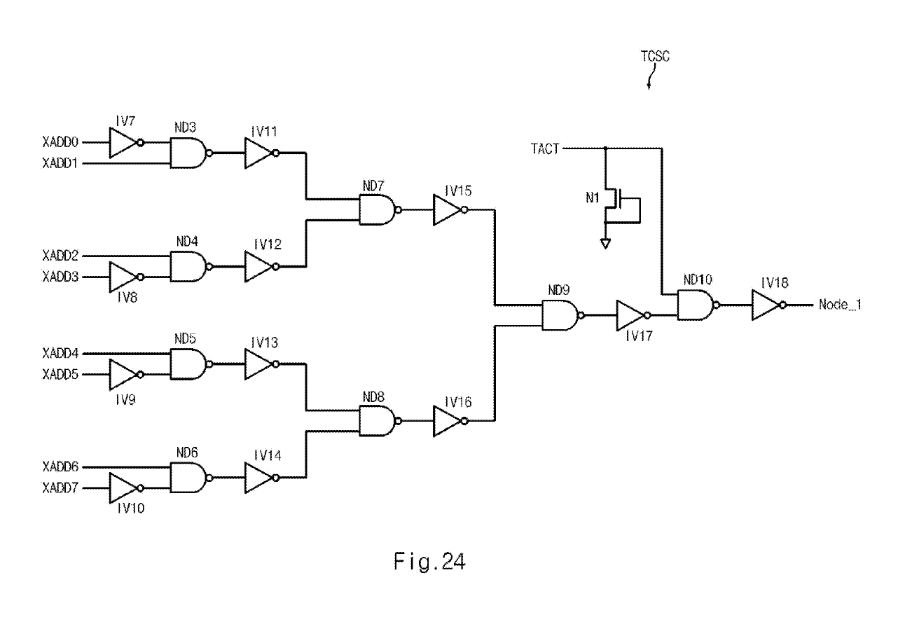

FIG. 24 is a detailed circuit diagram illustrating a decoder contained in a test chip selection controller TCSC shown in FIG. 23. In FIG. 24, the row address R2 (0110) and the column address C5 (0101) will be selected and used for convenience of description and better understanding of the present invention.

Referring to FIG. 24, the decoder includes a plurality of NAND gates ND3˜ND10, a plurality of inverters IV7˜IV18, and an NMOS transistor N1, such that it decodes addresses XADD0˜XADD7 received from the test pad P14.

In this case, the NAND gate ND3 and the inverter IV11 perform an AND operation of one address XADD0 inverted by the inverter IV7 and other address XADD1.

The NAND gate ND5 and the inverter IV13 perform an AND operation of one address XADD4 and another address XADD5 inverted by the inverter IV9.

The NAND gate ND6 and the inverter IV14 perform an AND operation of one address XADD6 and another address XADD7 inverted by the inverter IV10.

The NAND gate ND7 and the inverter IV15 perform an AND operation of output signals of the inverters IV11 and IV12. The NAND gate ND8 and the inverter IV16 perform an AND operation of output signals of the inverters IV13 and IV14. The NAND gate ND9 and the inverter IV17 perform an AND operation of output signals of the inverters IV15 and IV16.

The NMOS transistor N1 receives a ground voltage via source and gate terminals, and receives a test operation signal TACT via a drain terminal. The NAND gate ND10 and the inverter IV18 perform an AND operation of the output signal of the inverter IV17 and the test operation signal TACT, and output the AND operation result to the node Node_1.

The decoder decodes addresses XADD0˜XADD7 being input from the test pad P14 via a decoding unit, and outputs the decoded signal to the node Node_1 when the test operation signal TACT is activated.

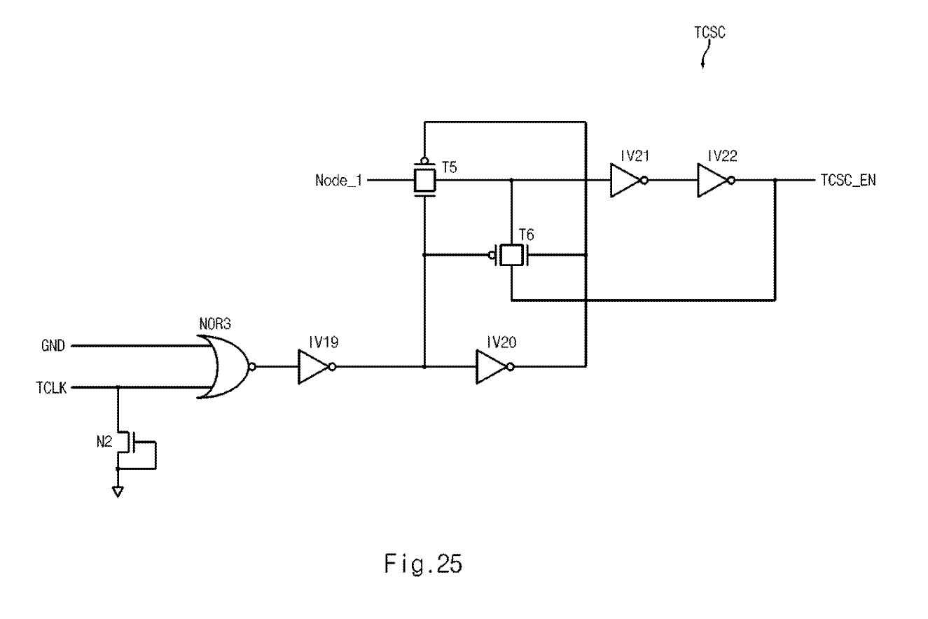

FIG. 25 is a detailed circuit diagram illustrating a latch unit contained in the test chip selection controller TCSC shown in FIG. 23.

Referring to FIG. 25, the latch unit includes an NMOS transistor N2, a NOR gate NOR3, inverters IV19˜IV22, and transfer gates T5 and T6.

The NMOS transistor N2 receives a ground voltage via source and gate terminals, and receives a test clock TCLK via a drain terminal. The NOR gate NOR3 and the inverter IV19 perform an OR operation of the ground voltage GND and the test clock TCLK. The transfer gates T5 and T6 and the inverter IV20 may selectively latch a signal applied to the node Node_1 in response to the output of the inverter IV19. The inverters IV21 and IV22 delay the output of the transfer gate T5 without inverting it, and thus output the selection signal TCSC_EN.

When the test clock TCLk is activated to a high level, the above-mentioned latch unit latches the signal of the node Node_1 and thus outputs the selection signal TCSC_EN.

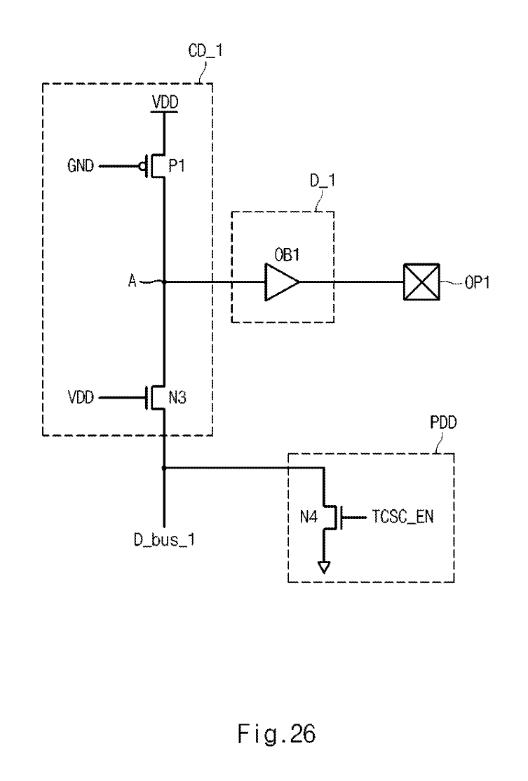

FIG. 26 is a detailed circuit diagram illustrating a current detector CD_1, a driver D_1, and a pull-down driver PDD related to the data bus D_bus_1 of the test chip shown in FIG. 23.

In FIG. 26, the current detector CD_1 includes a PMOS transistor P1 serving as a pull-up load element and an NMOS transistor N3 serving as a clamp element.

The PMOS transistor P1 is coupled between the power-supply voltage VDD and the node A, and receives a ground voltage GND via a gate terminal. The NMOS transistor N3 is coupled between the node A and the data bus D_bus_1, and receives the power-supply voltage VDD via a gate terminal.

The current detector CD_1 having the above constituent elements enables the PMOS transistor P1 and the NMOS transistor N3 to be kept in an ON status. Accordingly, the current detector CD_1 detects a current of the data bus D_bus_1, and outputs it to the node A. The driver D_1 includes the output buffer OB1. The output buffer OB1 performs buffering of the output signal of the node A, and outputs the buffered signal to the output pad OP1.

The pull-down driver PDD includes an NMOS transistor N4 serving as a pull-down element. The NMOS transistor N4 is coupled between the data bus D_bus_1 and the ground voltage GND, such that it receives the selection signal TCSC_EN via the gate terminal. When the selection signal TCSC_EN is activated to a high level, the NMOS transistor N4 pulls the data bus D_bus_1 down to a ground voltage level.

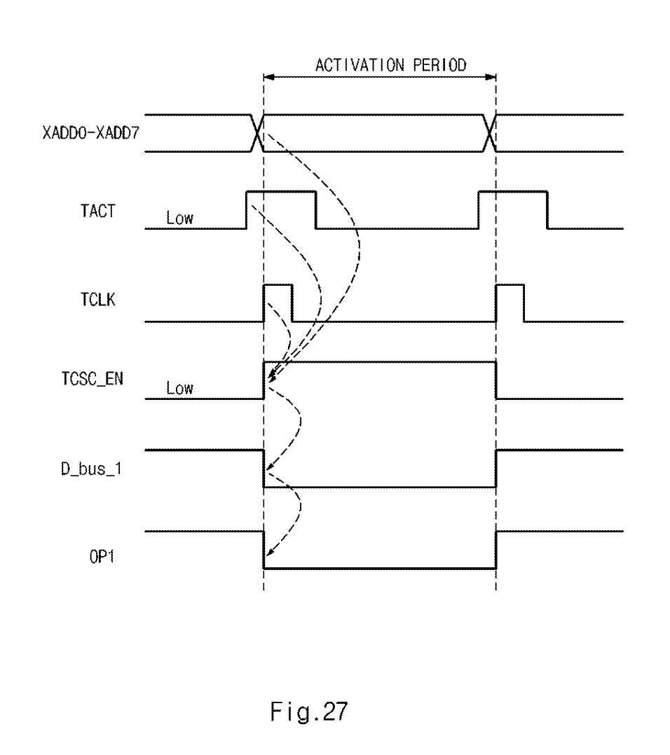

FIG. 27 is a timing diagram illustrating operations related to the data bus D_bus_1 of the test chip shown in FIG. 23.

Referring to FIG. 27, addresses XADD0˜XADD7 are transferred from the test pad P14 to the test chip during an activation period (also called an active period). The test chip selection controller TCSC outputs a high level signal to the node Node_1 by the decoding operation of the decoder. In this case, the test operation signal TACT becomes high in level.

Under the condition that the test operation signal TACT is high in level, the test clock TCLK of a high pulse is transmitted to the test chip.

Thus, the selection signal TCSC_EN is synchronized with the test clock TCLK such that the selection signal TCSC_EN is changed to a high level signal. The selection signal TCSC_EN is latched by the latch unit of the test chip selection controller TCSC. In this case, the selection signal TCSC_EN maintains the latch status until the test clock TCLK again goes high.

After that, if the selection signal TCSC_EN becomes high in level, the NMOS transistor N4 of the pull-down driver PDD is turned on, such that the data bus D_bus_1 is pulled down to a ground voltage level. As a result, the pull-down voltage of the data bus D_bus_1 is transferred to the output pad OP1 via the NMOS transistor N3 and the output buffer OB1, such that a low level signal is output externally via the output pad OP1.

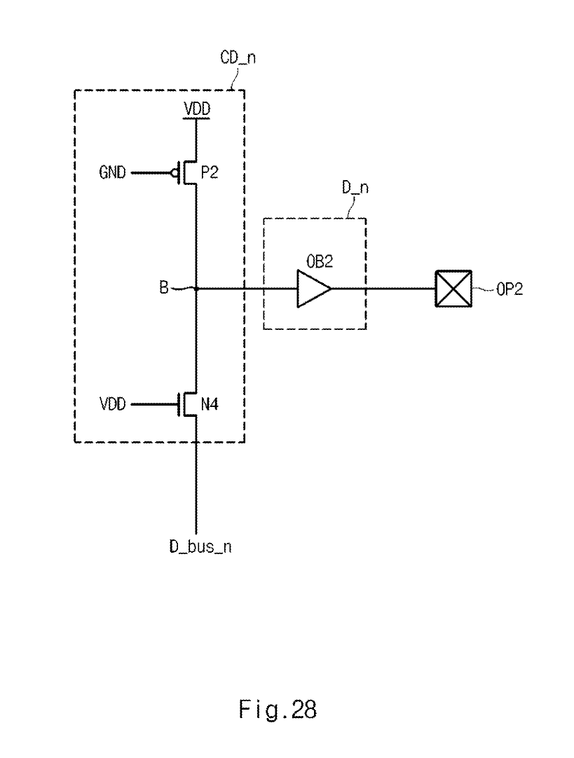

FIG. 28 is a detailed circuit diagram illustrating a current detector CD_1 and a driver D_1 related to the data bus D_bus_n of the test chip shown in FIG. 23.

In FIG. 28, the current detector CD_n includes a PMOS transistor P2 serving as a pull-up load element and an NMOS transistor N4 serving as a clamp element.

The PMOS transistor P2 is coupled between the power-supply voltage VDD and the node B, and receives a ground voltage GND via a gate terminal. The NMOS transistor N4 is coupled between the node B and the data bus D_bus_n, and receives the power-supply voltage VDD via a gate terminal.

The current detector CD_n having the above constituent elements enables the PMOS transistor P2 and the NMOS transistor N4 to be kept in an ON status. Accordingly, the current detector CD_1 detects a current of the data bus D_bus_1, and outputs it to the node B. The driver D_n includes the output buffer OB2. The output buffer OB2 performs buffering of the output signal of the node B, and outputs the buffered signal to the output pad OP2.

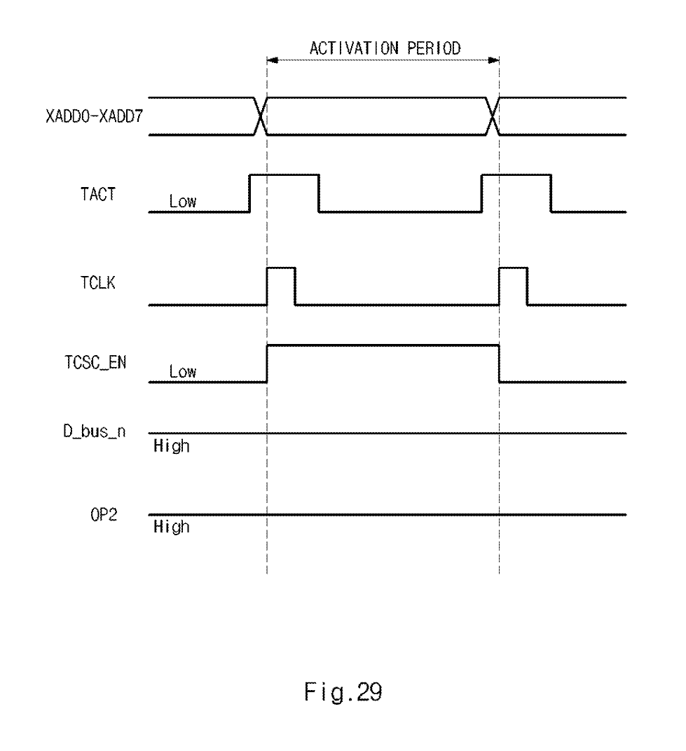

FIG. 29 is a timing diagram illustrating operations related to the data bus D_bus_n of the test chip shown in FIG. 23.

Referring to FIG. 29, addresses XADD0˜XADD7 are transferred from the test pad P14 to the test chip during an activation period. The test chip selection controller TCSC outputs a high level signal to the node Node_1 by the decoding operation of the decoder. In this case, the test operation signal TACT becomes high in level.

Under the condition that the test operation signal TACT is high in level, the test clock TCLK of a high pulse is transmitted to the test chip. Thus, the selection signal TCSC_EN is synchronized with the test clock TCLK such that the selection signal TCSC_EN is changed to a high level signal. The selection signal TCSC_EN is latched by the latch unit of the test chip selection controller TCSC. In this case, the selection signal TCSC_EN maintains the latch status until the test clock TCLK again reaches the high pulse status.

In this case, the current detector CD_n outputs the signal received via the data bus D_bus_n to the output pad OP2 via the node B and the output buffer OB2. Therefore, the output pad OP2 outputs a high level signal.

As described above, the embodiment of the present invention controls the tag chip's output current received via the data buses D_bus_1˜D_bus_n so as to externally output the failed status of test and tag chips, such that the test operation is facilitated and a test time is reduced. Further, in the test mode, if the test chip is selected, the data bus D_bus_1 coupled to the test chip is pulled down, such that the test chip can be easily identified.

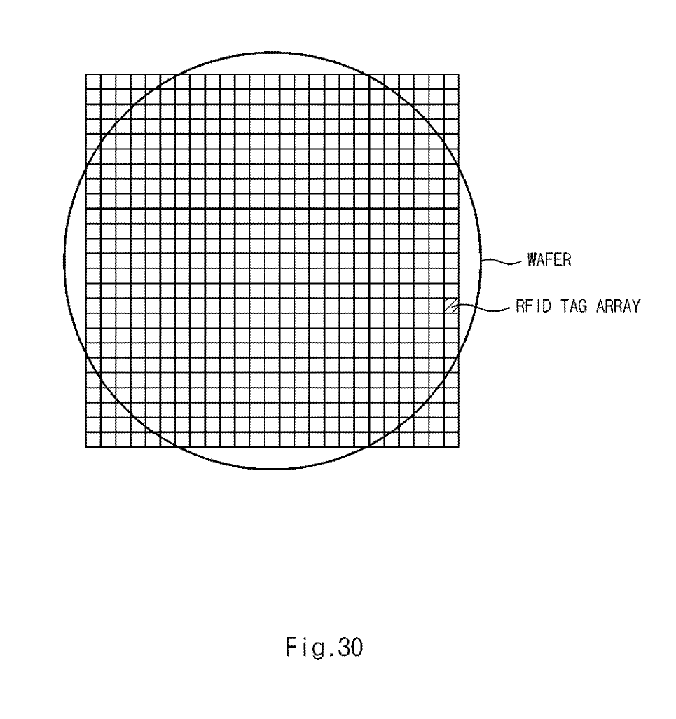

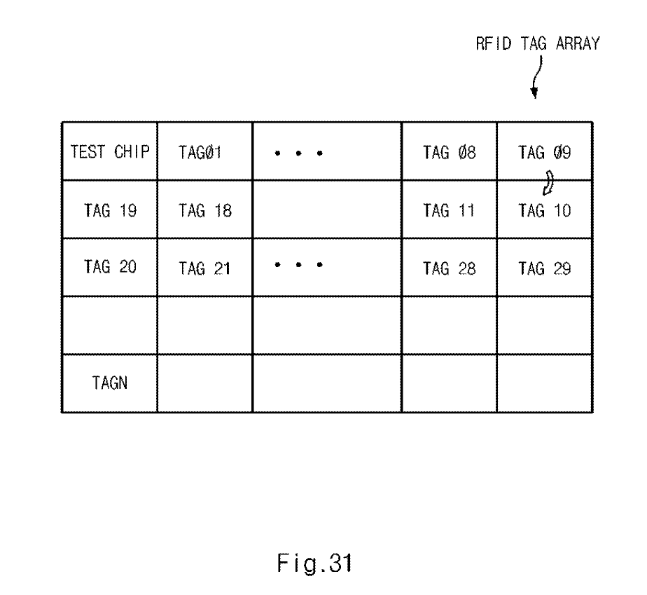

FIG. 30 shows a wafer including a plurality of RFID tag arrays according to a third embodiment of the present invention. Referring to FIG. 30, a plurality of tag arrays is arranged on one wafer. Each RFID tag array includes a plurality of RFID tags. That is, the RFID tag array indicates a set of RFID tags interconnected via scribe lanes.

FIG. 31 is a structural diagram illustrating one RFID tag array according to a third embodiment of the present invention.

Referring to FIG. 31, one RFID tag array includes one test chip and a plurality of RFID tags. The test chip is initialized when receiving a power-supply voltage VDD, such that it is firstly activated. As a result, RFID tags TAG1˜TAGN are sequentially activated.

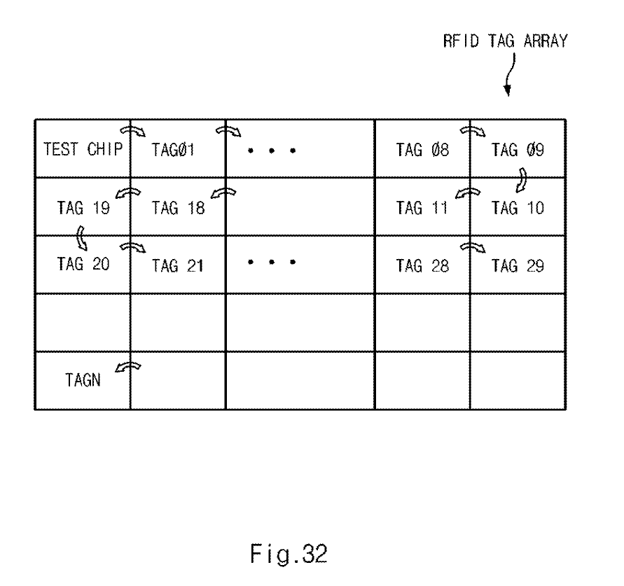

FIG. 32 is a conceptual diagram illustrating a process for sequentially activating a plurality of RFID tags in an RFID tag array according to a third embodiment of the present invention.

Referring to FIG. 32, if the test chip is initialized, in a first row, the RFID tags TAG01˜TAG09 are sequentially activated in a positive direction of an X axis, such that respective RFID tags contained in a first row are tested. In addition, in a third row, the RFID tags TAG20˜TAG29 are sequentially activated in a positive direction of an X-axis, such that respective RFID tags contained in a third row are tested. In this way, all the RFID tags contained in the RFID tag array are sequentially activated and tested.

The order of operations shown in the above-mentioned embodiment has been disclosed only for illustrative purposes, and thus the order of activating several RFID tags may also be changed to another according to a user's intention by modification in arrangement of scribe lanes. For example (i), after RFID tags have been activated in a negative direction of a Y axis in a first column, RFID tags may be activated in a positive direction of a Y axis in a second column. For another example (ii), RFID tags may also be activated in a diagonal direction, that is, the order of RFID tag TAG01→RFID tag TAG19→RFID tag TAG20→RFID tag TAG18.

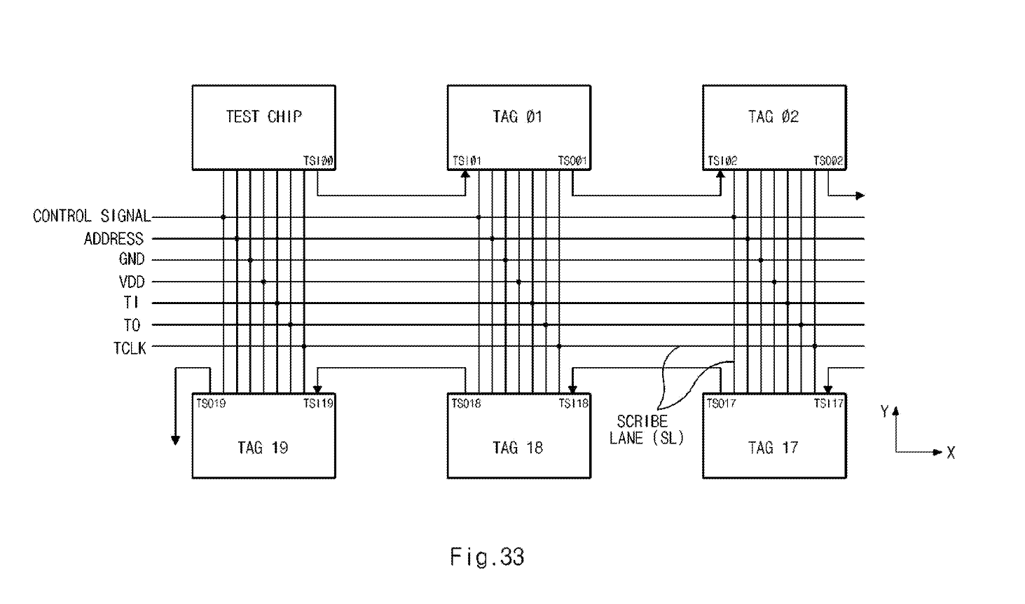

FIG. 33 is a circuit diagram illustrating the RFID tag array according to a third embodiment of the present invention.

Referring to FIG. 33, the RFID tag array includes one test chip and a plurality of RFID tags. In FIG. 33, a power-supply voltage VDD and a ground voltage GND, which have been received from an external device, are applied to an internal circuit of each RFID tag via I/O pads of the RFID tag after passing through a plurality of scribe lanes arranged in X- and Y-axis directions.

The test input signal TI, the test clock TCLK, the control signal, the address, etc. which have been received from an external device, are applied to an internal circuit of each RFID tag via I/O pads of the RFID tag after passing through a plurality of scribe lanes arranged in X- and Y-axis directions. However, the test output signal TXO, the control result signal, etc. output from the RFID tag are transferred from the RFID tag internal circuit to an external device via a plurality of scribe lanes arranged in X- and Y-axis directions after passing through I/O pads of each internal circuit of the RFID tag.

The test chip, the RFID tag TAG01, and other RFID tags TAG02˜TAGN are coupled to one another via a plurality of scribe lanes arranged in X- and Y-axis directions. The test serial input signal TSI and the test serial output signal TSO are sequentially transferred among RFID tags via scribe lanes.

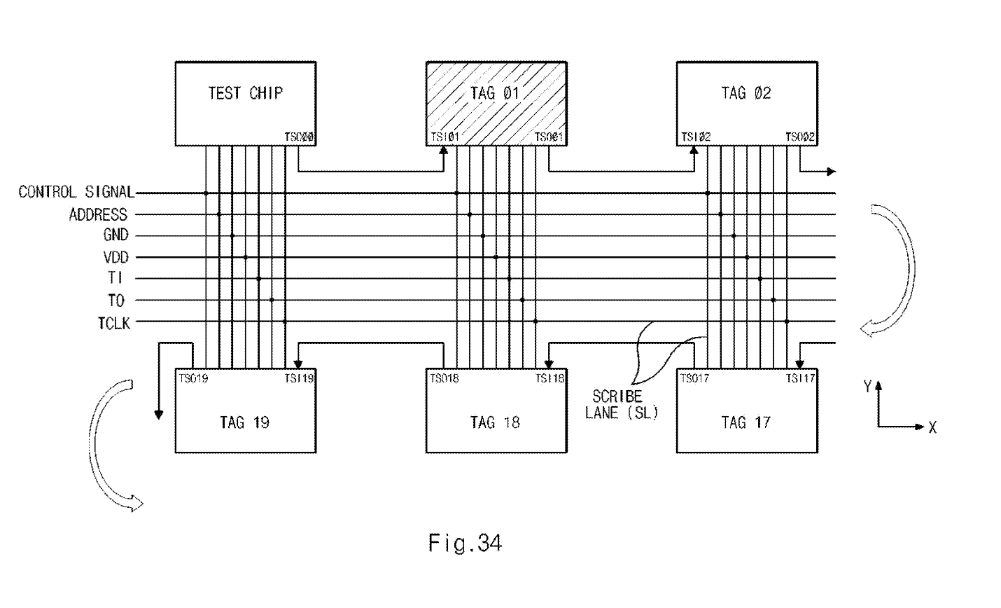

FIG. 34 is a circuit diagram illustrating a procedure for sequentially activating a plurality of RFID tags contained in an RFID tag array, and testing the RFID tags for an activation period according to an embodiment of the present invention.

Referring to FIG. 34, in order to test the RFID tag array, the test chip needs to be initialized. A variety of methods may be used to initialize the test chip. For example, if the power-supply voltage VDD is received via an I/O pad, initialization of the test chip may be established as necessary.

If the test chip is initialized, the test serial input signal is transferred from the output terminal TSO00 to an input terminal TSI01 of the RFID tag TAG01. In this case, although ‘TSO’ indicates an output terminal and ‘TSI’ indicates an input terminal for convenience of description, it should be noted that TSO and TSI substantially indicate the test serial output signal TSO and the test serial input signal TSI, respectively.

The RFID tag TAG01, under the condition that the power-supply voltage VDD, the ground voltage GND, and the test serial input signal are received, is synchronized with the test clock TCLK, such that it can be activated. When the RFID tag TAG01 is activated, the test input signal T1 is applied to the RFID tag TAG01 via I/O pads, such that the test operation is carried out.

If the test operation of the RFID tag TAG01 has been completed, the test serial output signal is generated after being synchronized with the test clock TCLK. The test serial output signal is transferred from the output terminal TSO01 to the input terminal TSI02.

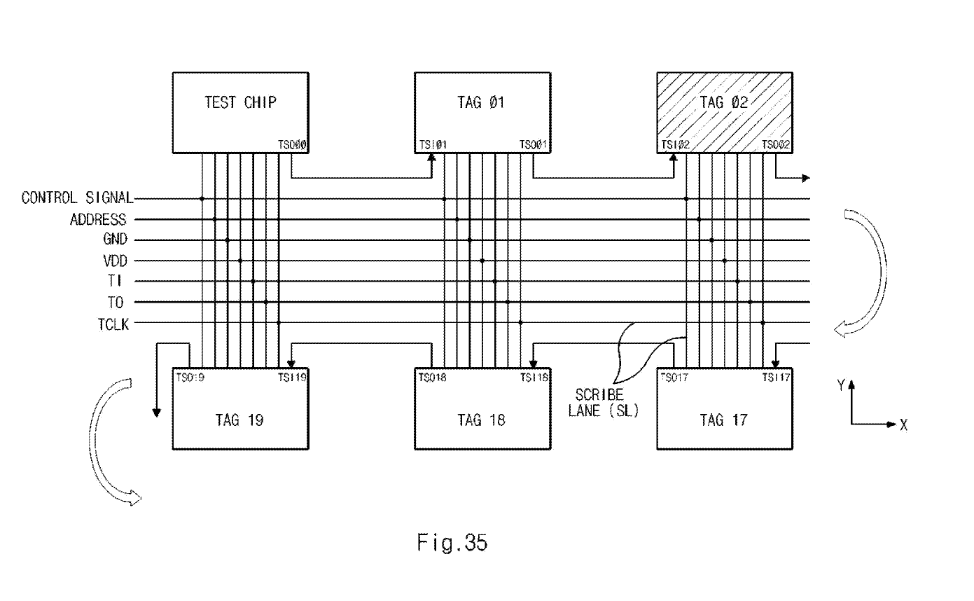

FIG. 35 is a circuit diagram illustrating a procedure for sequentially activating a plurality of RFID tags contained in an RFID tag array, and testing the RFID tags for an activation period according to an embodiment of the present invention.

The RFID tag TAG02, under the condition that the power-supply voltage VDD, the ground voltage GND, and the test serial input signal are received, is synchronized with the test clock TCLK, such that it can be activated. When the RFID tag TAG02 is activated, the test input signal T1 is applied to the RFID tag TAG02 via I/O pads, such that the test operation is carried out.

If the test operation of the RFID tag TAG02 has been completed, the test serial output signal is generated after being synchronized with the test clock TCLK. The test serial output signal is transferred from the output terminal TSO02 to the input terminal TSI03.

Likewise, the test serial output signal is further input to the RFID tags TAG03˜TAGN so as to activate the respective RFID tags, such that the respective RFID tags can be tested during the activation period.

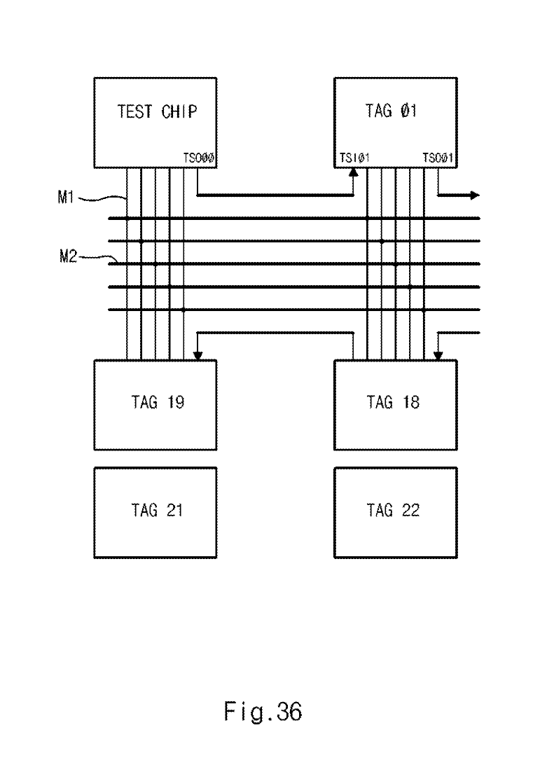

FIG. 36 is a circuit diagram illustrating that respective RFID tags are coupled to one another via scribe lanes in the RFID tag array according to a third embodiment of the present invention.

Referring to FIG. 36, the RFID tag array includes one test chip and a plurality of RFID tags. A plurality of scribe lanes arranged in X- and Y-axis directions. A plurality of interconnects in scribe lanes arranged in X- and Y-axis directions may be formed in different layers such as M1 and M2 layers.

In the M1 layer, a plurality interconnects in scribe lanes may be formed in the direction of an X axis. In the M2 layer, a plurality of interconnects in scribe lanes may be formed in the direction of a Y axis. Interconnects of the M1 layer and interconnects of the M2 layer can be coupled to each another via a contact.

The power-supply voltage and the ground voltage, which have been received from an external device, are applied to an internal circuit of each RFID tag via I/O pads of the RFID tag, after sequentially passing through scribe lanes arranged in an X-axis direction of the M1 layer, the contact, and other scribe lanes arranged in a Y-axis direction of the M2 layer.

The test input signal, the test clock, the control signal, and the address, which have been received from an external device, are applied to an internal circuit of each RFID tag via I/O pads of the RFID tag, after sequentially passing through scribe lanes arranged in the X-axis direction of the M1 layer, the contact, and other scribe lanes arranged in the Y-axis direction of the M2 layer.

A test output signal, a test serial output signal, a control output signal, etc. output from the RFID tag are transferred from the RFID tag's internal circuit to scribe lanes via I/O pads of the RFID tag. Then, they are sequentially applied to the scribe lanes arranged in the Y-axis direction of the M2 layer, the contact, and other scribe lanes arranged in the X-axis direction of the M1 layer, and are then transmitted to an external device.

The test serial input signal and the test serial output signal are transmitted among the test chip, the RFID tag TAG01, and other RFID tags TAG02˜TAGN via Y-axis directional scribe lanes and a contact in the M2 layer, X-axis directional scribe lanes and a contact in the M1 layer, and Y-axis directional scribe lanes of the M2 layer.

In accordance with the above-mentioned embodiment of the present invention, if it is assumed that only one test chip is assigned to each tag array and the test chip is initialized, several RFID tags coupled to the test chip are sequentially activated and tested. Therefore, a plurality of RFID tags can be easily tested.

Further, if it is assumed that only one test chip is assigned to each tag array and the test chip is initialized, the test output signal is sequentially transferred to several RFID tags serially coupled to each other so as to activate the RFID tags, such that these RFID tags can be tested in the embodiment of the present invention. If it is assumed that test input/output signals are simultaneously applied to and generated from all the RFID tags, additional scribe lanes are needed for I/O operations of the test input/output signals. However, the embodiment of the present invention can be realized by a plurality of RFID tags that are coupled in series to one another via no additional scribe lanes, therefore the layout size is reduced and a circuit structure is simplified.

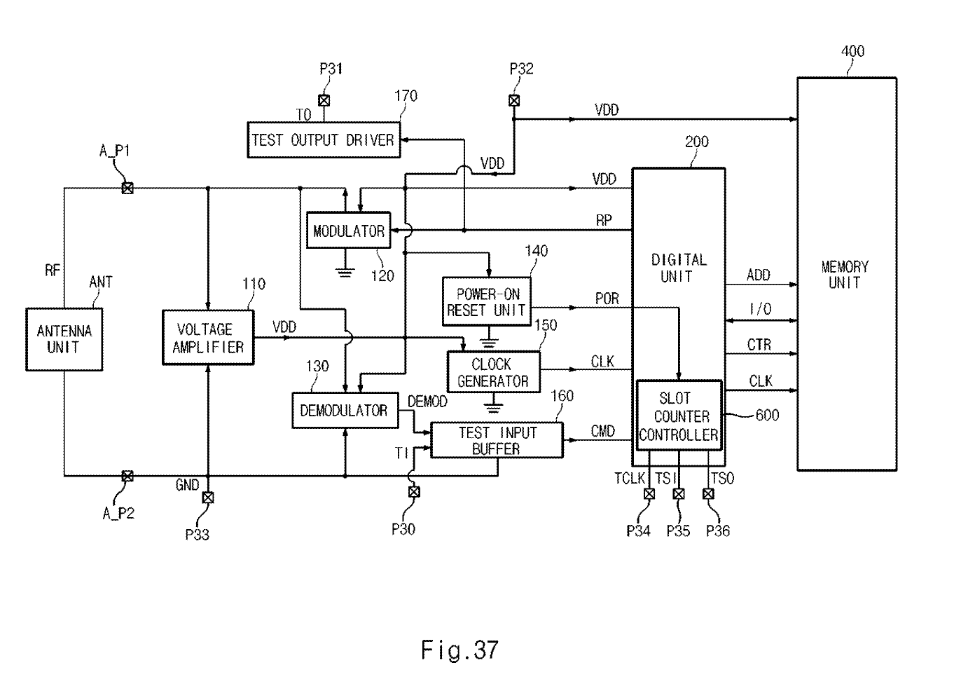

FIG. 37 is a structural diagram illustrating an RFID device according to a third embodiment of the present invention.

Referring to FIG. 37, the RFID device according to the third embodiment of the present invention includes an antenna unit ANT, a voltage amplifier 110, a modulator 120, a demodulator 130, a power-on reset unit 140, a clock generator 150, a test input buffer 160, a test output driver 170, a digital unit 200, and a memory unit 400.

The antenna unit ANT receives one or more RF signals from an RFID reader. The received RF signal is transmitted to the voltage amplifier 110 via antenna pads A_P1 and A_P2. The voltage amplifier 110 rectifies and boosts the RF signal received via the antenna unit ANT, and generates a power-supply voltage serving as an RFID-tag drive voltage. The modulator 120 modulates a response signal RP received from the digital unit 200, and outputs the modulated response signal RP to the antenna unit ANT.

The demodulator 130 demodulates the RF signal received from the antenna unit ANT in response to the output voltage of the voltage amplifier 110 so as to generate a demodulation signal DEMOD, and outputs the generated demodulation signal DEMOD to the test input buffer 160.

The power-on reset unit 140 detects a power-supply voltage generated in the voltage amplifier 110, and outputs a power-on reset signal POR to the digital unit 200 so as to control a reset operation in response to the detected power-supply voltage. The clock generator 150 outputs a clock CLK to the digital unit 200, wherein the clock CLK is capable of controlling operations of the digital unit 200 in response to the power-supply voltage output from the voltage amplifier 110.

The test input buffer 160, in response to a test input signal T1 from a test signal input pad P30 and the demodulation signal DEMOD from the demodulator 130, detects an operation command signal, and therefore generates a command signal CMD.

A power-supply voltage applying pad P32 is a pad capable of receiving a power-supply voltage VDD when testing a plurality of activated RFID tags on a wafer. A ground voltage applying pad P33 is a pad capable of receiving a ground voltage GND when testing a plurality of RFID tags on a wafer.

In other words, if the RFID tag receives an RF signal from the RFID reader by communicating with the RFID reader, the voltage amplifier 110 provides the power-supply voltage VDD. In other words, if the RFID tag receives an RF signal from the RFID reader by communicating with the RFID reader, the voltage amplifier 110 provides the power-supply voltage VDD. In contrast, when testing the RFID tag on a wafer according to the third embodiment of the present invention, the RFID device shown in FIG. 37 receives the power-supply voltage VDD and the ground voltage GND via an additional power-supply voltage applying pad P32 and an additional ground voltage applying pad P33, respectively.

In contrast, because the RFID device shown in the embodiment of the present invention can test such RFID tags on a wafer, it receives the power-supply voltage VDD and the ground voltage GND via an additional power-supply voltage applying pad P32 and an additional ground voltage applying pad P33, respectively.

The test output driver 170 drives a test output signal TO in response to the response signal RP received from the digital unit 200, and outputs the test output signal TO via the test signal output pad P31.

The digital unit 200 receives a power-supply voltage VDD, a power-on reset signal POR, and a clock CLK, analyzes a command signal CMD using the received signals, and generates a control signal and process signals. The digital unit 200 outputs a response signal RP corresponding to the control and process signals to the modulator 120.

The digital unit 200 includes a slot counter controller 600 for activating respective RFID tags. The slot counter controller 600 receives a test clock TCLK from the test clock input pad P34, and receives a test serial input signal TSI from the test serial signal input pad P35. The slot counter controller 600 receives a power-on reset signal POR from the power-on reset unit 140.

The slot counter controller 600 generates slot counter bits to control activation or deactivation of an RFID tag, generates a test serial output signal TSO and outputs it to another RFID tag via the test serial signal output pad P36

The digital unit 200 outputs an address ADD, input/output data I/O, a control signal CTR, and a clock CLK to the memory unit 400. The memory unit 400 writes information received from the digital unit 200 in a storage unit, and reads the information therefrom.

In this case, the memory unit 400 may be a non-volatile ferroelectric memory (FeRAM). The FeRAM has a data processing speed similar to that of a DRAM. Also, the FeRAM has a structure very similar to that of DRAM, and uses a ferroelectric substance as a capacitor material so that it has high residual polarization characteristics. Due to the high residual polarization characteristics, data is not lost although an electric field is removed.

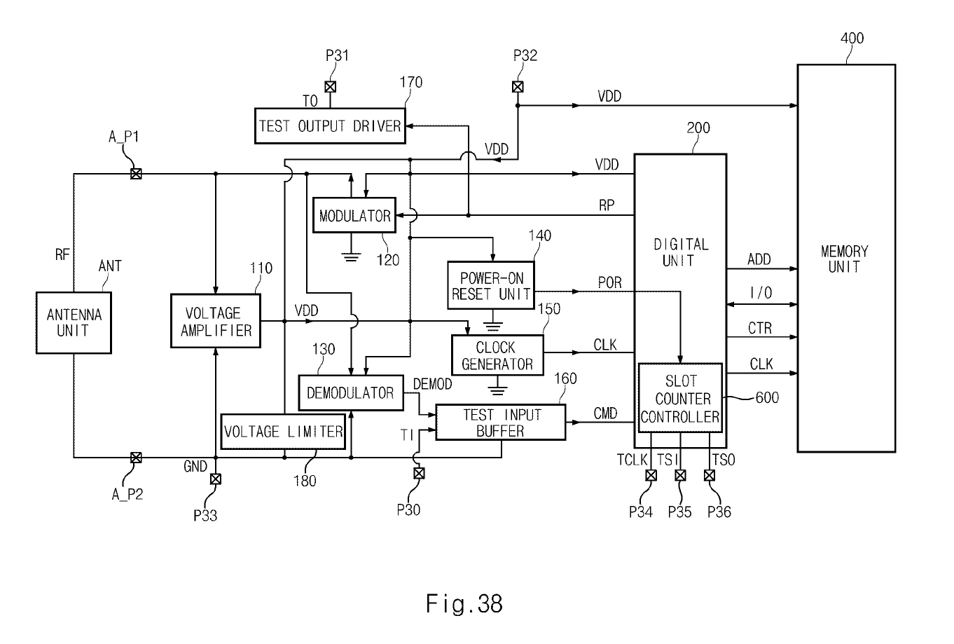

FIG. 38 is a structural diagram illustrating an RFID device according to a fourth embodiment of the present invention.

Referring to FIG. 38, the RFID device according to the fourth embodiment of the present invention includes an antenna unit ANT, a voltage amplifier 110, a modulator 120, a demodulator 130, a power-on reset unit 140, a clock generator 150, a test input buffer 160, a test output driver 170, a digital unit 200, and a memory unit 400.

The antenna unit ANT, the digital unit 200, and the memory unit 400 shown in the fourth embodiment are substantially equal to those in the third embodiment, but the fourth embodiment further includes a voltage limiter 180 applied differently from the third embodiment. In order to substantially prevent an internal circuit of the RFID tag from being damaged by an unexpected voltage exceeding the power-supply voltage VDD, the voltage limiter 180 limits the magnitude of either a voltage amplified by the voltage amplifier 110 or an externally-received power-supply voltage to a predetermined voltage level value or less.

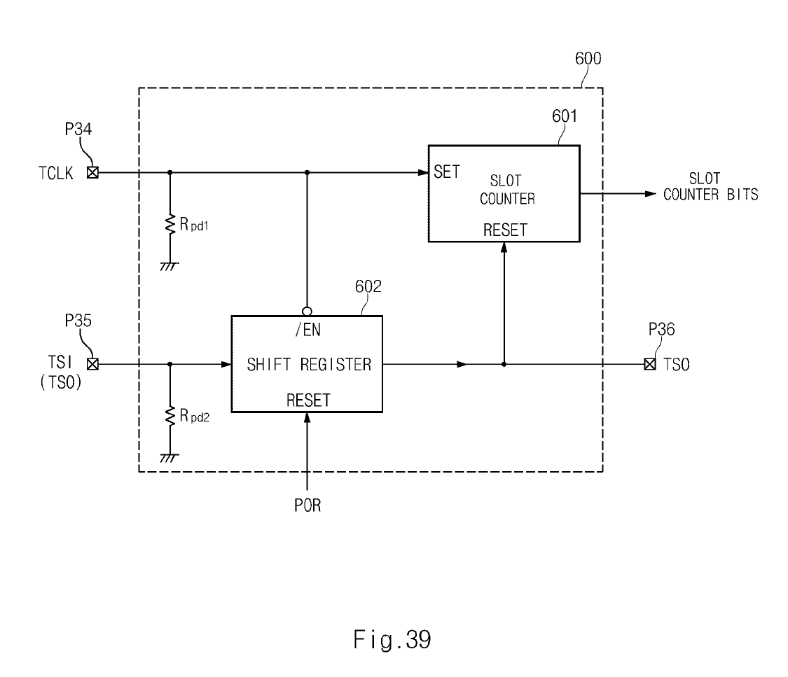

FIG. 39 is a detailed circuit diagram illustrating a slot counter controller 600 shown in FIGS. 37 and 38.

Referring to FIG. 39, the slot counter controller 600 includes a slot counter 601 and a shift register 602. The test clock TCLK is transmitted to the slot counter 601 and the shift register 602 via a test clock input pad P34. A pad resistor Rpd1 is coupled between a test clock input pad P34 and a ground terminal.

If a test clock TCLK is not applied to the slot counter 601 as a high level signal, the pad resistor Rpd1 allows the test clock TCLK to be biased. In more detail, in the case where noise occurs in a test clock TCLK so that the test clock TCLK has an intermediate level between low and high levels and is then applied to the slot counter 601, the pad resistor Rpd1 allows the test clock TCLK having the intermediate level to be biased to a low level so that no noise is applied to the slot counter 601. However, if the test clock TCLK is transmitted as a high level signal to the slot counter 601, this high level test clock TCLK has its own driving capability so that it is not biased to a low level signal by the pad resistor Rpd1.

A test serial input signal TSI from the test chip or a test serial output signal TSO from another RFID tag is applied to the shift register 602 via the test serial signal input pad P35. A pad resistor Rpd2 is coupled in parallel between the test serial input pad P35 and a ground terminal.

If a test serial input(output) signal TSI is not applied to the shift register 602 as a high level signal, the pad resistor Rpd2 allows the received signal TSI to be biased. In more detail, in the case where noise occurs in the a test clock TCLK so that the test serial input(output) signal TSI(TSO) has an intermediate level between low and high levels and is then applied to the slot counter 602, the pad resistor Rpd2 allows the test serial input(output) signal TSI having the intermediate level to be biased to a low level so that no noise is applied to the shift register 602. However, if the test serial input(output) signal TSI is transmitted as a high level signal to the shift register 602, this high level test serial input(output) signal TSI has its own driving capability so that it is not biased to a low level signal by the pad resistor Rpd2.

The slot counter 601 is set by the test clock TCLK, such that it outputs slot counter bits of a low level. The slot counter 601 is reset by a test serial output signal TSO output from the shift register 602, such that it outputs slot counter bits of a high level. If the slot counter 602 outputs the low level slot counter bits, the RFID tag is activated. Otherwise, if the slot counter 602 outputs the high level slot counter bits, then the RFID tag is deactivated.

The shift register 602 stores the value of either a test serial input signal TSI received from the test chip or a test serial output signal TSO received from another RFID tag. If the shift register 602 is activated by the test clock TCLK, then the value of the test serial input signal TSI or test serial output signal TSO received from another RFID tag is transmitted as a test serial output signal TSO. The test serial output signal TSO is transmitted to the slot counter 601 and the test serial signal output pad P36. The shift register 602 receives a power-on reset signal POR from the power-on reset unit 140, such that it is reset.

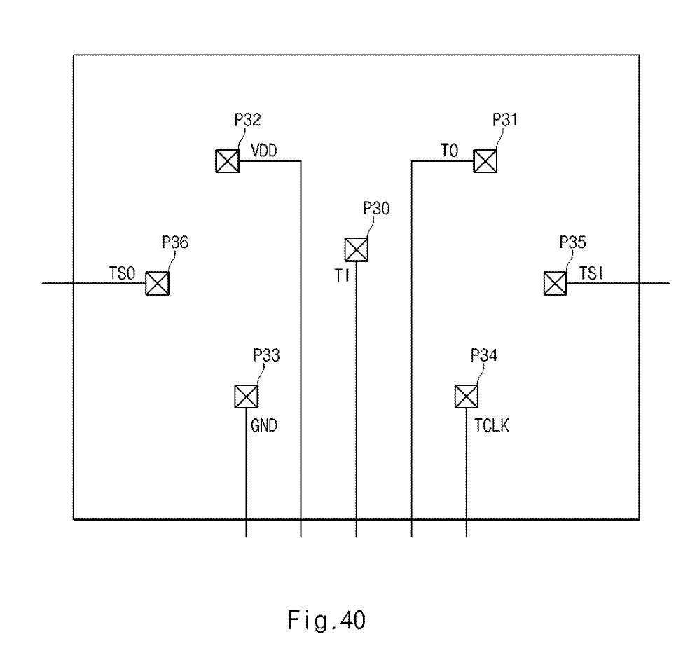

FIG. 40 is a structural diagram illustrating an input/output (I/O) pad used in testing the RFID tag shown in FIGS. 37 and 38 according to third and fourth embodiments of the present invention.

Referring to FIG. 40, the I/O pad of the RFID test chip includes a test signal input pad P30, a test signal output pad P31, a power-supply voltage applying pad P32, a ground-voltage applying pad P33, a test clock input pad P34, a test serial signal input pad P35, and a test serial signal output pad P36.

The test input signal TI is applied to the I/O pad of the RFID test chip via the test signal input pad P30, and the test output signal TO is output via the test signal output pad P31. The power-supply voltage VDD is applied to the I/O pad via the power-supply voltage applying pad P32, and the ground voltage GND is applied to the I/O pad via the ground-voltage applying pad P33. The test clock TCLK is applied to the I/O pad via the test clock input pad P34, the test serial input signal TSI is applied to the I/O pad via the test serial signal I/O pad 35, and the test serial output signal TSO is applied to the I/O pad via the test serial signal output pad P36.

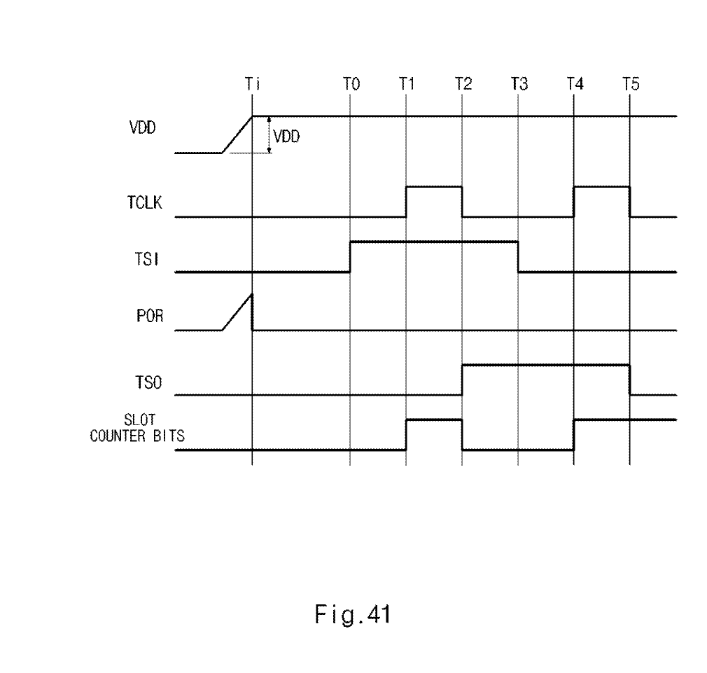

FIG. 41 is a timing diagram illustrating operations of the slot counter controller 600 shown in FIGS. 37 and 38.

Referring to FIG. 41, at a time Ti, the power-supply voltage VDD is applied to a test chip, such that the test chip is initialized. In this case, the power-on reset signal POR is initialized from a low level to a high level. The power-on reset signal POR is applied to the shift register 602, such that the shift register 602 is also initialized by the power-on reset signal POR.

At a time T0, the test serial input signal TSI is changed from a low level to a high level. That is, the test serial input signal TSI is applied from the test chip to the test serial signal input pad TSI01 of an RFID tag TAG01. The test serial input signal TSI input to the RFID tag TAG01 is applied to the shift register 602 of the slot counter controller 600.

The shift register 602 is activated when the test clock TCLK is low in level. Therefore, when the test clock TCLK is changed from a low level to a high level at the time T1, the shift register 602 is deactivated. Accordingly, on the condition that the shift register 602 of the RFID tag TAG01 is initialized until being activated, it outputs the test serial output signal TSO of a low level.

At a time T1, the test clock TCLK is input to a set terminal of the slot counter 601. In this case, if the test clock TCLK is changed from a low level to a high level, the slot counter 601 is set so that it outputs slot counter bits denoted by “111 . . . ”’. If the slot counter bits “111 . . . ” are outputted from the slot counter 601, the RFID tag is deactivated so that the RFID tag cannot be tested.

At a time T2, if the test clock TCLK is changed from a high level to a low level, the shift register 602 is activated. If the shift register 602 is activated at the time T2, the shift register 602 stores the value of a test serial input signal acquired at the time T2, and outputs the stored TSI value as the test serial output signal TSO.

The shift register 602 stores the input signal generated when activated, and then continuously outputs the stored signal until being deactivated. Thus, although the test serial output signal TSO is transitioned to a low level at a time T3, the test clock TCLK is continuously maintained at a low level. While the shift register 602 is maintained at an activation status, the test serial output signal TSO is high in level. Herein, it is preferable that the test serial input signal TSI be transitioned to a low level before reaching the next time T4 at which the test clock TCLK is transitioned to a high level.

The test serial output signal TSO is further input to a reset terminal of the slot counter 601. If the test serial output signal TSO is high in level, the slot counter 601 is reset so that it outputs slot counter bits denoted by “000 . . . ”. If the slot counter bits “000 . . . ” are output, the RFID tag is activated.

In other words, the slot counter 601 is maintained at a reset mode until the shift register 602 is deactivated by the input of a high level test clock TCLK. As a result, the slot counter bits “000 . . . ” are generated until reaching the time T1 at which the test clock TCLK is transitioned to a high level, so that an RFID tag is maintained at an activation status before reaching the time T1. Therefore, the test operation for the RFID tag can be carried out for the activation maintenance time.

The test operation may be carried out by an analog circuit unit, the digital unit 200 or the memory unit 400 according to a user's intention related to the RFID tag. Herein, it should be noted that the term “analog circuit unit” conceptually includes a voltage amplifier 110, a modulator 120, a demodulator 130, a power-on reset unit 140, a clock generator 150, a test input buffer 160, and a test output driver 170.

For example, when performing the test operation on the memory unit 400, reset data is written in each memory cell of the memory unit 400. The test input signal TI is input via an I/O pad. The test input signal TI is input to the test input buffer 160 so that a command signal CMD is generated. The command signal CMD includes an operation signal that causes data written in the RFID tag to be read.

The digital unit 200 reads the data written in the memory unit 400 using the control signal CTR in response to the command signal CMD. The response signal RP generated from the digital unit 200 includes information about the read data. The response signal RP is driven by the test output driver 170, and is output in a form of a test output signal TO through the test signal output pad P31. The digital unit 200 acquires information about the read data from the test output signal TO. An external test device located outside of the RFID tag compares the read data with the written data, and determines whether the read data is substantially equal to the written data. If the read data is substantially equal to the written data, the digital unit 200 decides that the memory unit 400 is in a normal mode. Otherwise, the digital unit 200 decides that the memory unit 400 is in a failed mode, so that the test operation for the memory unit 400 is completed.

At a time T4, if the test clock TCLK is changed from a low level to a high level, the shift register 602 is deactivated. The shift register 602 continuously outputs the test serial output signal TSO of a high level until it is deactivated by a next test clock TCLK of a low level. If the test serial output signal TSO of a high level is output, the slot counter 602 is reset so that it outputs slot counter bits “000 . . . ”. If the slot counter bits “000 . . . ” are output, an RFID tag TAG01 is activated.

At a time T5, if the test clock TCLK is changed from a high level to a low level, the shift register 602 of the RFID tag TAG01 is reactivated. If the shift register 602 is activated, then the shift register 602 stores a value of the test serial input signal TSI, being input to the RFID tag TAG01 at the time T5, and then outputs the stored TSI value as a test serial output signal TSO.

Therefore, the test serial input signal TSI is transitioned to a low level at the time T5, such that the test serial output signal TSO is also changed from a high level to a low level. The test serial output signal TSO is further input to a reset terminal of the slot counter 601. Therefore, if it is assumed that the test serial output signal TSO is maintained at a low level, the slot counter 601 is maintained in a set mode so that it outputs slot counter bits “111 . . . ”. If the slot counter bits “111 . . . ” are output, deactivation of the RFID tag TAG01 is maintained.

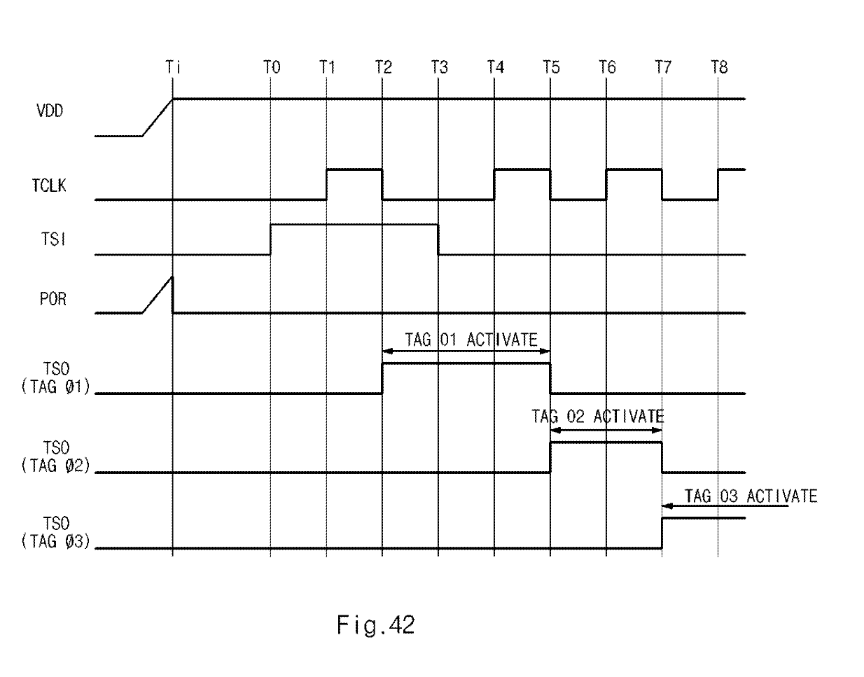

FIG. 42 is a timing diagram illustrating that a plurality of RFID tags shown in FIGS. 37 and 38 are sequentially activated.

Referring to FIG. 42, at a time Ti, the power-supply voltage VDD begins to flow in a test chip, such that the test chip is initialized. At this time Ti, the power-on reset signal POR is also initialized from a low level to a high level. The power-on reset signal POR is further input to the shift register 602, such that the shift register 602 is also initialized by the power-on reset signal POR.

At a time T0, the test serial input signal TSI is changed from a low level to a high level. That is, the test serial input signal TSI is output from the test chip to the test serial signal input pad TSI01 of the RFID tag TAG01. The test serial input signal TSI received in the RFID tag TAG01 is input to the shift register 602 of the slot counter controller 600.

The shift register 602 is activated when the test clock TCLK is low in level. Therefore, when the test clock TCLK is changed from a low level to a high level at the time T1, the shift register 602 is deactivated. Accordingly, on the condition that the shift register 602 of the RFID tag TAG01 is initialized until being activated, the shift register 602 outputs the test serial output signal TSO of a low level.

At a time T1, the test clock TCLK is input to a set terminal of the slot counter 601. In this case, if the test clock TCLK is changed from a low level to a high level, the slot counter 601 is set so that it outputs slot counter bits denoted by “111 . . . ”. If the slot counter bits “111 . . . ” are output from the slot counter 601, the RFID tag is deactivated so that the RFID tag cannot be tested.

At a time T2, if the test clock TCLK is changed from a high level to a low level, the shift register 602 is activated. If the shift register 602 is activated at the time T2, the shift register 602 stores the value of a test serial input signal acquired at the time T2, and then outputs the stored TSI value as the test serial output signal TSO.

At the time T2, the test serial input signal TSI is high in level, so that the test serial output signal TSO is also changed from a low level to a high level. The test serial output signal TSO is further input to a reset terminal of the slot counter 601. If the test serial output signal TSO is high in level, the slot counter 601 is reset so that it outputs slot counter bits denoted by “000 . . . ”, resulting in activation of the RFID tag TAG01.

The shift register 602 stores the input signal generated upon activation, and then continuously outputs the stored signal until being deactivated. Thus, although the test serial input signal TSI is transitioned to a low level at a time T3, the test clock TCLK is continuously maintained at a low level. While the shift register 602 is maintained in activation status, the test serial output signal TSO is high in level. Herein, the test serial input signal TSI may be transitioned to a low level before reaching the next time T4 at which the test clock TCLK is transitioned to a high level.

The test serial output signal TSO is further input to a reset terminal of the slot counter 601. If the test serial output signal TSO is high in level, the slot counter 601 is reset so that it outputs slot counter bits denoted by “000 . . . ”. If the slot counter bits “000 . . . ” are output, the RFID tag is activated.

At a time T4, if the test clock TCLK is changed from a low level to a high level, the shift register 602 is deactivated. The shift register 602 continuously outputs the test serial output signal TSO of a high level until it is deactivated by a next test clock TCLK of a low level. If the test serial output signal TSO of a high level is outputted, the slot counter 602 is reset so that it outputs slot counter bits “000 . . . ”. If the slot counter bits “000 . . . ” are output, an RFID tag TAG01 is activated.

At a time T5, if the test clock TCLK is changed from a high level to a low level, the shift register 602 of the RFID tag TAG01 is deactivated. If the shift register 602 is activated, then the shift register 602 stores a value of the test serial input signal TSI, being input to the RFID tag TAG01 at the time T5, and then outputs the stored TSI value as a test serial output signal TSO.

Therefore, the test serial input signal TSI is transitioned to a low level at the time T5, such that the test serial output signal TSO is changed from a high level to a low level. The test serial output signal TSO is further input to a reset terminal of the slot counter 601. Therefore, if it is assumed that the test serial output signal TSO is maintained at a low level, the slot counter 601 is maintained in the set mode so that it outputs slot counter bits “111 . . . ”. If the slot counter bits “111 . . . ” are outputted, the RFID tag TAG01 is deactivated.

In the meantime, the test serial output signal TSO of the RFID tag TAG01 is input to the test serial signal input terminal TSI02.

At the time T5, if the test clock TCLK is changed from a high level to a low level, the shift register 602 of the RFID tag TAG02 is activated. If the shift register 602 is activated, then the shift register 602 stores the value of a test serial input signal TSI being input to the RFID tag TAG02 at the time T5, and then outputs the stored TSI value as a test serial output signal TSO.

In an actual circuit, a slight time delay occurs between a transition time of the test clock TCLK and a transition time of the test serial output signal TSO. That is, the test clock TCLK is changed from a high level to a low level at the time T5. In addition, after the lapse of such a slight time delay, the test serial output signal TSO being input to the RFID tag TAG02 is changed from a high level to a low level. Thus, at the time T5, the test serial output signal TSO being input to the RFID tag TAG02 is high in level, such that the shift register 602 of the RFID tag TAG02 outputs the test serial output signal TSO of a high level.

The test serial output signal TSO is further input to a reset terminal of the slot counter 601. If the test serial output signal TSO is high in level, the slot counter 601 is reset so that it outputs slot counter bits denoted by “000 . . . ”. If the slot counter bits “000 . . . ” are output, the RFID tag TAG02 is activated.

At a time T6, if the test clock TCLK is changed from a low level to a high level, the shift register 602 is deactivated. The shift register 602 continuously outputs the test serial output signal TSO of a high level until it is deactivated by a next test clock TCLK of a low level. If the test serial output signal TSO of a high level is output, the slot counter 602 is reset so that it outputs slot counter bits “000 . . . ”. If the slot counter bits “000 . . . ” are outputted, the RFID tag TAG02 remains activated.

At a time T7, if the test clock TCLK is changed from a high level to a low level, the shift register 602 of the RFID tag TAG02 is deactivated. If the shift register 602 is activated, then the shift register 602 stores a value of the test serial input signal TSI being input to the RFID tag TAG02 at the time T7, and then outputs the stored TSI value as a test serial output signal TSO.

Accordingly, at the time T7, the test serial output signal TSO is low in level and is then input, such that the test serial output signal TSO is changed from a high level to a low level. Therefore, the test serial output signal TSO is transitioned to a low level at the time T5, such that the test serial output signal TSO is also changed from a high level to a low level. The test serial output signal TSO is further input to a reset terminal of the slot counter 601. Therefore, if it is assumed that the test serial output signal TSO is maintained at a low level, the slot counter 601 is maintained in the set mode so that it outputs slot counter bits “111 . . . ”. If the slot counter bits “111 . . . ” are output, the RFID tag TAG02 is deactivated.

Likewise, the test serial output signal TSO of the RFID tag TAG02 is input to the test serial signal input terminal TSI03.

At the time T7, if the test clock TCLK is changed from a high level to a low level, the shift register 602 of the RFID tag TAG03 is activated. If the shift register 602 is activated, then the shift register 602 stores the value of a test serial input signal TSI being input to the RFID tag TAG03 at the time T5, and then outputs the stored TSI value as a test serial output signal TSO.

In an actual circuit, a slight time delay slightly occurs between a transition time of the test clock TCLK and a transition time of the test serial output signal TSO. That is, the test clock TCLK is changed from a high level to a low level at the time T5. In addition, after the lapse of such a slight time delay, the test serial output signal TSO being input to the RFID tag TAG03 is changed from a high level to a low level. Thus, at the time T7, the test serial output signal TSO being input to the RFID tag TAG03 is high in level, such that the shift register 602 of the RFID tag TAG03 outputs the test serial output signal TSO of a high level.

The test serial output signal TSO is further input to a reset terminal of the slot counter 601. Thus, if the test serial output signal TSO is high in level, the slot counter 601 is reset so that it outputs slot counter bits denoted by “000 . . . ”. If the slot counter bits “000 . . . ” are output from the slot counter 601, the RFID tag TAG03 is activated.

At a time T8, if the test clock TCLK is changed from a low level to a high level, the shift register 602 is deactivated. The shift register 602 continuously outputs the test serial output signal TSO of a high level until it is deactivated by a next test clock TCLK of a low level. If the test serial output signal TSO of a high level is output, the slot counter 602 is reset so that it outputs slot counter bits “000 . . . ”. If the slot counter bits “000 . . . ” are output, the RFID tag TAG03 remains activated.

As in the above description, RFID tags TAG04˜TAGN may also be sequentially activated and tested.

Likewise, the test serial output signal TSO is further input to other RFID tags TAG04˜TAGN so as to activate the respective RFID tags, such that the respective RFID tags can be tested during their activation period.

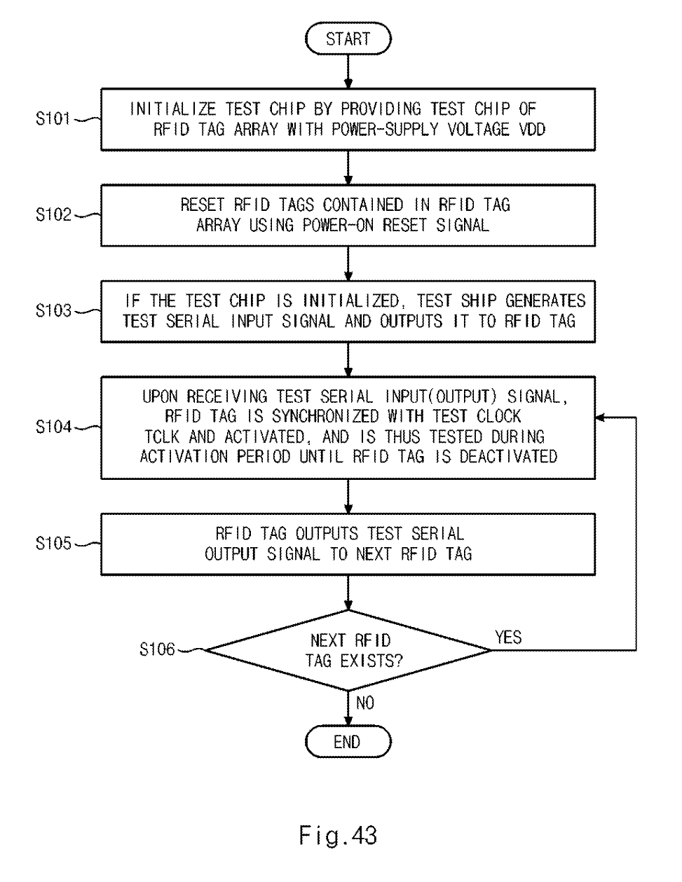

FIG. 43 is a flowchart illustrating a method for sequentially testing a plurality of RFID tags according to third and fourth embodiments of the present invention.

Referring to FIG. 43, a power-supply voltage VDD is applied to a test chip included in an RFID tag array so that the test chip is initialized at step S101. A plurality of RFID tags contained in the RFID tag array is reset by a power-on reset signal POR at step S102.

If the test chip is initialized, then the test chip generates a test serial input signal TSI and outputs it to the RFID tag TAG01 at step S103. If the RFID tag TAG01 receives the test serial input signal TSI, the RFID tag TAG01 is synchronized with a test clock TCLK and thus activated. Then, at step S104, the test chip performs a test operation on the RFID tag TAG01 during an activation period before the RFID tag TAG01 starts deactivation.

The RFID tag TAG01 outputs the test serial output signal to the RFID tag TAG02 at step S105. Thereafter, the above-mentioned test operation wherein the test serial output signal is output to a next RFID tag and this RFID tag is tested is repeated until the last tag chip is activated and tested at step S106.

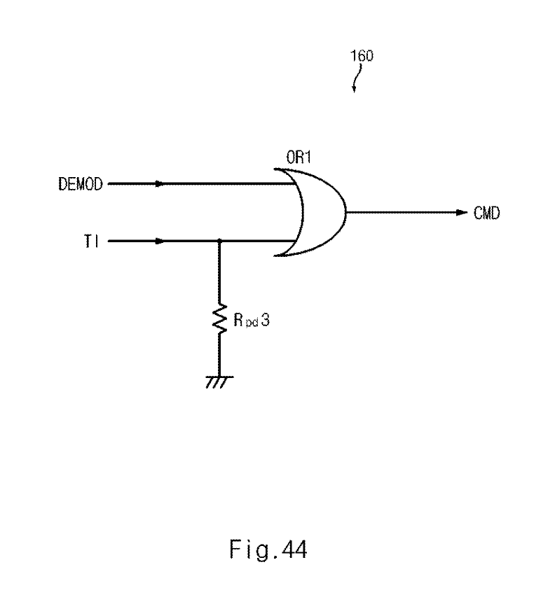

FIG. 44 is a circuit diagram illustrating a test input buffer 60 according to third and fourth embodiments of the present invention.

In the test input buffer 160 shown in FIG. 44, a test input signal T1 and a demodulation signal DEMOD are input to a logic element OR1.

A pad resistor Rpd3 is coupled between an input terminal of the logic OR gate OR1 and a ground terminal.

If a test input signal TI is not input to the test input buffer 160 as a high level signal, the pad resistor Rpd3 allows the input signal TI to be biased.

In more detail, in the case where noise occurs in a test input signal TI so that the test input signal TI has an intermediate level between low and high levels and is then applied to the test input buffer 160, the pad resistor Rpd3 allows the test input signal TI having the intermediate level to be biased to a low level so that no noise is input to the test input buffer 160. However, if the test input signal TI is output to the test input buffer 160 as a high level signal, this high level test input signal TI has its own driving capability so that it is not biased to a low level signal by the pad resistor Rpd3.

The logic element OR1 performs the logic OR operation between the test input signal and the demodulation signal DEMOD. That is, if any one of the test input signal TI and the demodulation signal DEMOD is activated, the logic element OR1 activates the CMD, and outputs it to the digital unit 200.

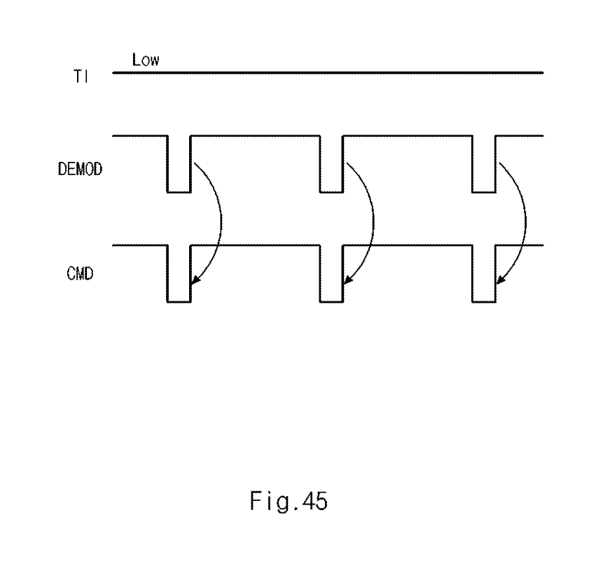

FIG. 45 is a timing diagram illustrating operations of a test input buffer 160 under the condition that the RFID tag is deactivated according to third and fourth embodiments of the present invention.

Referring to FIG. 45, if the test input signal TI of a low level is input to the test input buffer 160, it is impossible to perform the test operation of the RFID tag. If the demodulation signal DEMOD is input to the test input buffer 160, the command signal CMD is synchronized with the demodulation signal DEMOD so that it is activated. That is, if the demodulation signal DEMOD of a high level is input to the test input buffer 160, the command signal CMD is output as a high level signal. If the demodulation signal DEMOD of a low level is input to the test input buffer 160, the command signal CMD is output as a low level signal.

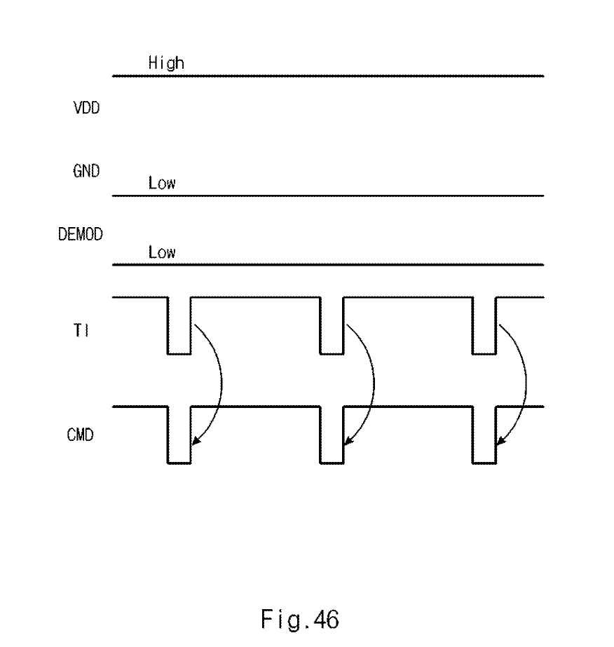

FIG. 46 is a timing diagram illustrating operations of the test input buffer 160 under an RFID tag is activated according to third and fourth embodiments of the present invention.

Referring to FIG. 46, a power-supply voltage VDD and a ground voltage GND are applied to the RFID tag. If the test operation is performed in the RFID tag, it is preferable that an RF signal is not received in the RFID tag, such that the demodulation signal DEMOD of a low level is input to the test input buffer 160. The test input buffer 160 is synchronized with the test input signal TI, such that it outputs a command signal CMD. In other words, if the test input signal TI of a high level is input to the test input buffer 160, the command signal of a high level is output from the test input buffer 160. If the test input signal TI of a low level is input to the test input buffer 160, the command signal CMD of a low level is output.

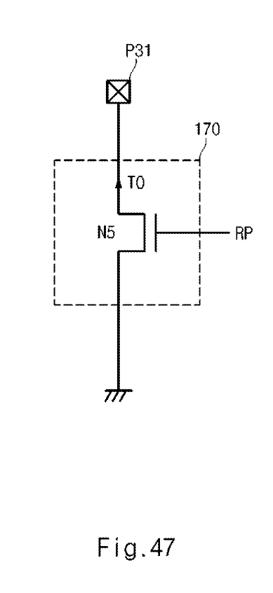

FIG. 47 is a circuit diagram illustrating the test output driver 170 according to an embodiment of the present invention.

Referring to FIG. 47, the test output driver 170 includes an NMOS transistor N5 equipped with an open drain structure. The NMOS transistor N5 receives a response signal RP through a gate terminal, a source terminal is coupled to the ground terminal, and a drain terminal is coupled to a test signal output pad P31.

If the response signal RP of a high level is input to the test output driver 170, the NMOS transistor N5 is turned on. Therefore, the source and drain terminals are turned on, so that the test output signal TO is driven at a low level. If the response signal RP of a low level is input to the test output driver 170, the NMOS transistor N5 is turned off. Therefore, the source terminal and the drain terminal are blocked, such that the test output signal TO is driven at a high level.

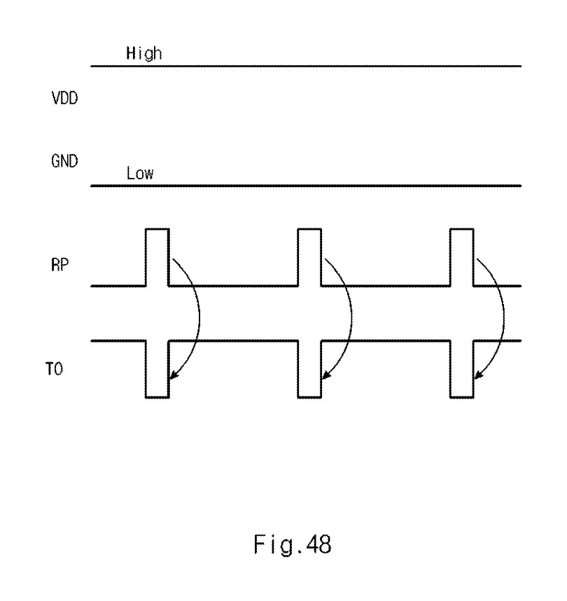

FIG. 48 is a timing diagram illustrating operations of the test output driver 170 according to third and fourth embodiments of the present invention.

Referring to FIG. 48, a power-supply voltage VDD and a ground voltage GND are applied to the RFID tag. If the response signal RP of a low level is input to the test output driver 170, an NMOS transistor N5 is turned off, such that the test output signal TO of a high level is output from the test output driver 170. On the other hand, if the response signal RP of a high level is input to the test output driver 170, the NMOS transistor N5 is turned on, such that the test output driver 170 outputs the test output signal TO of a low level. That is, the test output driver 170 outputs the test output signal TO having a phase opposite to that of the response signal RP to the test signal output pad 14.

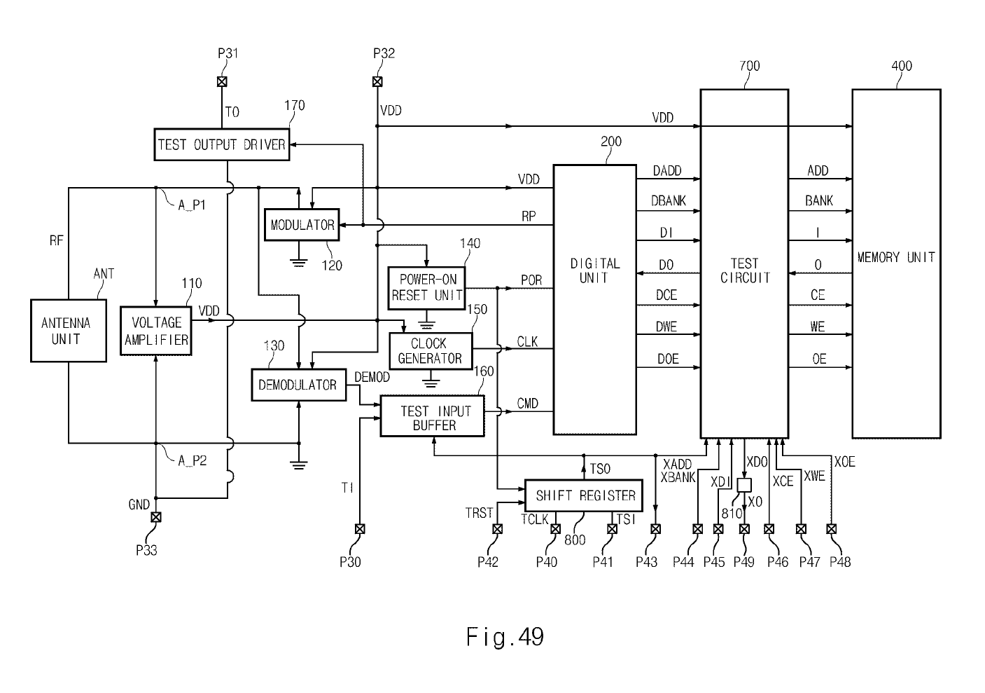

FIG. 49 is a structural diagram illustrating an RFID device according to a fifth embodiment of the present invention.

Referring to FIG. 49, the RFID device according to the fifth embodiment of the present invention includes an antenna unit ANT, a voltage amplifier 110, a modulator 120, a demodulator 130, a power-on reset unit 140, a clock generator 150, a test input buffer 160, a test output driver 170, a shift register 800, a digital unit 200, a test circuit 700, and a memory unit 400.

The antenna unit ANT receives one or more RF signals from an RFID reader. The received RF signal is transmitted to the voltage amplifier 110 via antenna pads A_P1 and A_P2. The voltage amplifier 110 rectifies and boosts the RF signal received via the antenna unit ANT, and generates a power-supply voltage serving as an RFID-tag drive voltage.

The modulator 120 modulates a response signal RP received from the digital unit 200, and outputs the modulated response signal RP to the RFID reader via the antenna unit ANT.

The demodulator 130 demodulates the RF signal received from the antenna unit ANT in response to the output voltage of the voltage amplifier 110 so as to generate a demodulation signal DEMOD, and outputs the generated demodulation signal DEMOD to the test input buffer 160.

The power-on reset unit 140 detects a power-supply voltage generated in the voltage amplifier 110, and outputs a power-on reset signal POR to the shift register 800 and the digital unit 200 so as to control a reset operation in response to the detected power-supply voltage. The clock generator 150 outputs a clock CLK to the digital unit 200, wherein the clock CLK is capable of controlling operations of the digital unit 200 in response to the power-supply voltage output from the voltage amplifier 110.

The test input buffer 160, in response to a test input signal T1 from a test signal input pad P30 and the demodulation signal DEMOD from the demodulator 130, detects an operation command signal, and therefore generates a command signal CMD.

A power-supply voltage applying pad P32 is a pad capable of receiving a power-supply voltage VDD when testing a plurality of RFID tags on a wafer. A ground voltage applying pad P33 is a pad capable of receiving a ground voltage GND when testing a plurality of RFID tags on a wafer.

In other words, if the RFID tag receives an RF signal from the RFID reader by communicating with the RFID reader, the voltage amplifier 110 provides the power-supply voltage VDD. In contrast, when testing the RFID tag on a wafer according to the fifth embodiment of the present invention, the RFID device shown in FIG. 49 receives the power-supply voltage VDD and the ground voltage GND via an additional power-supply voltage applying pad P32 and an additional ground voltage applying pad P33, respectively. The test output driver 170 drives a response signal RP received from the digital unit 200, such that it generates the test output signal TO.

The digital unit 200 receives a power-supply voltage VDD, a power-on reset signal POR, and a clock CLK, analyzes a command signal CMD using the received signals, and generates a control signal and process signals. The digital unit 200 outputs a response signal RP corresponding to the control and process signals to the modulator 120.

The test circuit 700 is activated by a test serial output signal TSO that has been generated by activation of the shift register 800. If the test circuit 700 is activated, upon receiving either addresses XADD and XBANK, input data XDI, and control signals XCE, XWE, and XOE from an external device or receiving addresses DADD and DBANK, input data DI, and control signals DCE, DWE, and DOE from the digital unit 200, the test circuit 700 tests internal circuits contained in the RFID tag, the digital unit 200, and the memory 400. Herein, it should be noted that the term “internal circuit” conceptually includes a voltage amplifier 110, a modulator 120, a demodulator 130, a power-on reset unit 140, a clock generator 150, a test input buffer 160, and a test output driver 170.

The digital unit 200 generates addresses DADD and DBANK, data DI, and control signals DCE, DWE, and DOE, upon receiving a command signal CMD generated by the test input signal TI received via the test signal input pad P30. The test circuit 700 generates addresses ADD and BANK, data I, and control signals CE, WE, and OE in response to addresses DADD and DBANK, data DI and control signals DCE, DWE, and DOE, and thus tests the memory unit 40. The test circuit 700 receives the control result signal O indicating a test result from the memory unit 400, and generates a control result signal DO. The digital unit 200 generates a response signal RP in response to the control result signal DO, and outputs the response signal RP to the response signal RP, such that the test output driver 170 outputs the response signal RP via the test signal output pad P31.

Upon receiving not only addresses XADD and XBANK from the address input pad P44, but also data XDI and control signals XCE, XWE, and XOE from the control signal input pads P45˜P48, the test circuit 700 generates addresses ADD and BANK, data I and control signals CE, WE and OE, such that it tests the memory unit 400 using the generated information. The test circuit 700 receives the control result signal O indicating a test result from the memory unit 400, and generates output data XDO. The test circuit 700 outputs output data XDO, and transmits the output data XDO to the control output driver 810, such that the output data XDO is output from the control signal output pad P49.

The memory unit 400 includes a plurality of memory cells, each of which writes and reads data in/from a storage unit.

The memory unit 400 may be a non-volatile ferroelectric memory (FeRAM). The FeRAM has a data processing speed similar to that of a DRAM. Also, the FeRAM has a structure very similar to that of DRAM, and uses a ferroelectric substance as a capacitor material so that it has high residual polarization characteristics. Due to the high residual polarization characteristics, data is not lost although an electric field is removed.

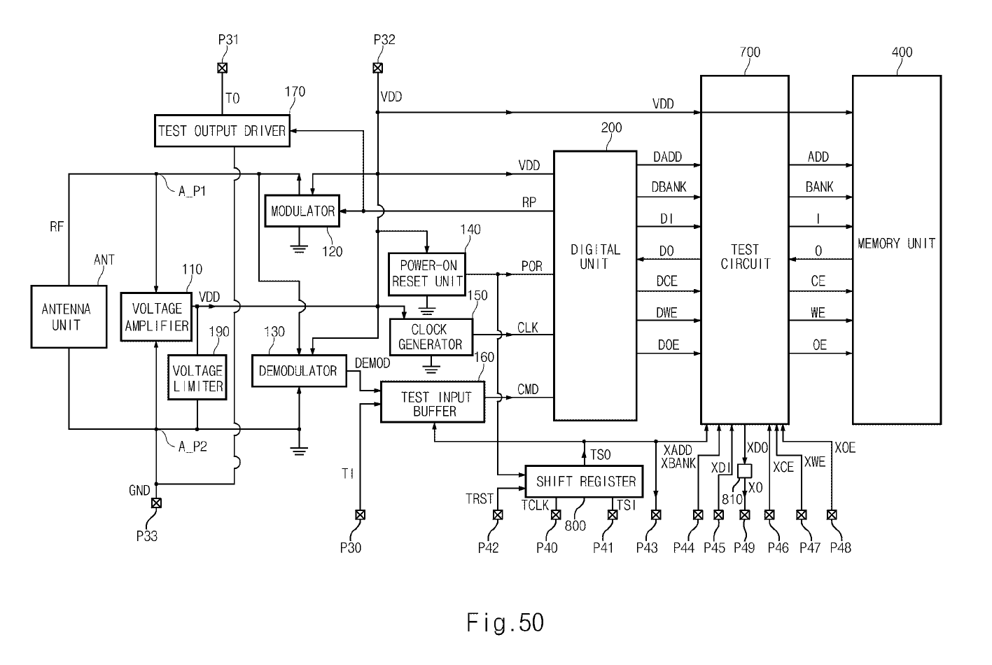

FIG. 50 is a structural diagram illustrating an RFID device according to a sixth embodiment of the present invention.

Referring to FIG. 50, the RFID device according to the sixth embodiment of the present invention includes an antenna unit ANT, a voltage amplifier 110, a modulator 120, a demodulator 130, a power-on reset unit 140, a clock generator 150, a test input buffer 160, a test output driver 170, a digital unit 200, a test circuit 700, and a memory unit 400.

The antenna unit ANT, the digital unit 200, the test circuit 700, and the memory unit 400 shown in the sixth embodiment are substantially equal to those in the fifth embodiment, but the sixth embodiment further includes a voltage limiter 190 in a different way from the fifth embodiment. In order to substantially prevent an internal circuit of the RFID tag from being damaged by an unexpected voltage abruptly exceeding the power-supply voltage VDD, the voltage limiter 190 limits the magnitude of either a voltage amplified by the voltage amplifier 110 or an externally-received power-supply voltage to a predetermined voltage level value or less.

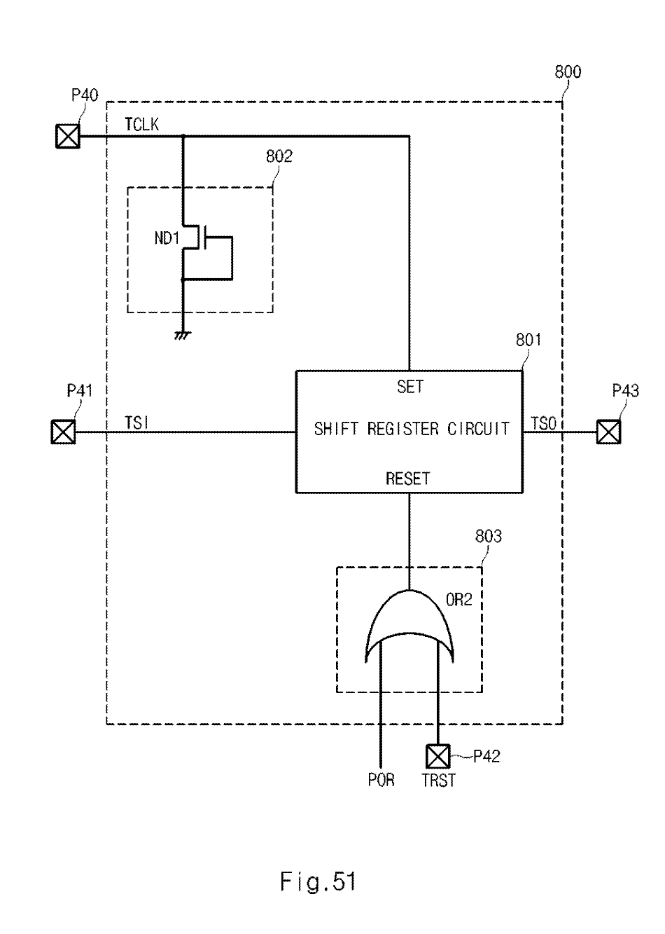

FIG. 51 is a detailed circuit diagram illustrating the shift register 800 according to fifth and sixth embodiments of the present invention. The shift register 800 includes a shift register circuit 801, an electrostatic protection unit 802, and an input buffer 803.

Referring to FIG. 51, the shift register circuit 801 stores the value of a test serial input signal TSI from the test chip or the value of a test serial output signal TSO from another RFID tag. If the shift register 801 is activated by the test clock TCLK, the shift register circuit 801 outputs either a value of the test serial input signal TSI or a value of a test serial output signal TSO received from another RFID tag as the test serial output signal TSO.

The shift register circuit 801 is reset by either a power-on reset signal POR received from the power-on reset unit 140 or a test reset signal TRST received from the test reset signal input pad P42. If the shift register circuit 801 is reset, it outputs the test serial output signal TSO of a low level irrespective of an input signal.

The test clock TCLK is input to the shift register 800 through the test clock input pad P40. An electrostatic protection unit 802 is coupled in parallel between the test clock input pad P40 and the ground terminal.

The electrostatic protection unit 802 includes an NMOS transistor ND1. In the NMOS transistor ND1, a gate terminal and a source terminal are coupled to a ground terminal, and a drain terminal is coupled to the test clock input pad P40. The NMOS transistor ND1 couples its own gate terminal to the ground terminal, such that it maintains an OFF status. However, if a high voltage is instantaneously applied to the electrostatic protection unit 802 due to static electricity generated in the test clock input pad P40, the NMOS transistor ND1 is turned on, such that a current flows in the ground terminal. Therefore, the electrostatic protection unit 802 substantially prevents a high current from flowing in the shift register circuit 801.

The input buffer 803 receives a power-on reset signal POR and a test rest signal TRST, such that it outputs a reset signal to a reset terminal of the shift register circuit 801. The input buffer 803 may be implemented as a logic OR element OR2.

If the power-on reset signal POR of a high level is input to the shift register 800, i.e., if a power-supply voltage begins to flow in a RFID tag, the power-on reset signal POR of a high level is input to the input buffer 803. The logic OR gate OR2 outputs a reset signal as a high level signal, such that it resets the shift register circuit 801. Therefore, the shift register circuit 801 outputs a test serial output signal TSO of a low level, irrespective of an input signal.

If the logic OR gate OR2 receives a test reset signal TRST of a high level from an external device so as to reset the shift register circuit 801, the logic OR gate OR2 outputs a reset signal of a high level, so that it resets the shift register circuit 801. Therefore, the shift register circuit 801 outputs a test serial output signal TSO of a low level irrespective of an input signal.

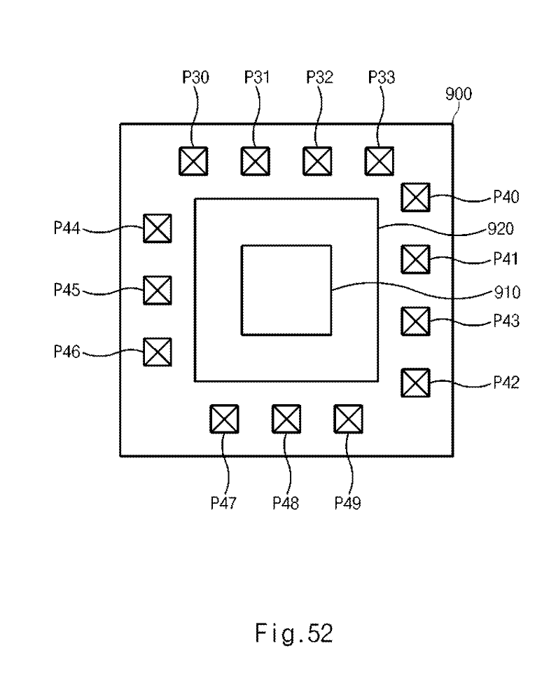

FIG. 52 is a structural diagram illustrating an Input/Output (I/O) pad 900 of the RFID device according to fifth and sixth embodiments of the present invention.

Referring to FIG. 52, the I/O pad 900 according to the fifth and sixth embodiments includes an I/O circuit unit 910 at a center part thereof. The I/O pad 900 further includes a test signal input pad P30, a test signal output pad P31, a power-supply voltage applying pad P32, a ground voltage applying pad P33, a test clock input pad P40, a test serial signal input pad P41, a test serial signal output pad P43, a test reset signal input pad P42, an address input pad P44, control signal input pads P45˜P48, and a control signal output pad P49 in a peripheral area of the center part. The electrostatic protection unit 920 substantially prevents the I/O circuit 910 from being damaged by static electricity generated from the input pads.

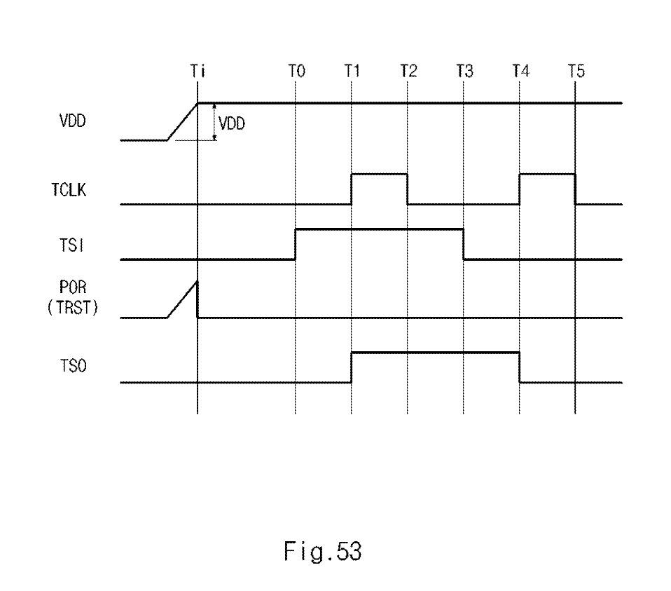

FIG. 53 is a timing diagram illustrating operations of the shift register 800 contained in the RFID tag TAG01 according to fifth and sixth embodiments of the present invention.

Referring to FIG. 53, at a time Ti, the power-supply voltage VDD is applied to a test chip, such that the test chip is initialized. In this case, the power-on reset signal POR is initialized from a low level to a high level. The power-on reset signal POR is input to the shift register circuit 801, such that it resets the shift register circuit 801. Even when the test reset signal TRST of a high level is input to the shift register 800 at the time Ti, the shift register circuit 801 is also reset.

At a time T0, the test serial input signal TSI is changed from a low level to a high level. That is, the test serial input signal TSI is applied from the test chip to the test serial signal input terminal TSI01 of the RFID tag TAG01. The test serial input signal TSI input to the RFID tag TAG01 is applied to the shift register circuit 801 of the shift register 800.

At a time T1, if the test clock TCLK of a high level is input to the shift register 800, the shift register circuit 801 stores the value of the test serial input signal TSI acquired at the time T1, and outputs the stored TSI value as the test serial output signal TSO. Because the test serial input signal TSI of a high level is input to the shift register 800 at the time T1, the shift register 800 outputs the test serial output signal TSO of a high level.

The shift register circuit 801 is set by the test clock TCLK. Therefore, the test serial output signal TSO is continuously maintained at a high level in the range from one time T1 of receiving the test clock TCLK of a high level to another time T4 of receiving the test clock TCLK of a high level. Accordingly, although the test clock TCLK is transitioned to a low level at the time T2, or the test serial input signal TSI is transitioned to a low level at the time T3, the test serial output signal TSO of a high level is output from the shift register circuit 801.

In order to deactivate the RFID tag TAG01, it is preferable that the test serial input signal TSI be set to a low level before the next test clock TCLK is output as a high level signal. In other words, while the test serial input signal TSI begins to be input as a low level signal to the RFID tag TAG01 in the embodiments of the present invention, there is a need only for the test serial input signal TSI to be input as a low level signal to the RFID tag TAG01 in the range from one time T1 to the other time T4 so as to accomplish purposes of the present invention.

If the test serial output signal TSO of a high level is output, the test circuit 700 is activated, such that a test operation can be carried out while the test serial output signal TSO of a high level is output.

If the test clock TCLK of a high level signal is input at a time T4, the shift register circuit 801 stores the value of a test serial input signal TSI acquired at the time T4, and outputs the stored TSI value as a test serial output signal TSO. Since the test serial input signal TSI of a low level is input at the time T4, the test serial output signal TSO of a low level is output at the time T4. If the test serial output signal TSO of a low level is output at the time T4, the test circuit 700 is deactivated, such that the test circuit is unable to perform the test operation.

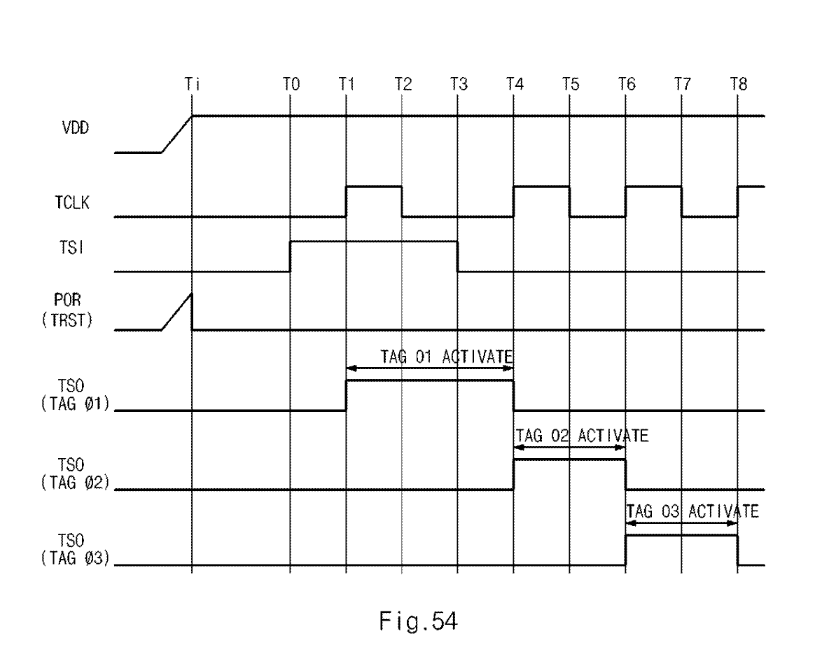

FIG. 54 is a timing diagram illustrating that a plurality of RFID tags are sequentially activated according to fifth and sixth embodiments of the present invention.

Referring to FIG. 54, at a time Ti, the power-supply voltage VDD is applied to a test chip, such that the test chip is initialized. At this time Ti, the power-on reset signal POR is also input to the shift register circuit 801, such that the shift register circuit 801 is also initialized by the power-on reset signal POR. Even when the test reset signal TRST of a high level is input to the shift register 800 at the time Ti, the shift register circuit 801 is also reset.

At a time T0, the test serial input signal TSI is changed from a low level to a high level. That is, the test serial input signal TSI is applied from the test chip to the test serial signal input terminal TSI01 of the RFID tag TAG01. The test serial input signal TSI input to the RFID tag TAG01 is applied to the shift register circuit 801 of the shift register 800.

At a time T1, if the test clock TCLK of a high level is input to the shift register 800, the shift register circuit 801 stores the value of the test serial input signal TSI acquired at the time T1, and outputs the stored TSI value as the test serial output signal TSO. Because the test serial input signal TSI of a high level is input to the shift register 800 at the time T1, the shift register 800 outputs the test serial output signal TSO of a high level.

The shift register circuit 801 is set by the test clock TCLK. Therefore, the test serial output signal TSO is continuously maintained at a high level in the range from one time T1 of receiving the test clock TCLK of a high level to another time T4 of receiving the test clock TCLK of a high level. Accordingly, the test clock TCLK is transitioned to a low level at the time T2. Although the test serial input signal TSI is transitioned to a low level at the time T3, the test serial output signal TSO of a high level is output from the shift register circuit 801.

In order to deactivate the RFID tag TAG01, it is preferable that the test serial input signal TSI be set to a low level before the next test clock TCLK is output as a high level signal. In other words, while the test serial input signal TSI begins to be input as a low level signal to the RFID tag TAG01 in the embodiments of the present invention, there is a need only for the test serial input signal TSI to be input as a low level signal to the RFID tag TAG01 in the range from one time T1 to the other time T4 so as to accomplish purposes of the present invention.

If the RFID tag TAG01 outputs the test serial output signal TSO of a high level, the test circuit 700 is activated. As a result, a test operation can be carried out while the test serial output signal TSO of a high level is output.

If the test clock TCLK of a high level signal is input at a time T4, the shift register circuit 801 of the RFID tag TAG01 stores the value of a test serial input signal TSI acquired at the time T4, and outputs the stored TSI value as a test serial output signal TSO. Since the test serial input signal TSI of a low level is input at the time T4, the test serial output signal TSO of a low level is output at the time T4. If the RFID tag TAG01 outputs the test serial output signal TSO of a low level at the time T4, the test circuit 700 is deactivated, such that the RFID tag TAG01 is also deactivated.

In the meantime, the test serial output signal TSO of the RFID tag TAG01 is input to the test serial signal input terminal TSI02 of the RFID tag TAG02.

At a time T4, the test clock TCLK of a high level is input to the RFID tag TAG02. The shift register circuit 801 of the RFID tag TAG02 stores a value of the test serial output signal TSO acquired at the time T4. Thereafter, the test serial output signal TSO is output through the test serial signal output terminal TSO02 of the RFID tag TAG02.

If the test clock TCLK of a high level is input to the RFID tag TAG01 at the time T4, the test serial output signal TCLK of the RFID tag TAG01 is changed from a high level to a low level at the time T4. In an actual circuit, a slight time delay occurs between a transition time of the test clock TCLK and a transition time of the test serial output signal TSO. At the time T4, the test serial output signal TSO being input to the RFID tag TAG02 is high in level. Therefore, the shift register circuit 801 of the RFID tag TAG02 stores a high level value therein, and outputs the high level test serial output signal TSO through the output pad TSO02 of the RFID tag 02.

If the test serial output signal TSO being output from the shift register 800 of the RFID tag TAG02 is output as a high level signal, the test circuit 700 of the RFID tag TAG02 becomes activated. Accordingly, the test operation for the RFID tag TAG02 can be carried out while the test serial output signal TSO is output as a high level signal.

The shift register circuit 801 of the RFID tag TAG02 is set by the test clock TCLK. Therefore, the test serial output signal TSO is continuously maintained at a high level in the range from one time T4, where the high level test clock TCLK is input to the shift register circuit 801, to the other time T6, where the high level test clock TCLK is again input to the shift register circuit 801. Therefore, although the test clock TCLK is transitioned to a low level at a time T5, the test serial output signal TSO being output from the shift register 800 of the RFID tag TAG02 remains high in level until reaching a next time T6.

If the test clock TCLK of a high level signal is input at a time T6, the shift register circuit 801 of the RFID tag TAG02 stores the value of a test serial output signal TSO being input to the RFID tag TAG02 at the time T6, and outputs the stored TSO value as a test serial output signal TSO. Since the test serial input signal TSI of a low level is input to the RFID tag TAG02 at the time T6, the test serial output signal TSO is output as a low level signal at the time T6.

If the test serial output signal TSO of a low level is output from the shift register circuit 801 of the RFID tag TAG02, this means that the test circuit 700 is deactivated, such that the RFID tag TAG02 is also deactivated.

The test serial output signal TSO of the RFID tag TAG02 is also input to the test serial signal input terminal TSI02 of the RFID tag TAG03.

If the test clock TCLK of a high level is input to the RFID tag TAG03 at the time T6, the shift register circuit 801 of the RFID tag TAG03 stores the value of a test serial output signal TSO being input at the time T6, and then outputs the stored TSO value as a test serial output signal TSO through the test serial signal output terminal TSO03 of the RFID tag TAG03.

If the test clock TCLK of a high level is input at the time T6, the test serial output signal TSO of the RFID tag TAG02 is changed from a high level to a low level at the time T6. In an actual circuit, a slight time delay occurs between a transition time of the test clock TCLK and a transition time of the test serial output signal TSO. At the time T6, the test serial output signal TSO being input to the RFID tag TAG03 is high in level. Therefore, the shift register circuit 801 of the RFID tag TAG03 stores a high level value. In addition, the shift register circuit 801 outputs the test serial output signal TSO of a high level through the output terminal TSO03 of the RFID tag TAG03.

If the test serial output signal TSO being output from the shift register 800 of the RFID tag TAG03 is output as a high level signal, the test circuit 700 of the RFID tag TAG03 becomes activated. Accordingly, the test operation for the RFID tag TAG03 can be carried out while the test serial output signal TSO is output as a high level signal.

The shift register circuit 801 of the RFID tag TAG03 is set by the test clock TCLK. Therefore, the test serial output signal TSO is continuously maintained at a high level in the range from a time T6, where the high level test clock TCLK is input to the shift register circuit 801, to a time T8, where the high level test clock TCLK is again input to the shift register circuit 801. Therefore, although the test clock TCLK is transitioned to a low level at the time T7, the test serial output signal TSO being output from the shift register 800 of the RFID tag TAG3 remains high in level until reaching a next time T8.

If the test clock TCLK of a high level signal is input at a time T6, the shift register circuit 801 of the RFID tag TAG03 stores the value of a test serial output signal TSO being input to the RFID tag TAG03 at the time T8, and outputs the stored TSO value as a test serial output signal TSO. Since the test serial input signal TSI of a low level is input to the RFID tag TAG03 at the time T8, the test serial output signal TSO is output as a low level signal at the time T8.

If the test serial output signal TSO of a low level is output from the shift register circuit 801 of the RFID tag TAG03, this means that the test circuit 700 is deactivated, such that the RFID tag TAG03 is also deactivated.

Likewise, the test serial output signal TSO of the RFID tag TAG03 is input to the test serial signal input terminal TSI04 of the RFID tag TAG04. In addition, RFID tags TAG04˜TAGN are sequentially activated as described above, such that the test operation for such RFID tags TAG04˜TAGN can be carried out during the activation period of the RFID tags TAG04˜TAGN.

The test operation for the activation period is as follows.

The test operation may be carried out by an analog circuit unit, the digital unit 200 or the memory unit 400 according to a user's intention related to the RFID tag. Herein, it should be noted that the term “analog circuit unit” conceptually includes a voltage amplifier 110, a modulator 120, a demodulator 130, a power-on reset unit 140, a clock generator 150, a test input buffer 160, and a test output driver 170.

For example, when performing the test operation on the memory unit 400, reset data is written in the memory unit 400. The test input signal TI is input via an I/O pad. The test input signal TI is input to the test input buffer 160 so that a command signal CMD is generated. The command signal CMD includes an operation signal that causes data written in the RFID tag to be read.

The test circuit 700 reads the data written in the memory unit 400 using control signals in response to the command signal CMD. The response signal RP generated from the digital unit 200 includes information about the read data. The response signal RP is driven by the test output driver 170, and is output in a form of a test output signal TO through the test signal output pad P31. The digital unit 200 acquires information about the read data from the test output signal TO. An external test device located outside of the RFID tag compares the read data with the written data, and determines whether the read data is substantially equal to the written data. If the read data is substantially equal to the written data, the digital unit 200 decides that the memory unit 400 is in a normal mode. Otherwise, the digital unit 200 decides that the memory unit 400 is in a failed mode, so that the test operation for the memory unit 400 is completed.

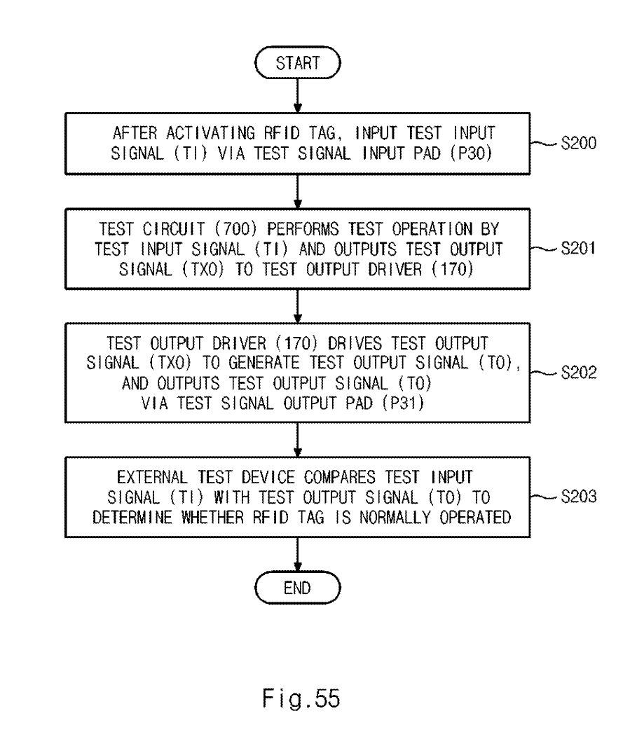

FIG. 55 is a flowchart illustrating a method for testing each of several RFID tags contained in an RFID tag array according to a first embodiment of the present invention.

Referring to FIG. 55, when each RFID tag is activated, a test input signal TI is input via the test signal input pad P30 of this RFID tag at step S200. The test circuit 700 performs the test operation upon receiving a test input signal TI, and outputs the test result signal TXO to the test output driver 170 at step S201.

The test output driver 170 generates a test output signal TO by operating the test result signal TXO, and outputs the test output signal TO to an external device via the test signal output pad P31 at step S202. An external test device compares the test input signal TI with the test output signal TO, such that it determines whether the RFID tag is normally operated at step S203.

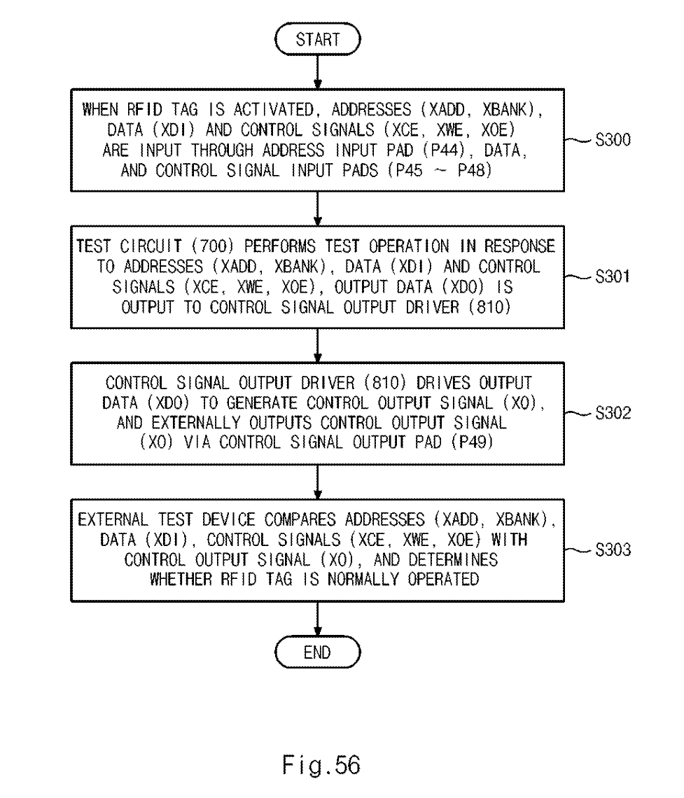

FIG. 56 is a flowchart illustrating a method for testing each of several RFID tags contained in an RFID tag array according to fifth and sixth embodiments of the present invention.

When the RFID tag is activated, addresses XADD and XBANK, input data XDI, and control signals XCE, XWE and XOE are input via the address input pad P44 and the control signal input pads P45˜P48 of the RFID tag at step S300. The test circuit 700 performs the test operation in response to the addresses XADD and XBANK, the input data XDI, and the control signals XCE, XWE and XOE, and outputs output data XDO to the control signal output driver 810 at step S301.

The control signal output driver 810 generates a control output signal XO by operating the output data XDO, and outputs the control output signal XO to an external device through the control signal output pad P49 at step S302. An external test device compares the addresses XADD and XBANK, input data XDI, and control signals XCE, XWE and XOE with the control output signal XO, such that it determines whether the RFID tag is normally operated at step S303.

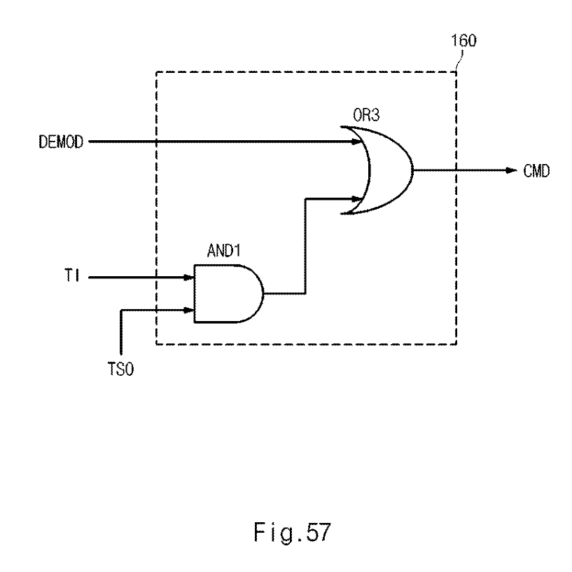

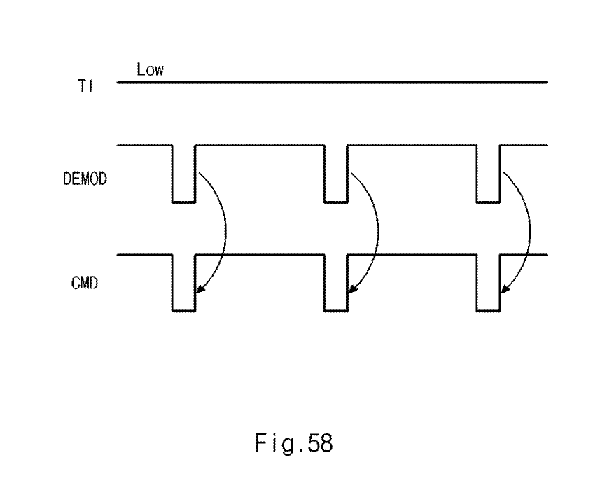

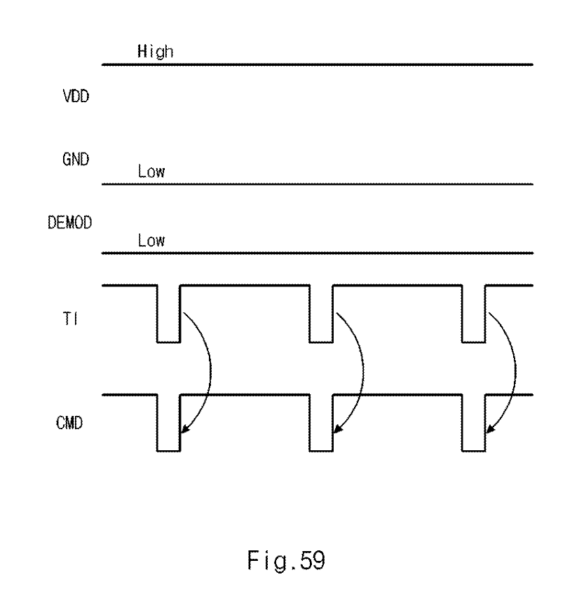

FIG. 57 is a detailed circuit diagram illustrating the test input buffer 160 according to fifth and sixth embodiments of the present invention.

Referring to FIG. 57, the test input buffer 160 receives a demodulation signal DEMOD from the demodulator 130, receives a test input signal TI from an external device, and receives a test serial output signal TSO from the shift register 800.

The test input signal TI and the test serial output signal TSO are input to the logic AND element AND1. The logic AND element AND1 performs a logic AND operation between the test input signal TI and the test serial output signal TSO.

The logic OR element OR3 receives the demodulation signal DEMOD and an output signal of the logic AND element AND1, performs a logic OR operation between the demodulation signal DEMOD and the output signal of the logic AND element AND1, and generates a command signal CMD. The command signal CMD is output to the digital unit 200.

FIG. 58 is a timing diagram illustrating operations of the test input buffer 160 under the condition that an RFID tag is deactivated according to fifth and sixth embodiments of the present invention.

Referring to FIG. 58, since an RFID tag is deactivated, it is impossible to perform the test operation on the RFID tag. Because the test operation cannot be performed on the RFID tag, the test input signal TI is also input as a low level signal to the test input buffer 160. If the test input signal TI of a low level is input to the test input buffer 160, the logic AND element AND1 performs a logic AND operation, such that it outputs a low level signal.

The logic OR element OR3 performs a logic OR operation. Since the output signal of the logic AND element AND1 is low in level, the logic OR element OR3 generates a command signal CMD in response to the demodulation signal DEMOD. That is, when the demodulation signal of a high level is input to the logic OR element OR3, the logic OR element OR3 outputs the command signal CMD of a high level. Upon receiving the demodulation signal of a low level, the logic OR element OR3 outputs the command signal CMD of a low level.

FIG. 59 is a timing diagram illustrating operations of the test input buffer 160 under the condition that an RFID tag is activated according to fifth and sixth embodiments of the present invention.

Referring to FIG. 59, if an RFID tag is activated, this RFID tag can be tested by a test input signal TI. If the RFID tag was activated, a power source voltage reaches a power-supply voltage level (VDD), and a ground voltage reaches a ground voltage level (GND). If the test input signal TI of a low level is input to the test input buffer 160, the logic AND element AND1 performs a logic AND operation so that it outputs a low level signal.

Because the RFID tag is activated, the test serial output signal TSO of a high level is input to the logic AND element AND1. The logic AND element AND1 performs a logic AND operation, so that a signal synchronized with the test input signal TI is output from the logic AND element AND1.

During the test operation, the demodulation signal DEMOD of a low level is input to the test input buffer 160. The logic OR element OR3 performs a logic OR operation between the demodulation signal DEMOD and the output signal of the logic AND element AND1, so that it generates a command signal CMD. In other words, the test input signal TI of a high level is input to the test input buffer 160, the test input buffer 160 outputs the command signal of a high level. If the test input signal TI of a low level is input to the test input buffer 160, the command signal CMD of a low level is output from the test input buffer 160.

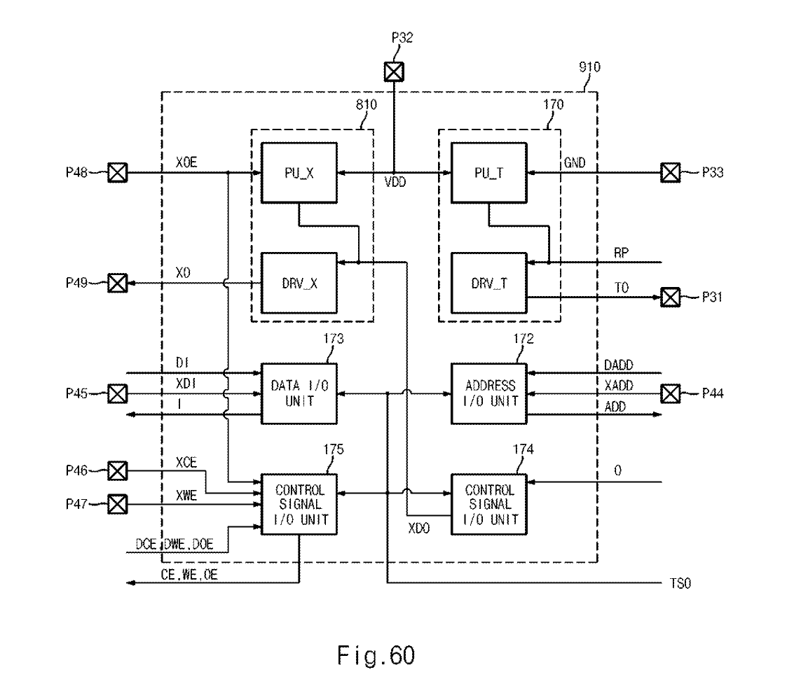

FIG. 60 is a detailed block diagram illustrating an I/O circuit unit 910 according to fifth and sixth embodiments of the present invention.

Referring to FIG. 60, the I/O circuit unit 910 includes a test output driver 170, a control output driver 810, an address input/output (I/O) unit 172, a data input/output (I/O) unit 173, and control signal input/output (I/O) units 174 and 175.

The test output driver 170 includes a pull-up driver PU_T and a driver DRV_T. The pull-up driver PU_T is coupled to a ground terminal, so that it pulls up a response signal RP being output from the digital unit 200. The driver DRV_T generates a test output signal TO by operating on the response signal RP being output from the digital unit 200, so that it outputs externally the test output signal TO via the test signal output pad P31.

The control output driver 810 includes a pull-up driver PU_X and a driver DRV_X. The pull-up driver PU_X selectively pulls up output data XDO in response to a control signal XOE being input via the control signal input pad P48. The driver DRV_X operates output data XDO being output from the control signal I/O unit 174, generates a control output signal XO, and externally outputs the control output signal XO via the control signal output pad P49.

The address I/O unit 172 includes a plurality of logic OR elements OR coupled in parallel to each other. Each logic OR element OR receives an address XADD from an external device, receives an address DADD from the digital unit 200, receives the test serial output signal TSO from the shift register 800, generates an address ADD, and outputs the addresses ADD to the memory unit 400.

The data I/O unit 173 includes a plurality of logic OR elements coupled in parallel to each other. Each logic OR element receives input data XDI from an external device, receives a control signal DI from the digital unit 200, receives the test serial output signal TSO from the shift register 800, generates a control signal I, and outputs the control signal I to the memory unit 400.

The control signal I/O unit 174 includes a plurality of logic XOR elements coupled in parallel to each other. Individual logic XOR elements receive a control signal O from the memory unit 400, receive the test serial output signal TSO from the shift register 800, generate output data XDO, and output the output data XDO to the control output driver 810.

The control signal I/O unit 175 includes a plurality of logic OR elements coupled in parallel to each other. Each logic OR element receives control signals DCE, DWE, and DOE from the digital unit 200, receives control signals XCE, XWE and XOE from an external device, generates control signals CE, WE and OE, and outputs the control signals CE, WE and OE to the memory unit 400.

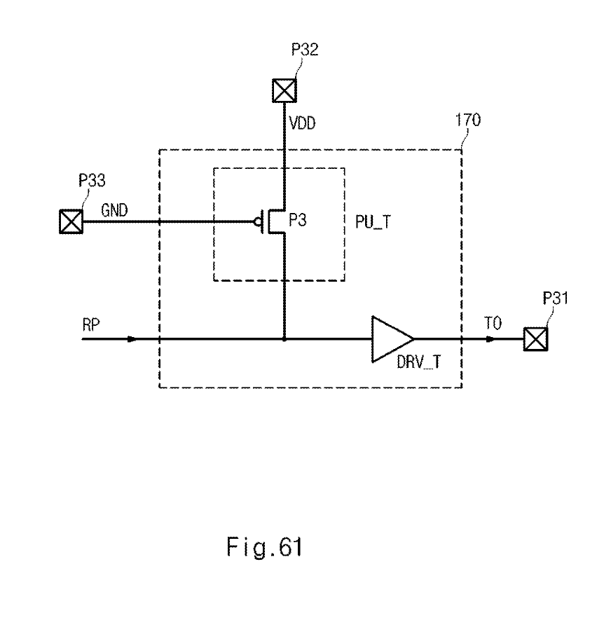

FIG. 61 is a detailed circuit diagram illustrating a test output driver 170 according to fifth and sixth embodiments of the present invention.

Referring to FIG. 61, the test output driver 170 includes a pull-up driver PU_T and a driver DRV_T. The pull-up driver PU_T includes a PMOS transistor P3. A ground voltage GND from the ground voltage applying pad P33 is applied to the gate terminal of the PMOS transistor P3. A power-supply voltage VDD from the power-supply voltage applying pad P32 is input to a drain terminal of the PMOS transistor P3. A source terminal of the PMOS transistor P3 is coupled to an input terminal of the driver DRV_T. A ground voltage GND is applied to a gate terminal of the PMOS transistor P3, so that the PMOS transistor P3 is kept in an ON status. Therefore, the pull-up driver PU_T pulls up the response signal RP being input to the driver DRV_T.

Since the pull-up driver PU_T is always activated, the driver DRV_T operates the response signal RP received from the digital unit 200. The driver DRV_T generates a test output signal TO, and outputs the test output signal TO through the test signal output pad P31.

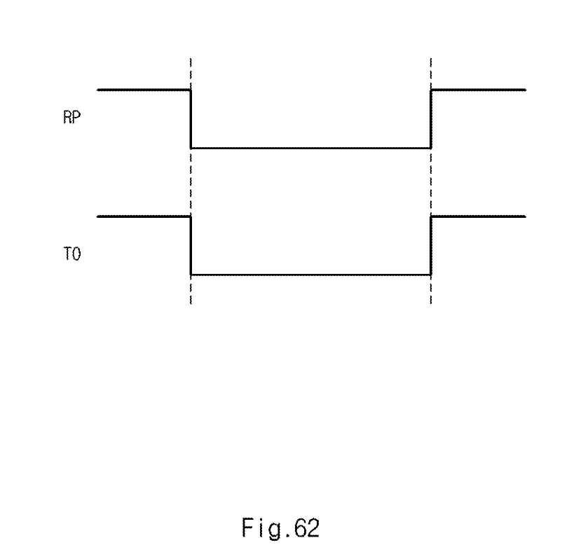

FIG. 62 is a timing diagram illustrating operations of the test output driver 170 according to fifth and sixth embodiments of the present invention.

Referring to FIG. 62, the test output driver 170 provides an input terminal of the driver DRV_T with a pull-up voltage of the power-supply voltage level VDD through the pull-up driver PU_T. Therefore, the driver DRV_T outputs the response signal RP received from the digital unit 200 as a test output signal TO using a pull-up voltage.

Upon receiving the response signal RP of a low level from the digital unit 200, the driver DRV_T operates or drives the test output signal TO as a low level signal. If the response signal RP of a high level is input to the driver DRV_T, the test output signal TO of a high level is output from the driver DRV_T.

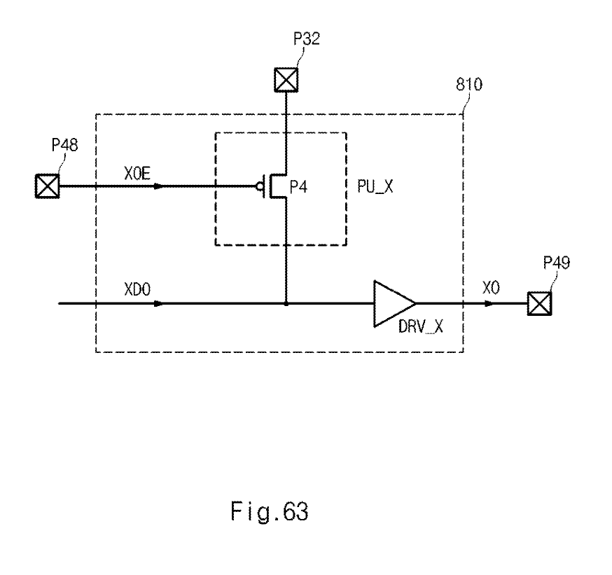

FIG. 63 is a detailed circuit diagram illustrating the control output driver 810 according to fifth and sixth embodiments of the present invention.

Referring to FIG. 63, the control output driver 810 includes a pull-up driver PU_X and a driver DRV_X. The pull-up driver PU_X includes a PMOS transistor P4. A control signal XOE received from the control signal input pad P48 is input to a gate terminal of the PMOS transistor P4. In addition, a power-supply voltage VDD is applied to a drain terminal of the PMOS transistor P4, and a source terminal of the PMOS transistor P4 is coupled to an input terminal of the driver DRV_X.

If the control signal XOE of a high level is input to the control output driver 810, the PMOS transistor P4 is turned off. Therefore, the supply of the power-supply voltage VDD is blocked, so that the pull-up driver PU_X does not pull up output data XDO being input to the driver DRV_X. If the control signal XOE of a low level is input to the control output driver 810, the PMOS transistor P4 is turned on. Accordingly, a power-supply voltage VDD is input to an input terminal of the driver DRV_X, such that the driver DRV_X pulls output data XDO up. Therefore, when the control signal XOE of a low level is input to the control output driver DRV_X although the output data XDO of a low level is input to the driver DRV_X, the output data XDO is pulled up so that it is reset to a high level. The driver DRV_X operates output data XDO being received from the digital unit 200, so that it generates a control output signal XO. In addition, the driver DRV_X outputs the control output signal XO to an external device via the control signal output pad P49.

If the control signal XOE of a low level is input to the control output driver 810, the pull-up driver PU_X is activated. Thus, output data XDO is reset to a high level, so that the driver DRV_X operates the output data XDO. Thereafter, if the control signal XOE of a high level is input to the control output driver 810, the pull-up driver PU_X is deactivated, such that the driver DRV_X does not pull the output data XDO up.

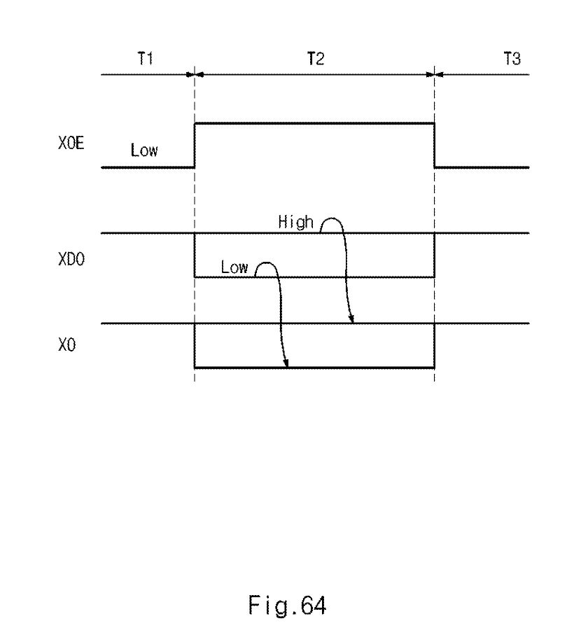

FIG. 64 is a timing diagram illustrating operations of the control output driver 810 according to fifth and sixth embodiments of the present invention.

Referring to FIG. 64, the control signal XOE of a low level is input to the control output driver 810 during a time period T1, so that the pull-up driver PU_X is activated. If the pull-up driver PU_X is activated, the power-supply voltage VDD is applied to an input terminal of the driver DRV_X. Thus, output data XDO being input to the driver DRV_X is pulled up so that it is reset to a high level.

If a control signal XOE is changed from a low level to a low level during the time period T2, the pull-up driver PU_X is deactivated. If the pull-up driver PU_X is deactivated, the power-supply voltage VDD is not applied to the input terminal of the driver DRV_X. Therefore, output data XDO being input to the driver DRV_X is driven in response to an output level of the digital unit 200. In other words, if the output data XDO of a low level is input to the control output driver 810, the driver DRV_X allows the control output signal XO to be low in level. If output data XDO of a high level is input to the control output driver 810, the driver DRV_X allows the control output signal XO to be high in level.

If the control signal XOE is changed back from a high level to a low level during the time period T3, the pull-up driver PU_X is activated, so that output data XDO is pulled up to a high level. Thus, the driver DRV_X allows output data XDO to be high in level.

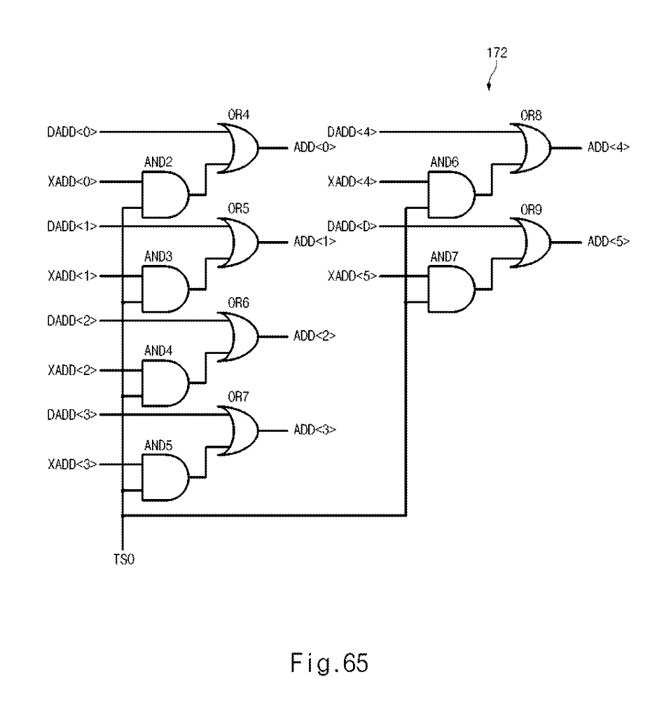

FIG. 65 is a circuit diagram illustrating the address I/O unit 172 shown in FIG. 60.

The address I/O unit 172 includes a plurality of logic elements OR4 OR9 coupled in parallel to each other. Each of the logic elements OR4 OR9 receives an address XADD from an external device, receives an address DADD from the digital unit 200, and receives a test serial output signal TSO from the shift register 800, so that it generates an address ADD and outputs the address ADD to a memory unit 400.

The address XADD received from an external device is used to test an RFID tag by control signals XCE, XWE and XOE. The address DADD received from the digital unit 200 is used to test an RFID tag by a test input signal TI.

The address I/O unit 172 receives the addresses XADD and DADD, generates an address ADD according to which test method will be applied to the RFID tag, and outputs the address ADD to the memory unit 400. The address ADD indicates information about the location of a memory cell contained in the memory unit 400, and may selectively test all memory cells or a specific memory cell contained in the memory unit 400.

The address I/O unit 172 includes a plurality of logic elements OR4 OR9 coupled in parallel to each other. Each of the logic elements OR4 OR9 performs a logic OR operation between the address DADD and an AND operation result calculated between the address XADD and the test serial output signal TSO.

The logic elements OR4 OR9 output the address ADD only when the test operation is carried out so that the test serial output signal TSO is output as a high level signal. When the test serial output signal TSO of a high level is output and the address DADD or XADD is input to the address I/O unit 172 as a high level signal, the address ADD is output as a high level signal. If each of the addresses XADD and DADD is input as a low level signal, the address ADD is output as a low level signal.

In other words, when performing the test by the test input signal T1, the address I/O unit 172 generates the address ADD in response to the address XADD. When performing the test by the control signals XCE, XWE and XOE, the address I/O unit 172 generates the address ADD in response to the address DADD.

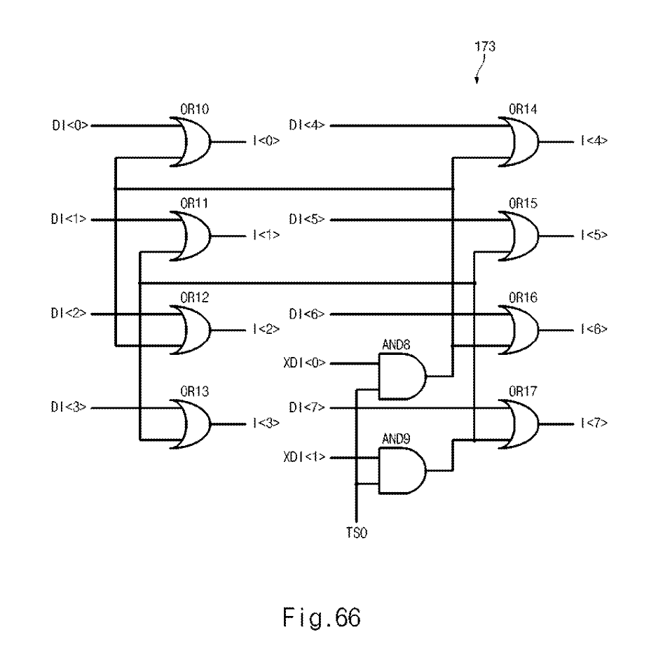

FIG. 66 is a detailed circuit diagram illustrating a data I/O unit 173 shown in FIG. 60.

Referring to FIG. 66, the data I/O unit 173 includes a plurality of logic elements OR10 OR17 coupled to each other. Each of the logic elements OR10 OR17 receives input data XDI from an external device, receives a control signal DI from the digital unit 200, and receives a test serial output signal TSO from the shift register 800, so that it generates a control signal I and outputs the control signal Ito the memory unit 400.

The input data XDI received from an external device is used to test an RFID tag by control signals XCE, XWE and XOE. The control signal DI received from the digital unit 200 is used to test an RFID tag by a test input signal TI.

The data I/O unit 173 includes a plurality of logic elements OR10˜OR17 coupled to each other. Each of the logic elements OR10˜OR17 performs a logic OR operation between the control signal DI and an AND operation result calculated between the input data XDI and the test serial output signal TSO. In the embodiment shown in FIG. 66, two input data parts XDI<0> and XDI<1> are branched and then input to four logic elements OR14˜OR17. However, the number of input data parts XDI may be changed in various ways according to a user's intention.

The logic elements OR10˜OR17 output the control signal I only when the test operation is carried out so that test serial output signal TSO is output as a high level signal. When the test serial output signal TSO is output as a high level signal, and either the input data XDI or the control signal DI is input to each of the logic elements OR10˜OR17 as a high level signal, each logic element outputs the control signal I as a low level signal.

The following table 1 shows an I/O relationship between the data I/O unit 173 according to fifth and sixth embodiments of the present invention.

TABLE 1

| External | | | | | | | | | | | | |
|---|---|---|---|---|---|---|---|---|---|---|---|---|
| test input | | Default output of digital unit 200 | | | | | | | | Input of valid memory unit 400 | | |
| XDI<0> | XDI<1> | DI<0> | DI<1> | DI<2> | DI<3> | DI<4> | DI<5> | DI<6> | DI<7> | I<0> | I<1> | I<2> |
| 0 | 0 | 0 | 0 | 0 | 0 | 0 | 0 | 0 | 0 | 0 | 0 | 0 |
| 0 | 1 | 0 | 0 | 0 | 0 | 0 | 0 | 0 | 0 | 0 | 1 | 0 |
| 1 | 0 | 0 | 0 | 0 | 0 | 0 | 0 | 0 | 0 | 1 | 0 | 1 |
| 1 | 1 | 0 | 0 | 0 | 0 | 0 | 0 | 0 | 0 | 1 | 1 | 1 |

| External | | | | | | | Detecting output | External |
|---|---|---|---|---|---|---|---|---|
| test input | | Input of valid memory unit 400 | | | | | of memory unit 400 | test output |
| XDI<0> | XDI<1> | I<3> | I<4> | I<5> | I<6> | I<7> | XOR OUT | XDO |
| 0 | 0 | 0 | 0 | 0 | 0 | 0 | 0 | 1 |
| 0 | 1 | 1 | 0 | 1 | 0 | 1 | 0 | 1 |
| 1 | 0 | 0 | 1 | 0 | 1 | 0 | 0 | 1 |
| 1 | 1 | 1 | 1 | 1 | 1 | 1 | 0 | 1 |

Referring to Table 1, the test circuit 700 tests the memory unit 400 by the control signal I according to a logic level of input data XDI<0> and XDI<I>, and thus outputs output data XDO as the result of the test.

For example, provided that the test circuit 700 receives the input data XDI<0> of a low level, the input data XDI<1> of a high level, and data DI<0>˜DI<7> of a low level, data I<1>, I<3>, I<5> and I<7> of a high level is output so that a corresponding memory cell can be tested. Thereafter, the test circuit 700 outputs high level output data XDO indicating the test result.

For another example, provided that the test circuit 700 receives the input data XDI<0> of a high level, the input data XDI<1> of a high level, and data DI<0>˜DI<7> of a low level, data I<1>˜I<7> of a high level is output so that all memory cells are tested. Thereafter, the test circuit 700 outputs high level output data XDO indicating the test result.

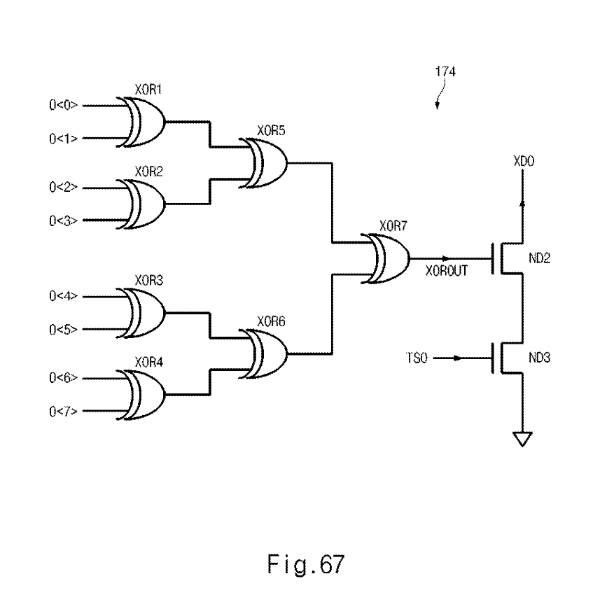

FIG. 67 is a detailed circuit diagram illustrating the control signal I/O unit 174 shown in FIG. 60.

Referring to FIG. 67, the control signal I/O unit 174 includes a plurality of logic elements XOR1˜XOR6 coupled to each other. Each of the logic elements XOR1˜XOR6 receives the control result signal O from the memory unit 400, receives the test serial output signal TSO from the shift register 800, generates output data XDO, and outputs the output data XDO to the control output driver 810.

The control result signal O indicates the result of testing the memory unit 400. The control signal I/O unit 174 performs an exclusive-OR (XOR) operation of the control result signals O<0>˜O<7> received from the memory unit 400. In other words, the control result signals O<0> and O<1> are exclusive-OR (XOR) operated, the control result signals O<2> and O<3> are exclusive-OR (XOR) operated, the control result signals O<4> and O<5> are exclusive-OR (XOR) operated, and the control result signals O<6> and O<7> are exclusive-OR (XOR) operated. The XOR operation result between the control result signals O<0> and O<1> and the XOR operation result between the control result signals O<2> and O<3> are XOR-operated so that a first XOR operation signal is generated. The XOR operation result between the control result signals O<4> and O<5> and the XOR operation result between the control result signals O<6> and O<7> are XOR-operated so that a second XOR operation signal is generated. The first and second XOR operation signals are XOR-operated, so that a control result signal XOROUT is generated.

The output terminal of the control signal I/O unit 174 includes two NMOS transistors ND2 and ND3 coupled in series to each other. The NMOS transistor ND2 receives the control result signal XOROUT via a gate terminal. The NMOS transistor ND2 outputs output data XDO via a drain terminal. In addition, a source terminal of the NMOS transistor ND2 is coupled to a source terminal of the NMOS transistor ND3. The NMOS transistor ND3 receives a test output signal TSO via a gate terminal. The drain terminal of the NMOS transistor ND3 is coupled to a source terminal of the NMOS transistor ND2, and the source terminal of the NMOS transistor ND3 is coupled to a ground terminal.

In the control signal I/O unit 174, the NMOS transistors ND2 and ND3 are turned on when the control result signal XOROUR and the test serial output signal TSO are simultaneously high in level. Accordingly, output data XDO is output as a ground level.

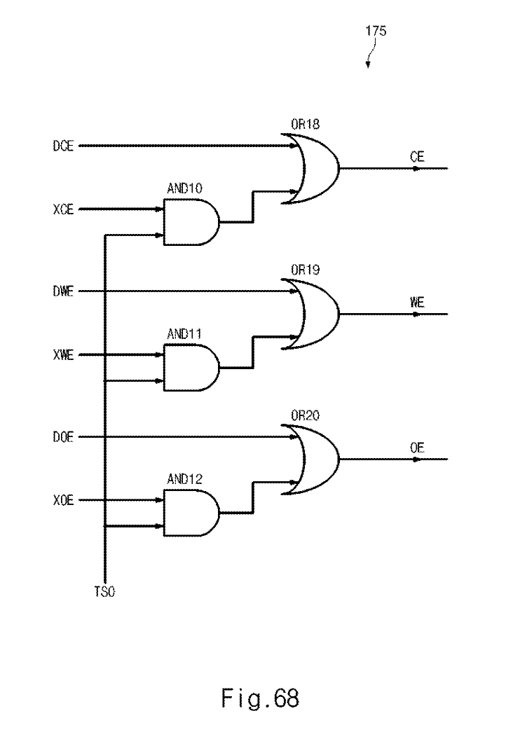

FIG. 68 is a detailed circuit diagram illustrating the control signal I/O unit 175 shown in FIG. 60.

Referring to FIG. 68, the control signal I/O unit 175 includes a plurality of logic elements AND10˜AND12 coupled to each other, and a plurality of OR gates coupled to each other. The control signal I/O unit 175 receives control signals DCE, DWE and DOE from the digital unit 200, receives control signals XCE, XWE and XOE from an external device, generates control signals CE, WE and OE, and outputs the control signals CE, WE and OE to the memory unit 400.

Input data XDI received from an external device is used to test the memory unit 400 of an RFID tag using control signals XCE, XWE and XOE. The control signal DI received from the digital unit 200 is used to test an RFID tag by a test input signal TI.

The logic element AND10 performs a logic AND operation between the control signal XCE and the test output signal TSO. The logic element OR18 performs a logic OR operation between the output signal of the logic element AND10 and the control signal DCE, so that it outputs the control signal CE. The logic element AND11 performs a logic AND operation between the control signal XWE and the test output signal TSO. The logic element OR19 performs a logic OR operation between the output signal of the logic element AND11 and the control signal DWE, so that it outputs the control signal WE. The logic element AND12 performs a logic AND operation between the control signal XOE and the test output signal TSO. The logic element OR20 performs a logic OR operation between the output signal of the logic element AND12 and the control signal DOE, so that it outputs the control signal OE.

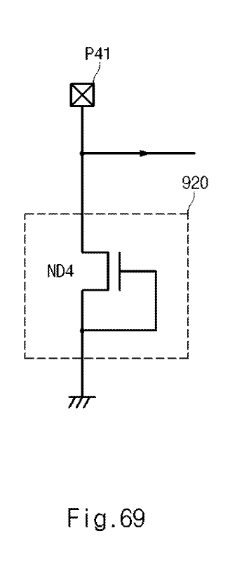

FIG. 69 is a detailed circuit diagram illustrating the electrostatic protection unit 920 shown in FIG. 52.

Referring to FIG. 69, the test serial signal input pad P41 receives the test serial input signal TSO or the test serial output signal TSO from an external device, and transmits the test serial input signal TSO or the test serial output signal TSO to the shift register 800. The electrostatic protection unit 920 is coupled between the test serial signal input pad P41 and the ground terminal.

The electrostatic protection unit 920 includes an NMOS transistor ND4. In the NMOS transistor ND4, a gate terminal and a source terminal are coupled to a ground terminal. The drain terminal is coupled to the test serial signal input pad P41. Since the gate terminal of the NMOS transistor ND4 is coupled to the ground terminal, the NMOS transistor ND4 maintains an OFF status. However, if a high voltage is instantaneously applied to the electrostatic protection unit 920 due to static electricity generated in the test serial signal input pad P42, the NMOS transistor ND4 is turned on, such that a current flows in the ground terminal. Therefore, the electrostatic protection unit 920 substantially prevents a high current from flowing in the shift register circuit 800 contained in the RFID tag.

As apparent from the above description, an RFID device and a method for testing the same according to the embodiments of the present invention can enable one test chip to test a plurality of tag chips contained in a tag chip array in a wafer level, resulting in reduced costs and higher efficiency in a test operation.

Although a number of illustrative embodiments consistent with the invention have been described, it should be understood that numerous other modifications and embodiments can be devised by those skilled in the art that will fall within the spirit and scope of the principles of this disclosure. Particularly, numerous variations and modifications are possible in the component parts and/or arrangements which are within the scope of the disclosure, the drawings and the accompanying claims. In addition to variations and modifications in the component parts and/or arrangements, alternative uses will also be apparent to those skilled in the art.

1. A radio frequency identification (RFID) device comprising:
a tag chip configured to perform a test operation upon receiving a test input signal from a node external to the tag chip, and output a test output signal to the external node, the test output signal providing a result of the test operation; and
a test chip configured to test the tag chip upon receiving an address and data from a node external to the test chip.

2. The radio frequency identification (RFID) device according to claim 1, wherein the test chip receives the address and the data via a single common test pad according to a time sharing scheme.

3. The radio frequency identification (RFID) device according to claim 1, wherein the address includes a tag selection address and a memory address.

4. The radio frequency identification (RFID) device according to claim 3, wherein the tag selection address, the memory address, and the data are input in a predetermine order.

5. The radio frequency identification (RFID) device according to claim 1, wherein the tag chip is one of a plurality of tag chips arranged in column and row directions that define a tag chip array, and
wherein the test chip is configured to control a test operation of the tag chip array.

6. The radio frequency identification (RFID) device according to claim 5, wherein the tag chip and the test chip are coupled to each other via an interconnect formed on a scribe region.

7. The radio frequency identification (RFID) device according to claim 5, wherein the test chip is arranged at a center of the tag chip array.

8. The radio frequency identification (RFID) device according to claim 1, wherein the tag chip includes a memory unit which includes a non-volatile ferroelectric memory so as to perform read/write operations of data.

9. The radio frequency identification (RFID) device according to claim 1, wherein the test chip further includes:
a test signal output pad configured to output the test output signal to an external part;
a power-supply voltage applying pad configured to receive a power-supply voltage;
a ground voltage applying pad configured to receive a ground voltage; and
a test signal input pad configured to receive the test input signal.

10. The radio frequency identification (RFID) device according to claim 1, wherein the test chip further includes:
a first pad configured to receive a data latch activation signal capable of controlling a latch operation of the data;
a second pad configured to receive an address latch activation signal capable of controlling a latch operation of the address;
a data output pad via which the tag chip outputs a test result of a memory unit to an external node;
a third pad configured to receive a chip enable signal from an external node;
a fourth pad configured to receive a write enable signal from an external node;
a fifth pad configured to receive an output enable signal from an external node;
a test input pad configured to receive a test operation signal capable of activating a test mode; and
a test clock input pad configured to receive a test clock signal capable of controlling an operation of the test mode.

11. A radio frequency identification (RFID) device comprising:
a memory unit having a cell array that is configured to store data in response to internal control signals; and
a test interface unit configured to generate the internal control signals upon receiving address information and data from an external node when a test activation signal is activated, perform a test operation of the memory unit, and output a test output signal indicating a result of the test operation to an external node.

12-26. (canceled)

27. A method for testing a radio frequency identification (RFID) device including a memory unit and a test interface unit for testing the memory unit in response to address information and data that are received from an external node via a single common test pad, the method comprising:
receiving the address information and the data via the common test pad;
performing a test operation of the memory unit; and
outputting a result of the test operation of the memory unit to an external node via the common test pad.

28-32. (canceled)

33. A radio frequency identification (RFID) device comprising:
a tag chip array configured to have a plurality of tag chips, each tag chip including a memory unit;
a test chip configured to test the tag chip array upon receiving address information and data from an external node; and
a data bus coupling the tag chip array to the test chip, the data bus providing a path between the tag chip array and the test chip for an output current of the tag chip array to be provided to the test chip,
wherein the test chip is configured to output a status of one or more tag chips in the tag chip array to an external node based on the output current of the tag chip array received.

34-46. (canceled)

47. A method for testing a radio frequency identification (RFID) device including a tag chip and a test chip, the test chip being configured to test the tag chip in response to an address and data received from an external node and being coupled to the tag chip via a data bus, the method comprising:
receiving an address corresponding to each of the tag chip and the test chip;
detecting a current applied to the data bus in response to a test command; and
determining whether the tag chip or the test chip is in a failed mode based on an amount current of a pull-down current detected.

48-49. (canceled)

50. A radio frequency identification (RFID) device comprising:
a digital unit configured to be activated by a test serial input signal and a test clock signal, perform a test operation in response to a test input signal received from an external node during an activation period, and output a response signal when the test operation is completed; and
an input/output (I/O) pad unit configured to receive a power-supply voltage, a ground voltage, the test serial input signal, the test clock signal, and the test input signal from an external node.

51-67. (canceled)

68. A method for testing a radio frequency identification (RFID) device having a digital unit and an input/output (I/O) pad unit, the digital unit being configured to be activated by a test serial input signal and a test clock signal, perform a test operation in response to a test input signal received from an external node during an activation period, and output a response signal when the test operation is completed, the input/output (I/O) pad unit being configured to receive a power-supply voltage, a ground voltage, the test serial input signal, the test clock signal, and the test input signal from an external node, the method comprising:
activating the digital unit by the test serial input signal and the test clock signal;
receiving the test input signal via the input/output (I/O) pad unit;
performing, by the digital unit, the test operation in response to the test input signal, to generate a test output signal;
outputting the test output signal to an external node; and
comparing the test input signal with the test output signal.

69. (canceled)

70. A radio frequency identification (RFID) device comprising:
a shift register configured to receive a test serial input signal and a test clock signal, generate a test serial output signal, and output the test serial output signal;
a test circuit configured to be activated by the test serial output signal and perform a test operation in response to a test input signal received from an external node during an activation period; and
an input/output (I/O) pad unit configured to receive a power-supply voltage, a ground voltage, the test serial input signal, the test clock signal, and the test input signal from an external node, and output the test serial output signal.

71-76. (canceled)

77. A radio frequency identification (RFID) device comprising:
a shift register configured to receive a test serial input signal and a test clock signal, generate a test serial output signal, and output the test serial output signal;
a test circuit which configured to be activated by the test serial output signal and perform a test operation in response to an address, data, and a control signal received from an external node during an activation period; and
an input/output (I/O) pad unit configured to receive a power-supply voltage and a ground voltage from an external node, receive the test serial input signal, the test clock signal, the address, the data, and the control signal, and output the test serial output signal.

78-87. (canceled)

88. A method for testing a radio frequency identification (RFID) device including a shift register configured to receive a test serial input signal and a test clock signal, generate a test serial output signal, and output the test serial output signal, a test circuit configured to be activated by the test serial output signal and perform a test operation in response to a test input signal received from an external node during an activation period, and an input/output (I/O) pad unit configured to receive a power-supply voltage and a ground voltage from an external node, receive the test serial input signal, the test clock signal, the test input signal, and output the test serial output signal, the method comprising:
activating the test circuit based on the test serial output signal;
receiving the test input signal via the input/output (I/O) pad unit;
generating a test output signal by allowing the test circuit to perform the test operation in response to the test input signal;
outputting the test output signal to an external node; and
comparing the test input signal with the test output signal.

89. (canceled)

90. A method for testing a radio frequency identification (RFID) device having a shift register configured to receive a test serial input signal and a test clock signal, generate a test serial output signal, and output the test serial output signal, a test circuit configured to be activated by the test serial output signal and performs a test operation in response to an address, data, and a control signal received from an external node during an activation period, and an input/output (I/O) pad unit configured to receive a power-supply voltage and a ground voltage from an external node, receive the test serial input signal, the test clock signal, the address, the data, and the control signal, and output the test serial output signal, the method comprising:
activating the test circuit using the test serial output signal;
receiving the address and the control signal via the input/output (I/O) pad unit;
generating a test output signal by allowing the test circuit to perform the test operation in response to the address and the control signal;
outputting the test output signal to an external node; and
comparing the test input signal with the test output signal.

91. A radio frequency identification (RFID) device comprising:
a test chip configured to be initialized by a power-supply voltage and start a test operation; and
a plurality of RFID tags coupled in series to the test chip,
wherein the RFID tags are sequentially activated upon receiving a power-supply voltage and a ground voltage from an external node, so that a test operation of the RFID tags can be performed.

92-114. (canceled)

115. A method for testing a radio frequency identification (RFID) device having a test chip and a plurality of RFID tags coupled in series to the test chip, the method comprising:
initializing the test chip after receiving a power-supply voltage;
receiving the power-supply voltage and a ground voltage when a test operation begins by the initialization of the test chip; and
activating the RFID tags sequentially testing the RFID tags activated sequentially.

116-119. (canceled)
